(19) United States
(12) Patent Application Publication
(10) Pub. No.: US 2026/0068281 A1
(43) Pub. Date: Mar. 5, 2026

(54) SEMICONDUCTOR DEVICE AND METHODS OF FORMATION

(71) Applicant: Taiwan Semiconductor Manufacturing Company, Ltd., Hsinchu (TW)

(72) Inventors: Tzu Jung TIEN, Hsinchu County (TW); Cheung CHENG, Hsinchu City (TW); Wen-Chih CHIANG, Hsinchu City (TW)

(21) Appl. No.: 18/819,650

(22) Filed: Aug. 29, 2024

(51) Int. Cl. H01L 29/51; H01L 21/762; H01L 29/417

(52) U.S. Cl. CPC H10D 64/685; H10D 64/258

(57) ABSTRACT

A high-voltage transistor may include a composite gate dielectric layer having multiple regions with different dielectric constant values and/or a composite gate structure having multiple regions of different work function values. The composite dielectric layer having multiple regions with different dielectric constant values and/or the composite gate structure having multiple regions with different work functions increases the threshold voltage uniformity across a channel region of the high-voltage transistor. The increased threshold voltage uniformity may enable a low subthreshold swing and a low subthreshold off-stage current leakage to be achieved for the high-voltage transistor, which increases the operating efficiency of the high-voltage transistor and enables the size of the high-voltage transistor to be reduced without increasing (or with minimal increase to) the subthreshold swing and and/or the subthreshold off-stage current leakage of the high-voltage transistor.

### BACKGROUND

A high-voltage transistor includes a transistor that is configured to operate at greater voltages (e.g., a high gate voltage, a high drain voltage) relative to medium voltage transistors and low voltage transistors, and a medium voltage transistor includes a transistor that is configured to operate at greater voltages (e.g., a high gate voltage, a high drain voltage) relative to low voltage transistors. The maximum voltages that can be endured (without being damaged) by medium voltage transistors may be lower than the maximum voltages that can be endured (without being damaged) by high-voltage transistors, and the maximum voltages that can be endured (without being damaged) by low voltage transistors are lower than the maximum voltages that can be endured (without being damaged) by medium voltage transistors.

High-voltage transistors and medium voltage transistors may be used in applications such as integrated circuit (IC) drivers, power ICs, shifter circuits, image sensors, power management, radio frequency (RF) power amplifiers, display driver ICs (DDICs), bipolar complementary metal oxide semiconductor (CMOS) diffused metal oxide semiconductor (DMOS) ICs (BCD ICs), and/or image signal processing (ISP) ICs, among other examples.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example semiconductor device described herein.

FIGS. 2A-2C are diagrams of an example implementation of an integrated circuit device described herein.

FIGS. 3A-3W are diagrams of an example implementation of forming an integrated circuit device that includes a composite gate dielectric layer described herein.

FIGS. 4A-4C are diagrams of an example implementation of an integrated circuit device described herein.

FIGS. 5A-5C are diagrams of an example implementation of an integrated circuit device described herein.

FIGS. 6A-6Z are diagrams of an example implementation of forming an integrated circuit device that includes a composite gate structure described herein.

FIGS. 7A-7C are diagrams of an example implementation of an integrated circuit device described herein.

FIGS. 8A-8C are diagrams of an example implementation of an integrated circuit device described herein.

FIG. 9 is a diagram of an example implementation of an integrated circuit devices described herein.

FIG. 10 is a flowchart of an example process associated with forming a transistor structure described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

High-voltage transistors may be integrated into a semiconductor device along with low voltage transistors such that power management circuitry, display driver circuitry, sensor circuitry, and/or other high voltage circuitry may be integrated with low voltage logic circuitry of the semiconductor device. While this enables high-voltage transistors and low voltage transistors to be manufactured using similar semiconductor manufacturing processes and to share manufacturing operations, high-voltage transistors may suffer from performance defects due to such manufacturing integration.

For example, electrical isolation in the form of isolation regions (e.g., shallow trench isolation (STI) regions, local oxidation of silicon (LOCOS) regions) may be provided around the high-voltage transistors in a similar manner as the low voltage transistors. The sharp transition between the isolation regions and the channel regions of the high-voltage transistors may result in a phenomenon referred to as the subthreshold hump effect (or the double hump effect). For example, the threshold voltage (Vₜ) of the high-voltage transistor may be lowest at the edges of a channel region of a high-voltage transistor near the isolation regions (e.g., due to field crowding and/or surface doping concentration in the high-voltage transistor, among other examples), and may increase toward the center of the channel region, resulting in a subthreshold hump in the threshold voltage (Vₜ) of the high-voltage transistor. Because the threshold voltage (Vₜ) of the high-voltage transistor is lower at the edges of the channel region, subthreshold swing and subthreshold off-stage current leakage may be higher at the edges of the channel region than near the center of the channel region.

In some implementations described herein, a high-voltage transistor may include a composite gate dielectric layer having multiple regions with different dielectric constant values (e.g., different k-values) to achieve greater threshold voltage (Vₜ) uniformity across a channel region of the high-voltage transistor than if a uniform gate dielectric layer were used. The regions of different k-values may be arranged in a direction along a length of the channel region between source/drain regions of the high-voltage transistor, and/or may be arranged in a direction along a width of the channel region. The use of regions of different k-values can compensate for the subthreshold hump effect at edges of the channel region by tuning the threshold voltage at the edges of the channel region. Additionally and/or alternatively, the threshold voltage uniformity may be increased (e.g., separately or in addition to threshold voltage tuning by regions of different k-values for the gate dielectric layer) by forming a gate structure of the high-voltage transistor to have multiple regions of different work function values. Thus, the gate structure may be referred to as a composite gate structure. The regions with different work function values of the composite gate structure may compensate for the subthreshold hump effect at edges of the channel region by tuning the threshold voltage at the edges of the channel region.

In this way, the composite dielectric layer having multiple regions with different dielectric constant values, and/or the composite gate structure having multiple regions with different work functions, increases the threshold voltage uniformity across a channel region of the high-voltage transistor. The increased threshold voltage uniformity may enable a low subthreshold swing and a low subthreshold off-stage current leakage to be achieved for the high-voltage transistor, which increases the operating efficiency of the high-voltage transistor and enables the size of the high-voltage transistor to be reduced without increasing (or with minimal increase to) the subthreshold swing and and/or the subthreshold off-stage current leakage of the high-voltage transistor.

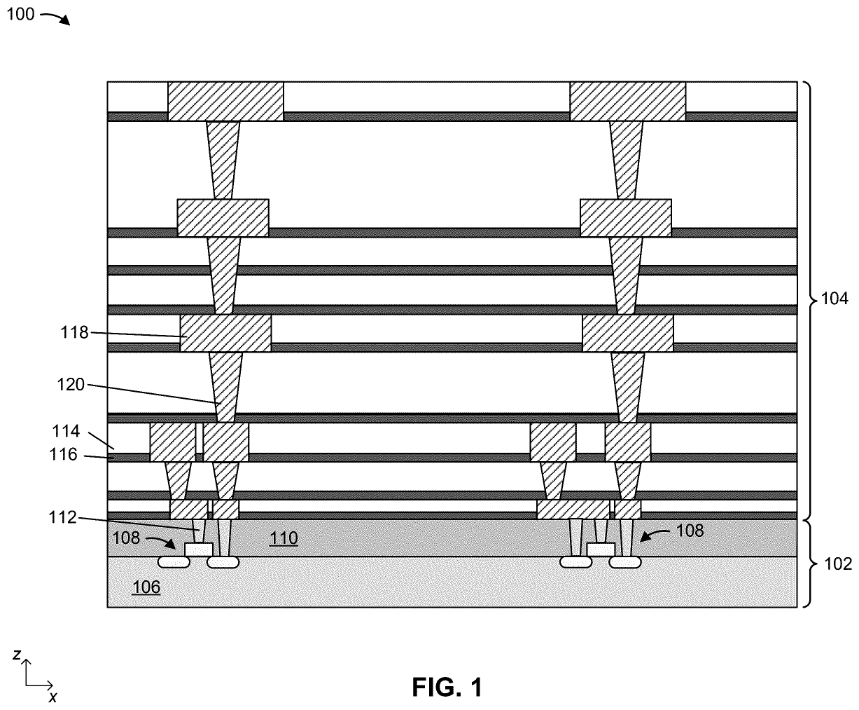

FIG. 1 is a diagram of an example semiconductor device 100 described herein. The semiconductor device 100 may include system on chip (SoC) device, a logic device such as a central processing unit (CPU) or a graphics processing unit (GPU), a memory device (e.g., a high bandwidth memory (HBM) device), a panel driver device, an integrated circuit (IC) driver, a radio frequency (RF) power amplifier, a display driver IC (DDIC), and/or another type of semiconductor device.

As shown in FIG. 1, the semiconductor device 100 may include a device layer 102 and an interconnect layer 104 above the device layer 102 in a z-direction in the semiconductor device 100. The device layer 102 may also be referred to as a frontend region or a front end of line (FEOL) region of the semiconductor device 100. The interconnect layer 104 may also be referred to as a backend region or a back end of line (BEOL) region of the semiconductor device 100.

The device layer 102 includes a substrate 106. The substrate 106 may correspond to a portion of a semiconductor wafer on which the semiconductor device 100 is formed. The substrate 106 includes a silicon (Si) substrate, a substrate formed of a material including silicon, a III-V compound semiconductor material substrate such as gallium arsenide (GaAs), a silicon on insulator (SOI) substrate, or another type of semiconductor substrate. The substrate 106 may extend in an x-direction and/or in a y-direction in the semiconductor device 100.

Integrated circuit devices 108 may be included in and/or on the substrate 106 in the device layer 102 of the semiconductor device 100. The integrated circuit devices 108 include frontend transistor structures (e.g., frontend planar transistor structures, frontend fin field effect transistor (finFET) structures, frontend gate all around (GAA) transistor structures), pixel sensors, capacitors, resistors, inductors, photodetectors, transceivers, transmitters, receives, optical circuits, and/or other types of frontend semiconductor devices. Frontend semiconductor devices refer to the semiconductor devices that are formed in the device layer 102 (e.g., in and/or on the substrate 106) of the semiconductor device 100.

In some implementations, one or more of the integrated circuit devices 108 include a high-voltage transistor (or a medium voltage transistor). “High-voltage transistor” refers to a transistor that is configured to operate at higher operating voltages (e.g., higher gate voltages, higher source/drain voltages) than low voltage transistors. As an example, a high-voltage transistor may be configured to operate in a drain voltage range of approximately 9 volts to approximately 36 volts, whereas a low-voltage transistor may be configured to operate in a drain voltage range of approximately 0 volts to approximately 1.8 volts. However, other values for these ranges are within the scope of the present disclosure.

In some implementations, a high-voltage transistor (or a medium voltage transistor) may include a laterally diffused (or laterally double diffused) metal-oxide semiconductor (LDMOS) transistor that has a drift region in which charge carriers are laterally diffused to facilitate distribution of an electric field between a gate structure and a source/drain region of the high-voltage transistor. The lateral diffusion of charge carriers in the drift region enables the high-voltage transistor to withstand higher gate and source/drain voltages (e.g., by increasing the breakdown voltage of the high-voltage transistor) than low voltage transistors.

A dielectric layer 110 is included over the substrate 106. The dielectric layer 110 includes an interlayer dielectric (ILD) layer, an etch stop layer (ESL), and/or another type of dielectric layer. The dielectric layer 110 includes dielectric material(s) that enable various portions of the substrate 106 and/or the integrated circuit devices 108 to be selectively etched or protected from etching, and/or to electrically isolate the integrated circuit devices 108 in the device layer 102. The dielectric layer 110 includes a silicon nitride (SiₓN_{y}), an oxide (e.g., a silicon oxide (SiOₓ) and/or another oxide material), and/or another type of dielectric material. The dielectric layer 110 may extend in the x-direction and/or in a y-direction in the semiconductor device 100.

The interconnect layer 104 of the semiconductor device 100 is included above the substrate 106 and above the integrated circuit devices 108 in the z-direction in the semiconductor device 100. The integrated circuit devices 108 may be electrically coupled to the interconnect layer 104 by contact structures 112. In some implementations, an integrated circuit device 108 may be electrically coupled to gate contacts and source/drain contacts. The contact structures 112 may include contact plugs, vias, pillars, contact pads, and/or another type of electrically conductive contacts. The contact structures 112 may include one or more electrically conductive materials such as tungsten (W), cobalt (Co), ruthenium (Ru), titanium (Ti), an alloy thereof, a metal nitride that contains one or more metals, and/or another electrically conductive material. In some implementations, a liner is included between a contact structure 112 and the dielectric layer 110. The liner may include an adhesion liner, a barrier liner, and/or another type of liner, and may include liner materials such as tantalum (Ta), tantalum nitride (TaN), and/or titanium nitride (TiN), among other examples.

The interconnect layer 104 includes a plurality of dielectric layers (e.g., backend dielectric layers) that are arranged in a direction (e.g., the z-direction) that is approximately perpendicular to the substrate 106. The dielectric layers may include ILD layers 114 and ESLs 116 that are arranged in an alternating manner in the z-direction. The ILD layers 114 and the ESLs 116 may extend in the x-direction and/or in the y-direction in the semiconductor device 100.

The ILD layers 114 may each include an oxide (e.g., a silicon oxide (SiOₓ) and/or another oxide material), an undoped silicate glass (USG), a boron-containing silicate glass (BSG), a fluorine-containing silicate glass (FSG), tetraethyl orthosilicate (TEOS), hydrogen silsesquioxane (HSQ), and/or another suitable dielectric material. In some implementations, an ILD layer 114 includes an extreme low dielectric constant (ELK) dielectric material having a dielectric constant that is less than approximately 2.5. Examples of ELK dielectric materials include carbon doped silicon oxide (C—SiOₓ), amorphous fluorinated carbon (α-CₓF_{y}), parylene, bis-benzocyclobutenes (BCB), polytetrafluoroethylene (PTFE), a silicon oxycarbide (SiOC) polymer, porous hydrogen silsesquioxane (HSQ), porous methyl silsesquioxane (MSQ), porous polyarylether (PAE), and/or porous silicon oxide (SiOₓ), among other examples.

The ESLs 116 may each include a silicon nitride (SiₓN_{y}), silicon carbide (SiC), silicon oxynitride (SiON), and/or another suitable dielectric material. In some implementations, an ILD layer 114 and an ESL 116 include different dielectric materials to provide etch selectivity to enable various structures to be formed in the interconnect layer 104.

The interconnect layer 104 includes a plurality of conductive structures. One or more of the conductive structures are electrically coupled and/or physically coupled with one or more of the integrated circuit devices 108 (e.g., with the contact structures 112 of the integrated circuit devices 108) in the device layer 102. The conductive structures provide electrical routing that enables signals and/or power to be provided to and/or from the integrated circuit devices 108. The conductive structures may include a combination of metallization structures 118 and interconnect structures 120. The metallization structures 118 may include trenches, metallization layers, conductive traces, and/or other types of metallization structures. The interconnect structures 120 may include vias, plugs, interconnects, and/or another type interconnect structure. The metallization structures 118 and the interconnect structures 120 may one or more electrically conductive materials such as tungsten (W), cobalt (Co), ruthenium (Ru), titanium (Ti), aluminum (Al), copper (Cu), gold (Au), and/or a combination thereof, among other examples of electrically conductive materials. In some implementations, one or more liner layers are included on the metallization structures 118 and the interconnect structures 120. The one or more liner layers may include barrier liners, adhesion liners, and/or another type of liners. Examples of materials for the one or more liners include tantalum nitride (TaN) and/or titanium nitride (TiN), among other examples.

In some implementations, the metallization structures 118 and the interconnect structures 120 of the interconnect layer 104 may be arranged in in a vertical manner (e.g., in the z-direction). In other words, a plurality of stacked metallization structures 118 and interconnect structures 120 extend between the device layer 102 and a top of the interconnect layer 104 to facilitate electrical signals and/or power to be routed between the device layer 102 and connection structures (not shown) of the semiconductor device 100. The plurality of stacked metallization structures 118 may be arranged in layers referred to as M-layers. For example, a metal-0 (M0) layer may located at the bottom of the interconnect layer 104 and may be directly coupled with the device layer 102 (e.g., with the contact structures 112 of the integrated circuit devices 108 in the device layer 102). A via-1 (V1) layer that includes one or more interconnect structures 120 may be included above the M0 layer. A metal-1 layer (M1) layer may be located above the V1 layer in the interconnect layer 104, a via-2 (V2) layer may be included above the M1 layer, a metal-2 layer (M2) layer may be located above the V2 layer, and so on. Additionally, via layers may be included between vertically arranged M-layers.

As indicated above, FIG. 1 is provided as an example. Other examples may differ from what is described with regard to FIG. 1.

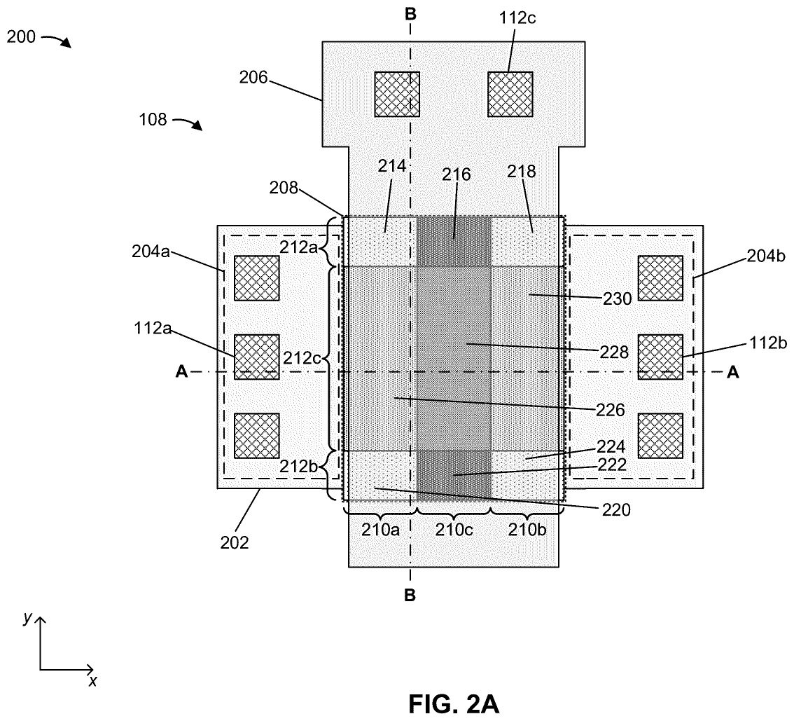

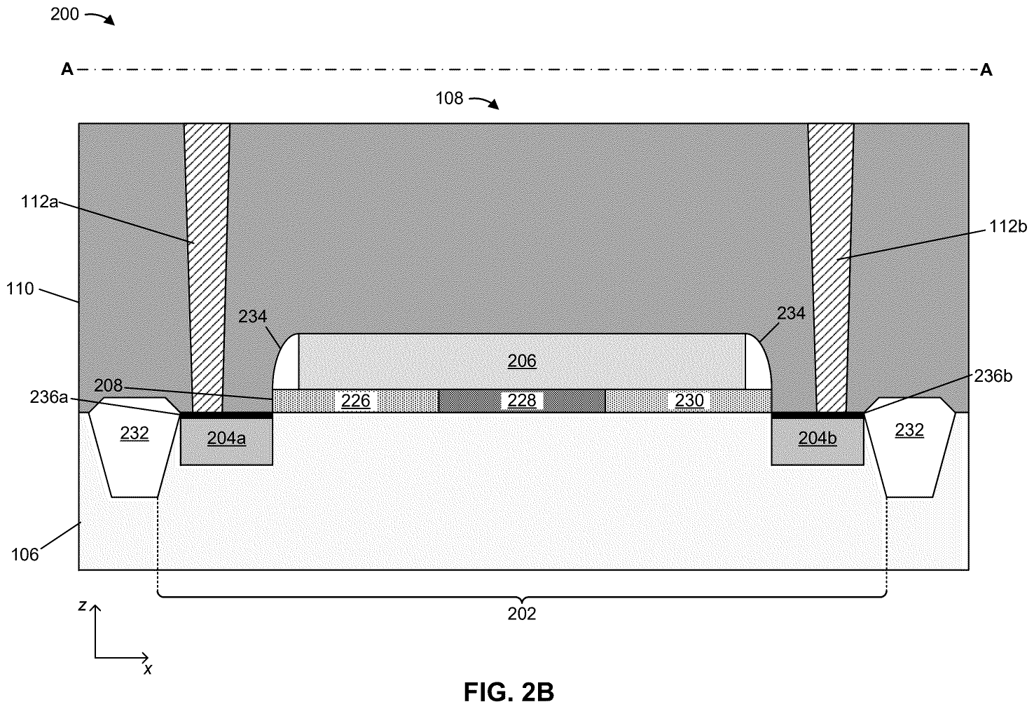

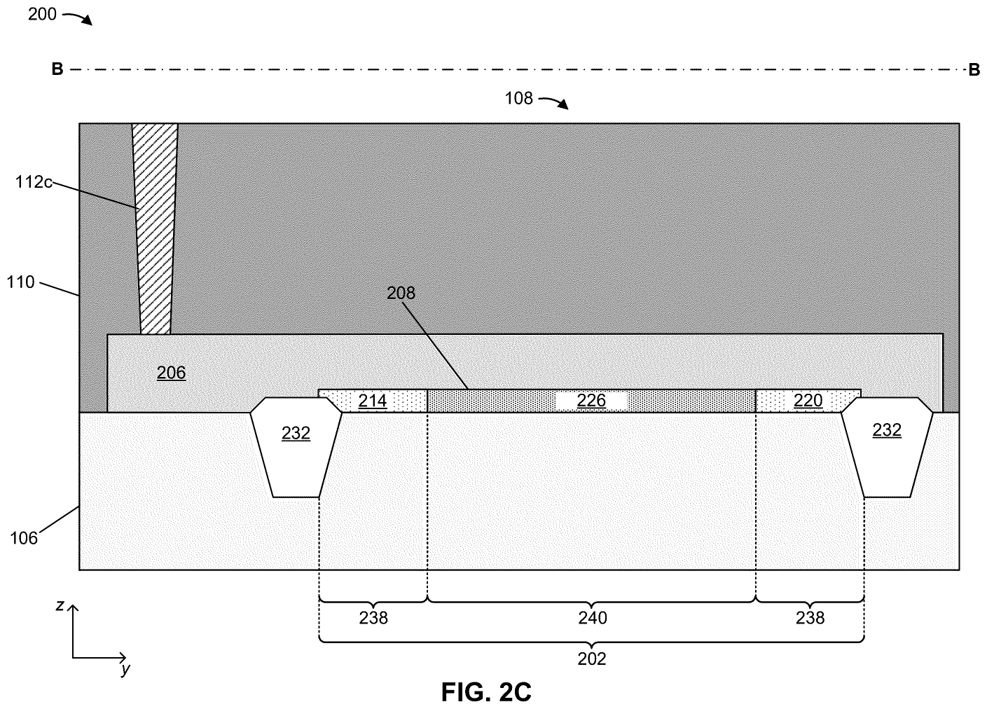

FIGS. 2A-2C are diagrams of an example implementation 200 of an integrated circuit device 108 described herein. In the example implementation 200, the integrated circuit device 108 includes a high-voltage transistor structure. FIG. 2A illustrates a top view of the integrated circuit device 108. FIG. 2B illustrates an example cross-section view of the integrated circuit device 108 along the line A-A in FIG. 2A (e.g., along an x-direction). FIG. 2C illustrates an example cross-section view of the integrated circuit device 108 along the line B-B in FIG. 2A (e.g., along a y-direction).

As shown in FIG. 2A, the integrated circuit device 108 includes an active region 202. The active region 202 also may be referred to as an operation domain (OD), and may include a portion of the substrate 106 of the semiconductor device 100 that is used in active operation of the integrated circuit device 108.

The integrated circuit device 108 may include a source/drain region 204a and a source/drain region 204 b in the active region 202 (e.g., in the substrate 106 of the semiconductor device 100). A source/drain region may refer to a source region, a drain region, or a combination of a source and drain region, depending on the context. In some implementations, the source/drain region 204a is a source region of the integrated circuit device 108 and the source/drain region 204b is a drain region of the integrated circuit device 108 that is configured to operate at a relatively high voltage such as up to approximately 36 volts or higher.

The source/drain regions 204a and 204b may each include one or more doped regions of the substrate 106 of the semiconductor device 100. In some implementations, the source/drain regions 204a and 204b may include the same dopant type. For example, the source/drain regions 204a and 204b may each include silicon doped with one or more p-type dopants such as boron (B) and/or gallium (Ga), among other examples. As another example, the source/drain regions 204a and 204b may each include silicon doped with one or more n-type dopants such as arsenic (A) and/or phosphorous (P), among other examples. In some implementations, the source/drain regions 204a and 204b include different dopant types. For example, the source/drain region 204a may include silicon doped with one or more p-type dopants, and the source/drain region 204b may include silicon doped with one or more n-type dopants.

The integrated circuit device 108 may include a gate structure 206 that extends in the y-direction across the active region 202. The gate structure 206 may be included above the active region 202 and/or may wrap around one or more sides of the active region 202. The gate structure 206 may be located laterally between the source/drain regions 204a and 204b. The source/drain region 204a may be located on a first side (e.g., laterally adjacent to the first side) of the gate structure 206, and the source/drain region 204b may be located on a second side (e.g., laterally adjacent to the second side) of the gate structure 206 opposing the first side. Thus, the source/drain region 204a, the gate structure 206, and the source/drain region 204b may be laterally arranged in the x-direction. The portion of the active region 202 under the gate structure 206 may be referred to as the channel region of the integrated circuit device 108.

In some implementations, the gate structure 206 includes a polysilicon gate. In some implementations, the gate structure 206 includes a metal gate and includes one or more metal materials such as tungsten (W), titanium (Ti), titanium aluminum (TiAl), and/or other suitable metal materials.

The integrated circuit device 108 includes a gate dielectric layer 208. The gate dielectric layer 208 may be included on the active region 202 (e.g., on the substrate 106 of the semiconductor device 100) such that the gate dielectric layer is located between the active region 202 and the gate structure 206. The gate dielectric layer 208 may provide electrical isolation between the gate structure 206 and the active region 202, which enables a voltage applied to the gate structure 206 to cause an electric field to be generated in the active region 202. The electric field modifies the electrical conductivity the active region 202, which selectively forms a conductive channel between the source/drain regions 204a and 204b.

As shown in FIG. 2A, the gate dielectric layer 208 is a composite gate dielectric layer in that the gate dielectric layer 208 includes a plurality of portions having different k-values. The different k-values of the plurality of portions may compensate for the subthreshold hump effect at edges of the active region 202 of the integrated circuit device 108 by tuning the threshold voltage (Vₜ) at the edges of the active region 202 and/or near the source/drain regions 204a and 204b. This enables a greater threshold voltage (Vₜ) uniformity across the active region 202 to be achieved for the integrated circuit device 108.

The plurality of portions of the gate dielectric layer 208 may be arranged in a grid that includes a plurality of columns 210a-210c arranged in the x-direction and extending in the y-direction, and a plurality of rows 212a-212c arranged in the y-direction and extending in the x-direction. The quantity of columns, rows, and portions illustrated in FIG. 2A is an example, and other quantities are within the scope of the present disclosure.

The row 212a may include portions 214, 216, and 218 of the gate dielectric layer 208. The row 212b may include portions 220, 222, and 224 of the gate dielectric layer 208. The row 212c may be located between the rows 212a and 212b in the y-direction and may include portions 226, 228, and 230. The rows 212a and 212b may be located at the outer edges of the active region 202 of the integrated circuit device 108, and the material compositions of the portions 214, 216, 218, 220, 222, and 224 included in the rows 212a and 212b may be selected for tuning the threshold voltage of the integrated circuit device 108 at the edges of the active region 202. The material compositions of the portions 226, 228, and 230 included in the row 212c may be selected for tuning the threshold voltage of the integrated circuit device 108 at the center of the active region 202.

The portions 214, 216, and 218 of the row 212a may be arranged in the x-direction, and the portion 216 may be located laterally between the portions 214 and 218 in the x-direction. The portions 220, 222, and 224 of the row 212b may be arranged in the x-direction, and the portion 222 may be located laterally between the portions 220 and 224 in the x-direction. The portions 226, 228, and 230 of the row 212c may be arranged in the x-direction, and the portion 228 may be located laterally between the portions 226 and 230 in the x-direction.

The column 210a may include portions 214, 220, and 226 of the gate dielectric layer 208. The column 210b may include portions 218, 224, and 230 of the gate dielectric layer 208. The column 210c may be located between the columns 210a and 210b in the x-direction and may include portions 216, 222, and 228. The columns 210a and 210b may be located at opposing ends of the channel region under the gate structure 206 of the integrated circuit device 108, and the material compositions of the portions 214, 218, 220, 224, 226, and 230 included in the columns 210a and 210b may be selected for tuning the threshold voltage of the integrated circuit device 108 at the ends of the channel region. The material compositions of the portions 216, 222, and 228 included in the column 210c may be selected for tuning the threshold voltage of the integrated circuit device 108 at the center of the channel region.

The portions 214, 220, and 226 of the column 210a may be arranged in the y-direction, and the portion 226 may be located laterally between the portions 214 and 220 in the y-direction. The portions 218, 224, and 230 of the column 210b may be arranged in the y-direction, and the portion 230 may be located laterally between the portions 218 and 224 in the y-direction. The portions 216, 222, and 228 of the column 210c may be arranged in the y-direction, and the portion 228 may be located laterally between the portions 216 and 222 in the y-direction.

Two or more of the portions 214-230 may have approximately the same k-value. For example, the portions 214, 218, 220, and 224 may have approximately the same k-value. These portions 214, 218, 220, 224 may include the same material or same material composition to achieve approximately the same k-value. For example, the portions 214, 218, 220, and 224 may each include silicon dioxide (SiO₂). As another example, the portions 214, 218, 220, and 224 may each include silicon nitride (SiₓN_{y} such as Si₃N₄). Similarly, the portions 216 and 222 may have approximately the same k-value and may include the same material or same material composition, and/or the portions 226 and 230 may have approximately the same k-value and may include the same material or same material composition.

The k-value of the portions 214, 218, 220, and 224 may be different from the k-value of the portions 226 and 230 to compensate for the field crowding and/or surface doping concentration at the edges of the active region 202. For example, the k-value of the portions 214, 218, 220, and 224 may be greater than the k-value of the portions 226 and 230. The greater k-value of the portions 214, 218, 220, and 224 provides for a higher threshold voltage (Vₜ) at the edges of the active region 202 than if the k-value of the portions 214, 218, 220, and 224 were approximately equal to the k-value of the portions 226 and 230, which provides for greater threshold voltage uniformity across the active region 202 in the y-direction than if the k-value of the portions 214, 218, 220, and 224 were approximately equal to the k-value of the portions 226 and 230. Thus, the portions 214, 218, 220, and 224 may be composed of a material (e.g., hafnium oxide (HfOₓ such as HfO₂)) having a higher k-value than the material of the portions 226 and 230 (e.g., silicon dioxide (SiO₂)).

Similarly, the k-value of the portions 216 and 222 may be different from the k-value of the portion 228 to compensate for the field crowding and/or surface doping concentration at the edges of the active region 202. For example, the k-value of the portions 216 and 222 may be greater than the k-value of the portion 228, which provides for greater threshold voltage uniformity across the active region 202 in the y-direction than if the k-value of the portions 216 and 222 were approximately equal to the k-value of the portion 228. Thus, the portions 216 and 222 may be composed of a material having a higher k-value than the material of the portion 228.

Along the x-direction (e.g., along the length of the channel region of the integrated circuit device 108), the k-value of the portions 214, 218, 220, and 224 may be different from the k-value of the portions 216 and 222 to compensate for the field crowding and/or surface doping concentration at the ends of the channel region. For example, the k-value of the portions 214, 218, 220, and 224 may be greater than the k-value of the portions 216 and 222. Thus, at the edges of the active region 202, which provides for greater threshold voltage uniformity across the channel region in the x-direction than if the k-value of the portions 214, 218, 220, and 224 were approximately equal to the k-value of the portions 216 and 222. Thus, the portions 214, 218, 220, and 224 may be composed of a material having a higher k-value than the material of the portions 216 and 222.

Similarly, the k-value of the portions 226 and 230 may be different from the k-value of the portion 228 to compensate for the field crowding and/or surface doping concentration at the ends of the channel region. For example, the k-value of the portions 226 and 230 may be greater than the k-value of the portion 228, which provides for greater threshold voltage uniformity across the channel region in the x-direction than if the k-value of the portions 226 and 230 were approximately equal to the k-value of the portion 228. Thus, the portions 226 and 230 may be composed of a material having a higher k-value than the material of the portion 228.

The arrangement of the portions of 214-230, the associated k-values, and the associated material compositions are an example, and other arrangements for the portions of 214-230, the associated k-values, and the associated material compositions are within the scope of the present disclosure. The portions of 214-230 of the gate dielectric layer 208 may include various dielectric materials to achieve a particular k-value layout for the gate dielectric layer 208, such as a silicon oxide (SiOₓ such as SiO₂), a silicon nitride (SiₓN_{y} such as Si₃N₄), a hafnium oxide (HfOₓ such as HfO₂), an aluminum oxide (AlₓO_{y} such as Al₂O₃), lanthanum oxide (LaₓO_{y} such as La₂O₃), tantalum oxide (TaₓO_{y} such as Ta₂O₅), a titanium oxide (TiOₓ such as TiO₂), strontium titanium oxide (SrTiOₓ such as SrTiO₃), hafnium silicon oxide (HfSiOₓ such as HfSiO₄), yttrium oxide (YₓO_{y} such as Y₂O₃), and/or zirconium oxide (ZrOₓ such as ZrO₂), among other examples. In some implementations, one or more of the portions 214-230 include an oxide material that includes two or more of hafnium (Hf), titanium (Ti), lanthanum (La), silicon (Si), and/or zirconium (Zr). Examples of such dielectric materials include hafnium titanium oxide (HfₓTi_{y}O_{z}), hafnium lanthanum oxide (HfₓLa_{y}O_{z}), hafnium silicon oxide (HfₓSi_{y}O_{z}), and/or hafnium zirconium oxide (HfₓZr_{y}O_{z}), among other examples.

As further shown in FIG. 2A, one or more contact structures 112a (e.g., source/drain contact(s)) may be included on the source/drain region 204a such that the one or more contact structures 112a are electrically connected and/or physically connected with the source/drain region 204a. One or more contact structures 112b (e.g., source/drain contact(s)) may be included on the source/drain region 204b such that the one or more contact structures 112b are electrically connected and/or physically connected with the source/drain region 204b. One or more contact structures 112c (e.g., gate contact(s)) may be included on the gate structure 206 such that the one or more contact structures 112c are electrically connected and/or physically connected with the gate structure 206.

As shown in FIGS. 2B and 2C, the active region 202 of the integrated circuit device 108 may be included in the substrate 106 of the semiconductor device 100. The source/drain regions 204a and 204b may be included in the substrate 106, the gate structure 206 may be included above the substrate 106, and the gate dielectric layer 208 (and the portions 214-230 included therein) may be included between the gate structure 206 and the substrate 106.

As further shown in FIGS. 2B and 2C, an isolation region 232 (e.g., an STI region, a LOCOS region) may be included in the substrate 106 on one or more sides of the active region 202. In some implementations, the isolation region 232 is formed in a trench in the substrate 106 such that the isolation region 232 laterally surrounds the active region 202 and provides a continuous isolation barrier around the active region 202. The isolation region 232 may include a dielectric material such as a silicon oxide (SiOₓ), a silicon nitride (SiₓN_{y}), a silicon oxynitride (SiON), fluoride-doped silicate glass (FSG), a low-k dielectric material, and/or other suitable insulating material. Additionally and/or alternatively, the isolation region 232 may include one or more doped regions of the substrate 106.

As shown in FIG. 2B, sidewall spacers 234 may be included over and/or on sidewalls of the gate structure 206. The sidewall spacers 234 may provide electrical isolation for the gate structure 206 and may reduce the likelihood of electrical shorting between the gate structure 206 and the contact structures 112a and/or 112b. The sidewall spacers 234 may include one or more electrically insulating materials such as a silicon oxycarbide (SiOC), a nitrogen free SiOC, and/or another suitable material.

As further shown in FIG. 2B, the dielectric layer 110 may be included over the integrated circuit device 108. The contact structures 112a and 112b may extend through the dielectric layer 110 and to the source/drain regions 204a and 204b, respectively. Metal silicide layers 236a and 236b may be included on the source/drain regions 204a and 204b of the integrated circuit device 108, respectively. The metal silicide layers 236a and 236b may each include a titanium silicide (TiSi), a ruthenium silicide (RuSi), and/or another type of metal silicide material. The metal silicide layers 236a and 236b provide a transition between the semiconductor material of the source/drain regions 204a and 204b and metal material of the contact structures 112a and 112b that are respectively formed on the source/drain regions 204a and 204b. The metal silicide layers 236a and 236b enable a low contact resistance to be achieved between the contact structures 112a, 112b and the source/drain regions 204a, 204b.

As shown in FIG. 2C, the gate structure 206 may extend along the substrate 106 and over one or more sections of the isolation region 232 in the y-direction. The contact structure 112c may extend through the dielectric layer 110 and may be in electrical contact and/or physical contact with the gate structure 206.

As further shown in FIG. 2C, the portions 214 and 220 of the gate dielectric layer 208 may be located over edge portions 238 of the active region 202 in the y-direction, and the portion 226 of the gate dielectric layer 208 may be located over a central portion 240 of the active region 202. The material of the portions 214 and 220 may be selected such that the portions 214 and 220 have a particular k-value for tuning the threshold voltage of the integrated circuit device 108 in the edge portions 238. The material of the portions 216, 218, 222, and 224 (not shown in the cross-section in FIG. 2C) may similarly be selected such that the portions 216, 218, 222, and 224 have k-values for tuning the threshold voltage of the integrated circuit device 108 in the edge portions 238. The material of the portion 226 may be selected such that the portion 226 has a particular k-value for tuning the threshold voltage of the integrated circuit device 108 in the central portion 240. The material of the portions 228 and 230 (not shown in the cross-section in FIG. 2C) may similarly be selected such that the portions 228 and 230 have k-values for tuning the threshold voltage of the integrated circuit device 108 in the central portion 240.

As indicated above, FIGS. 2A-2C are provided as an example. Other examples may differ from what is described with regard to FIGS. 2A-2C.

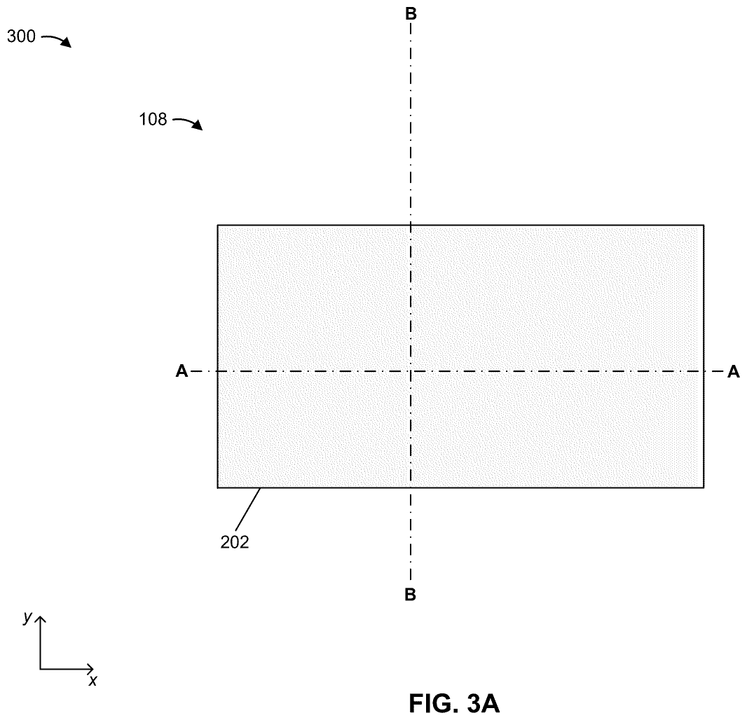

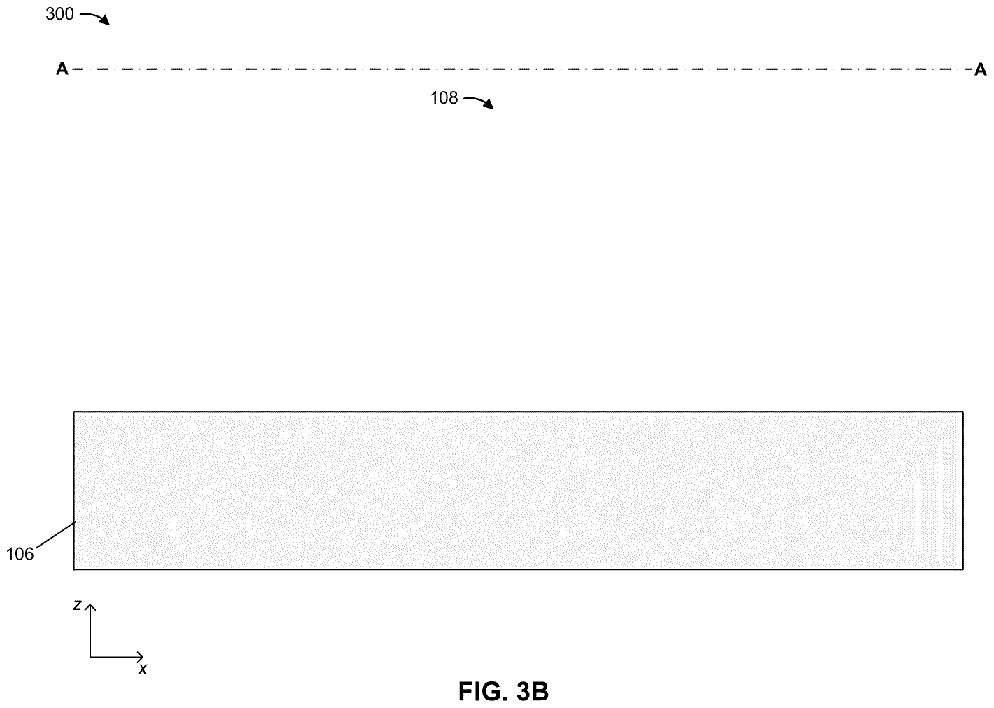

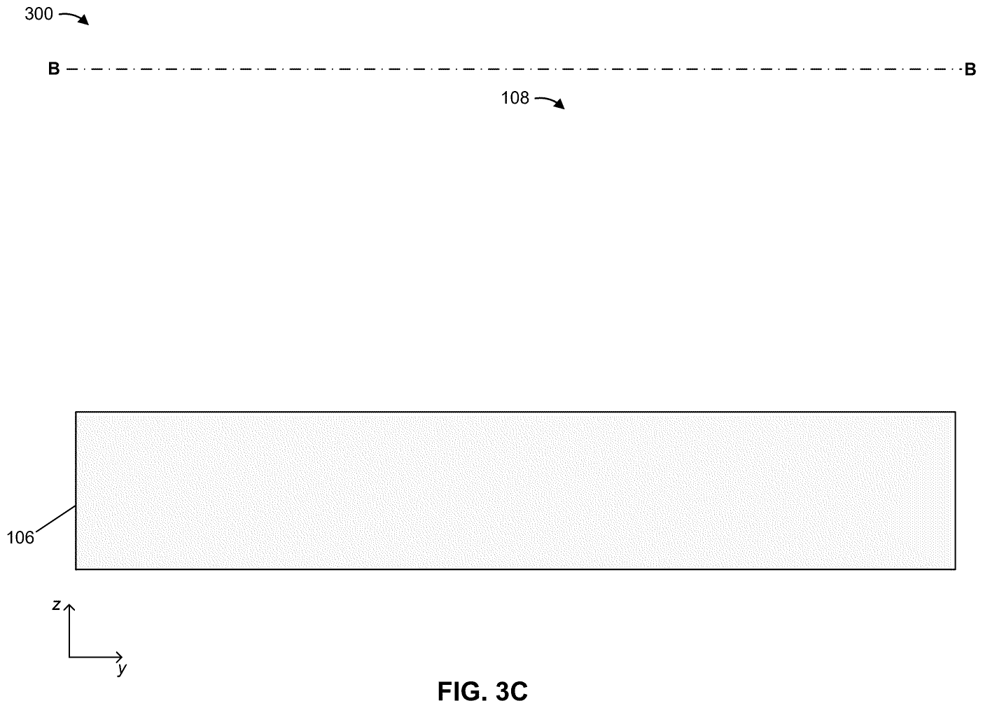

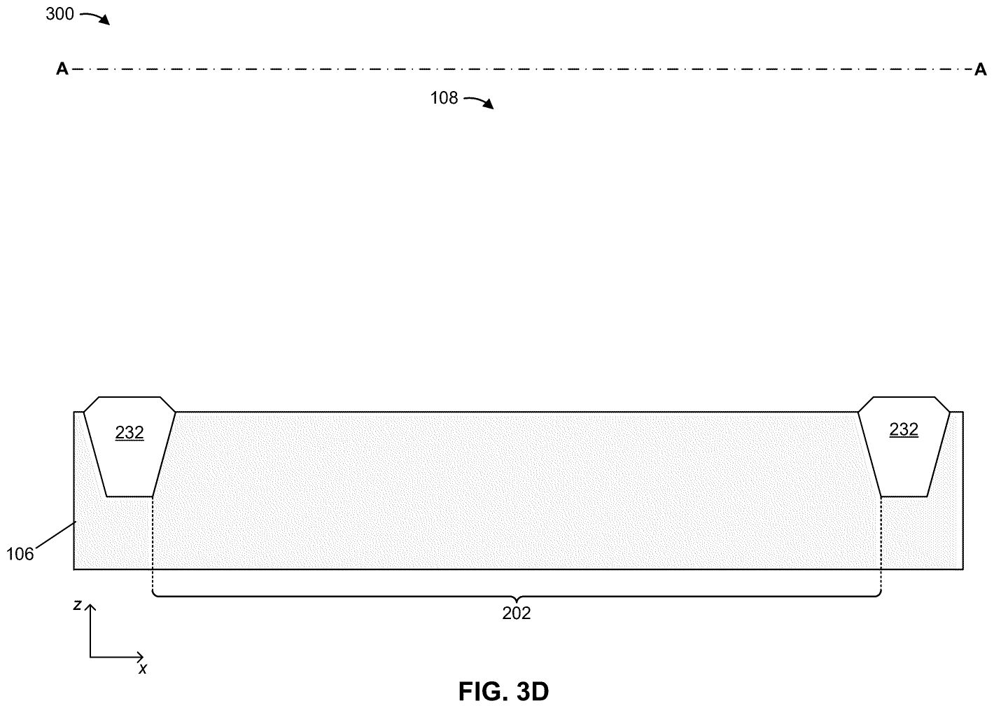

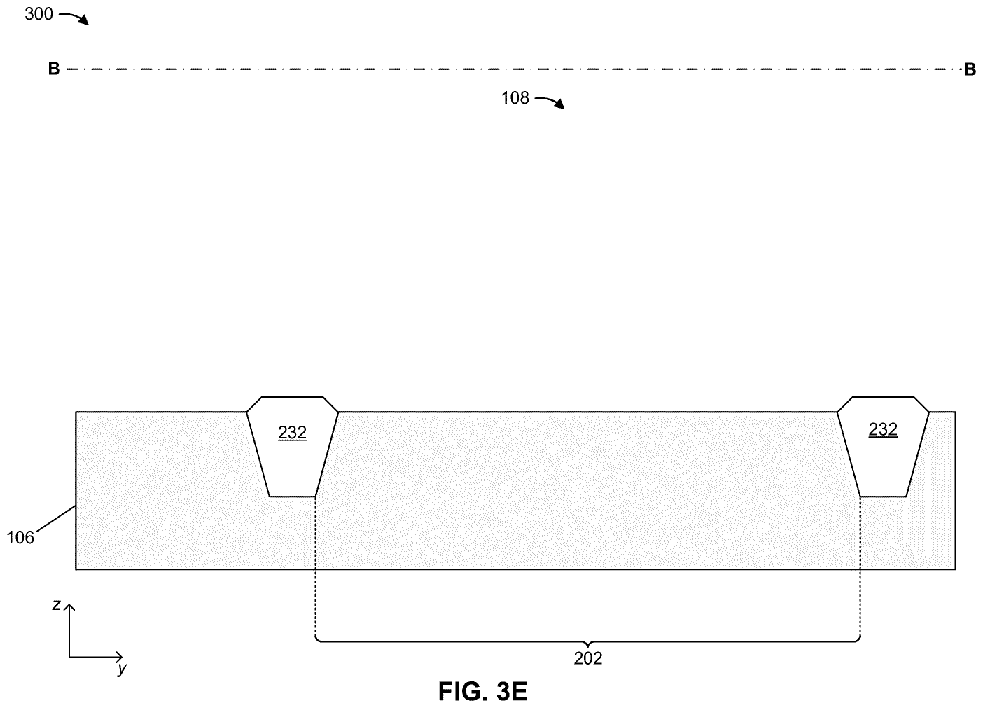

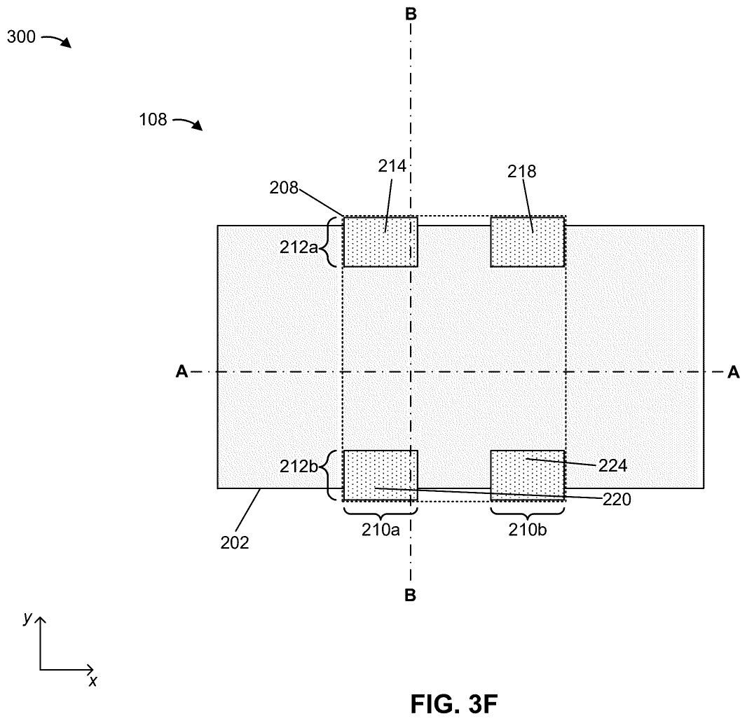

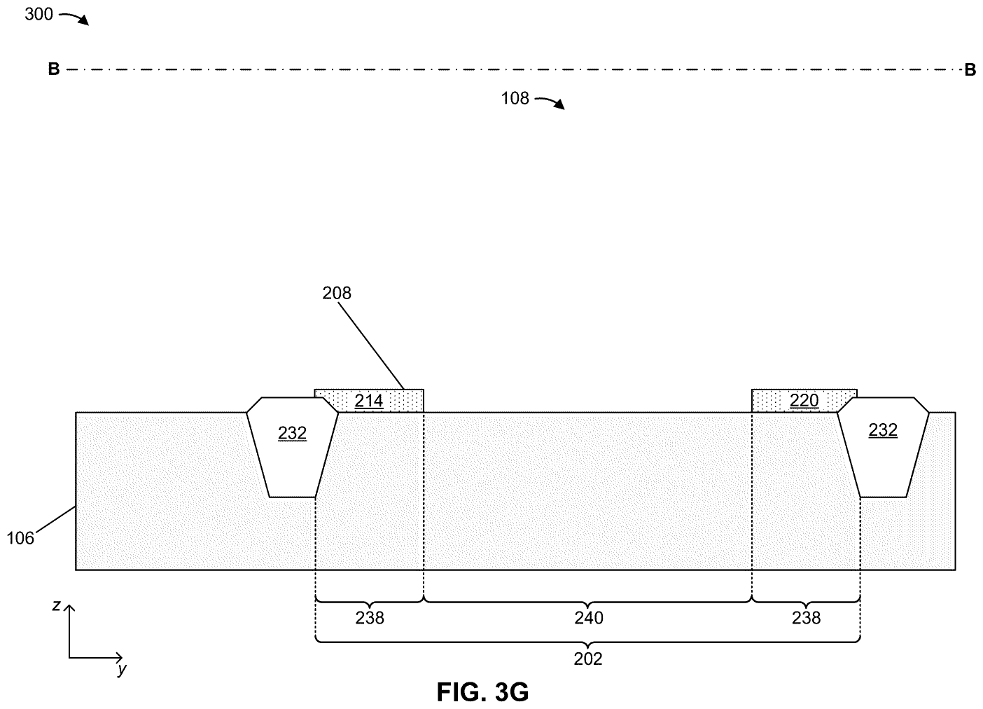

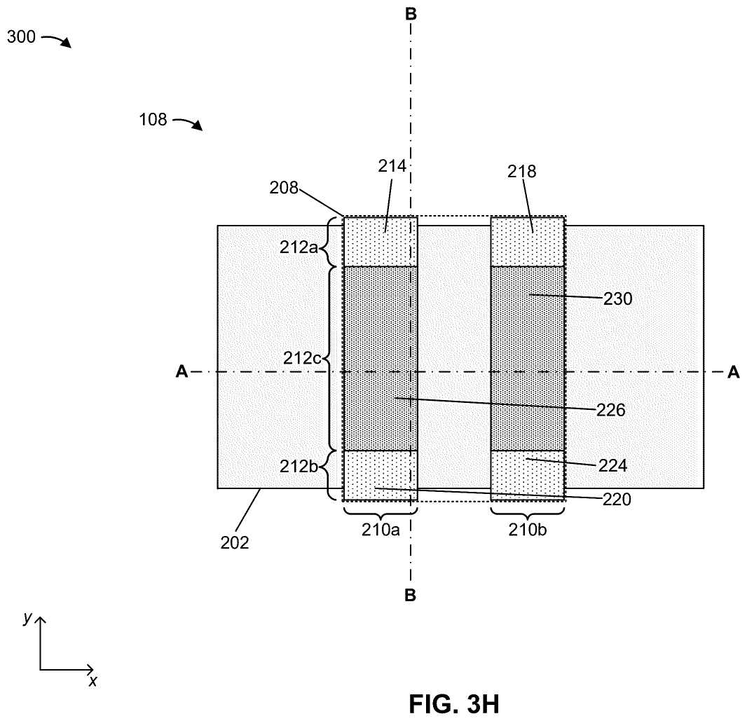

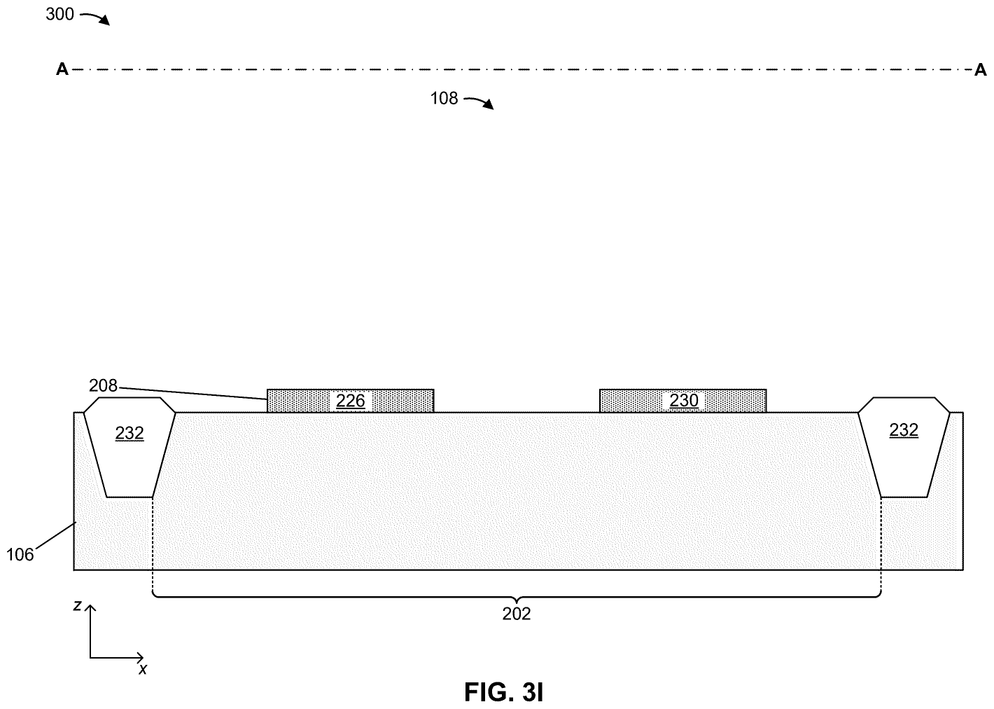

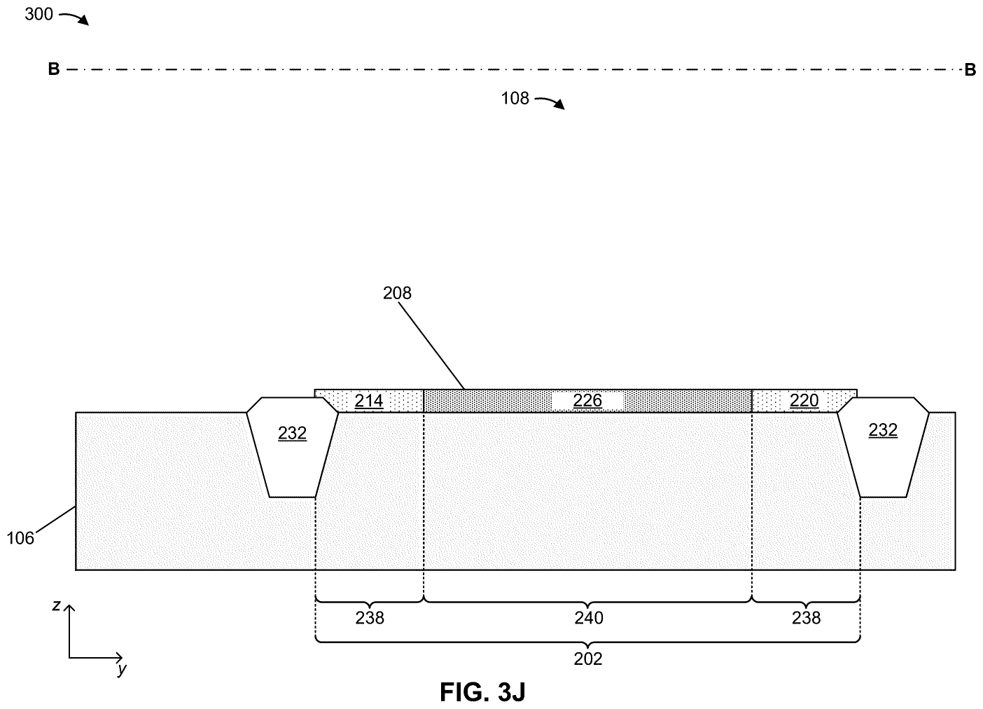

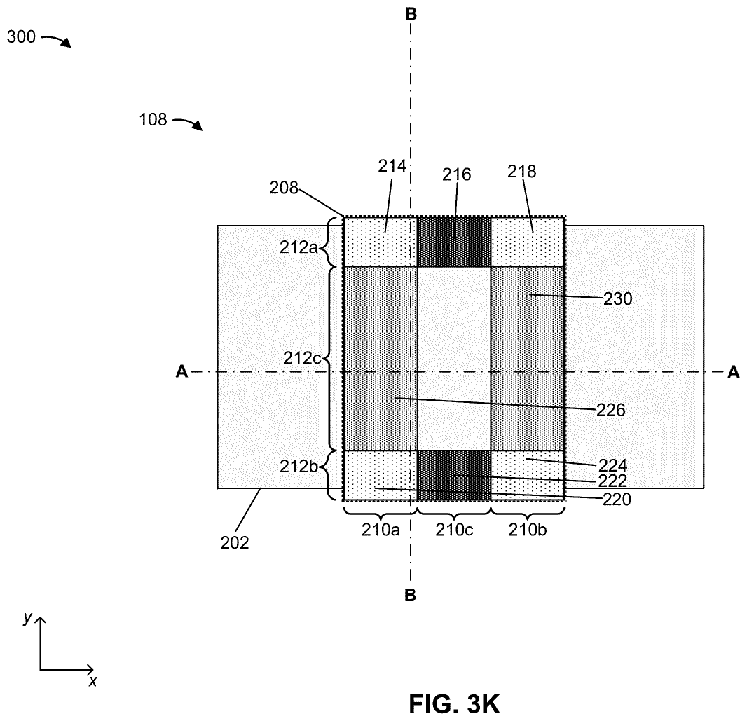

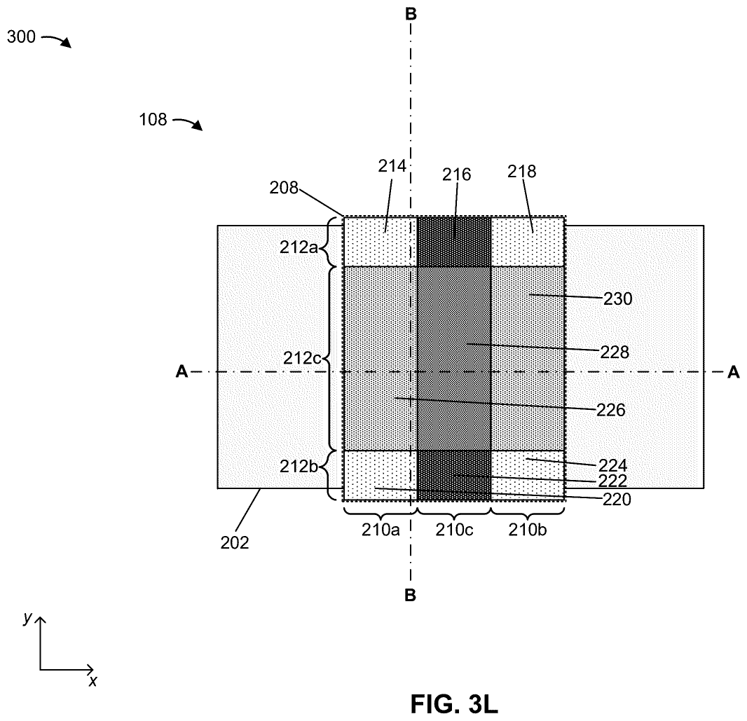

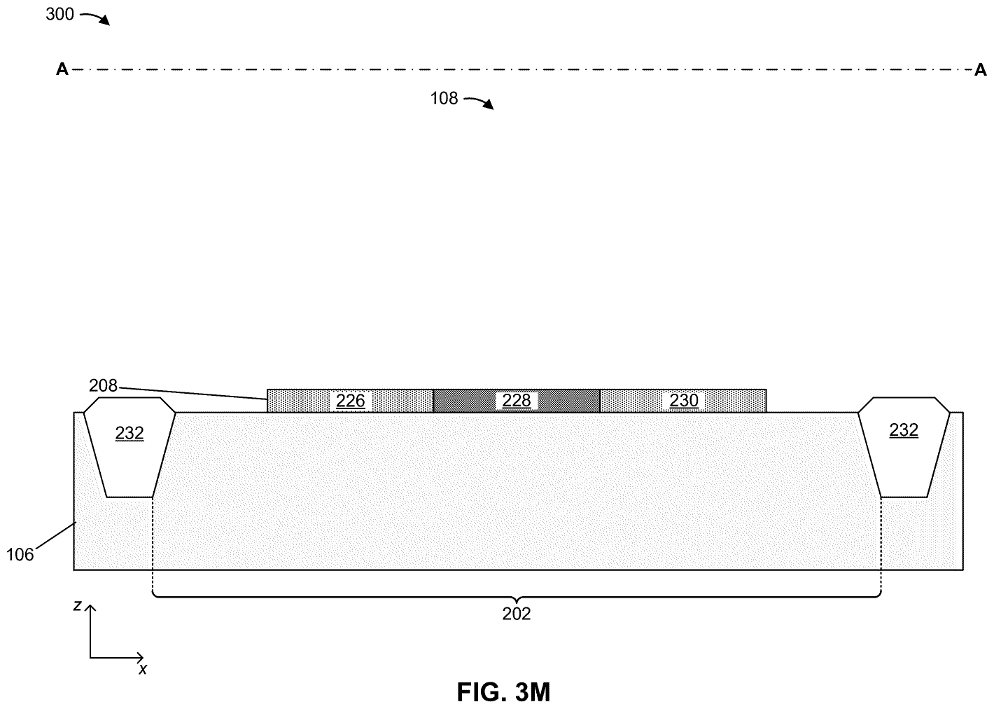

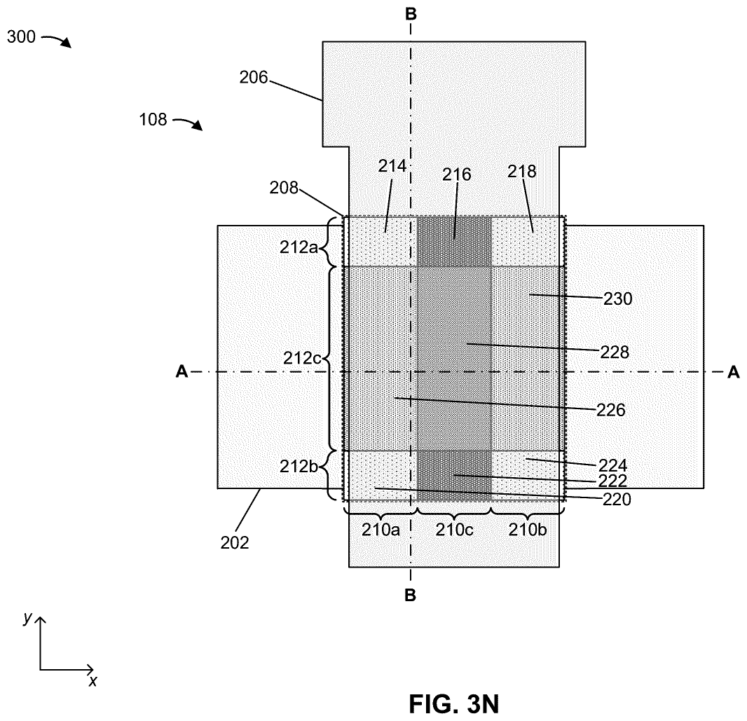

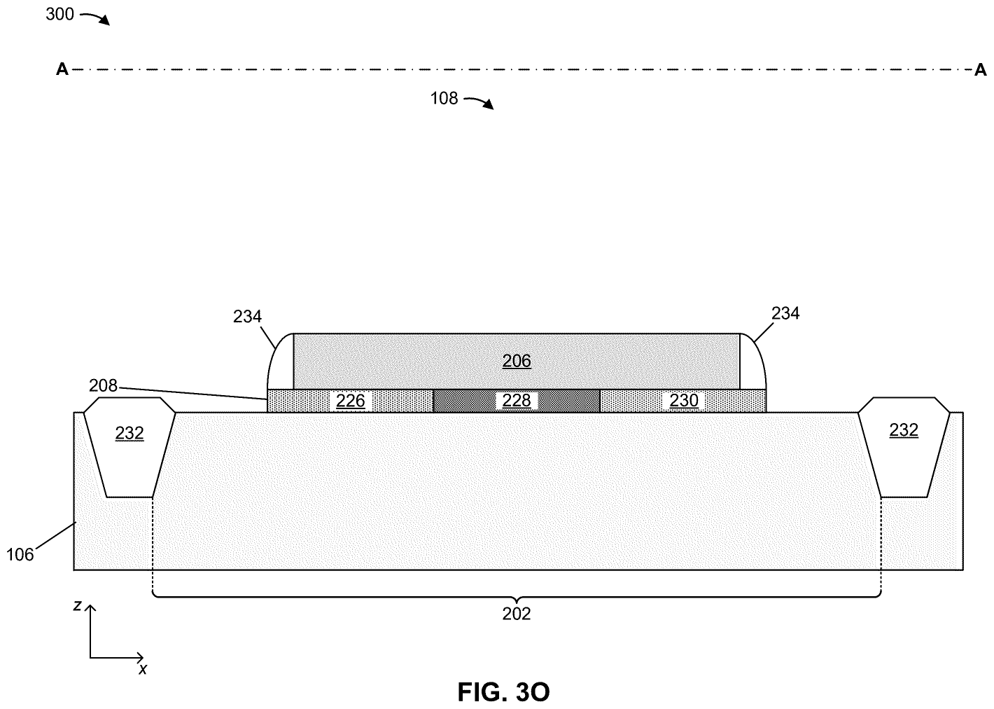

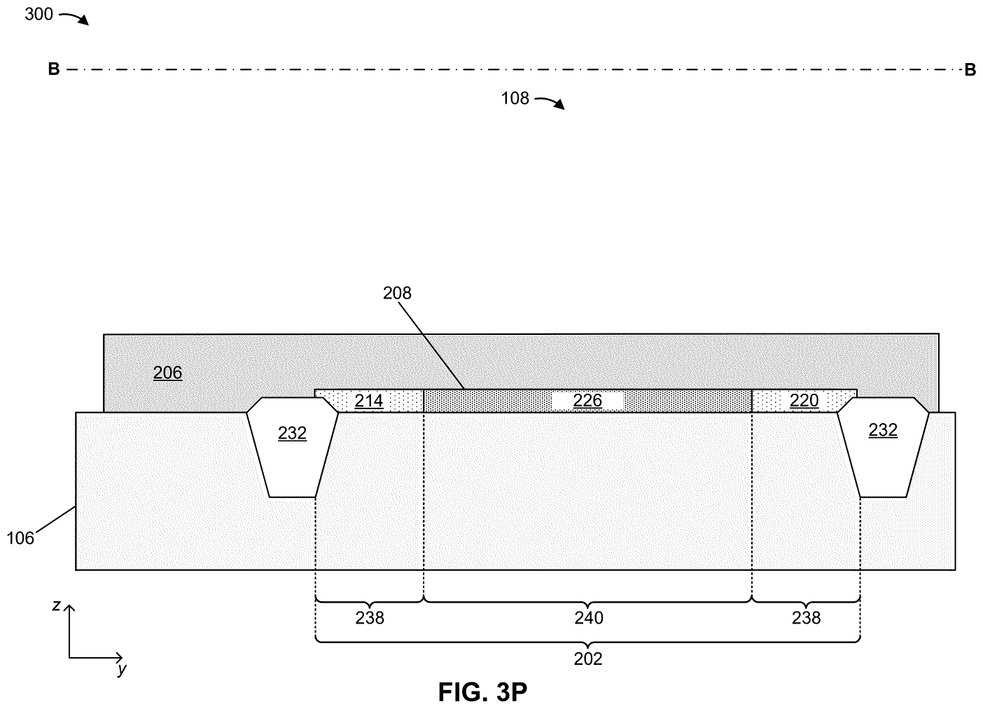

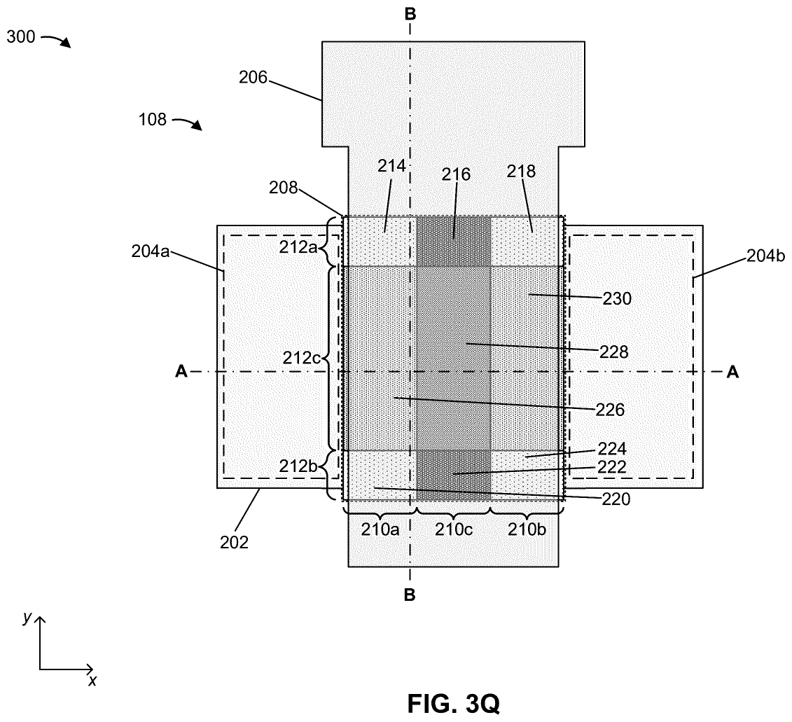

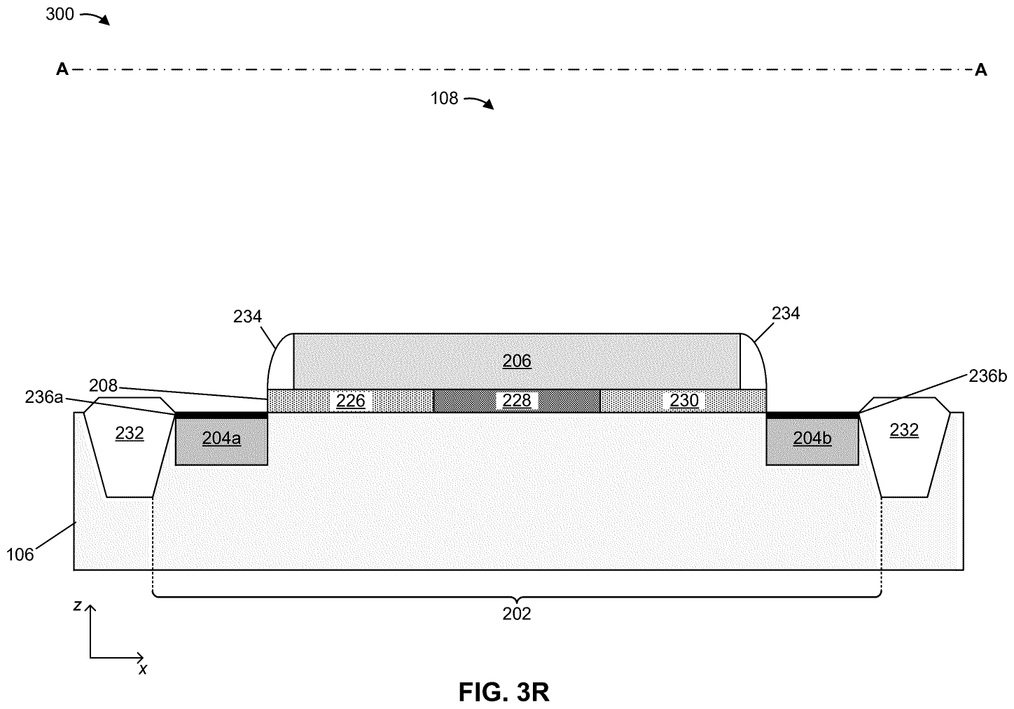

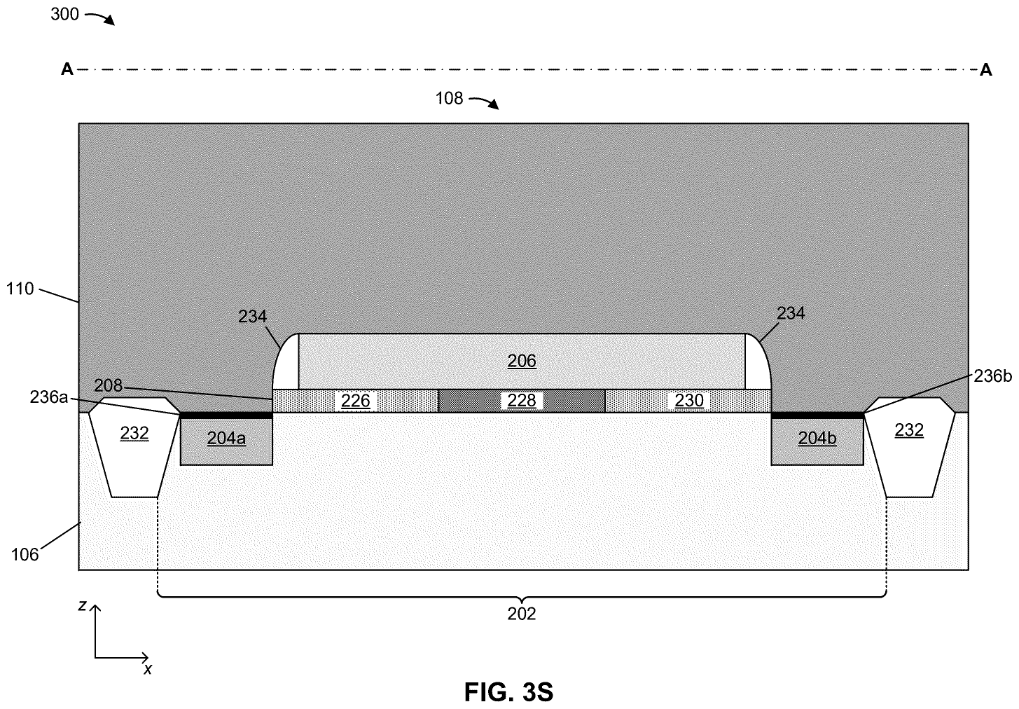

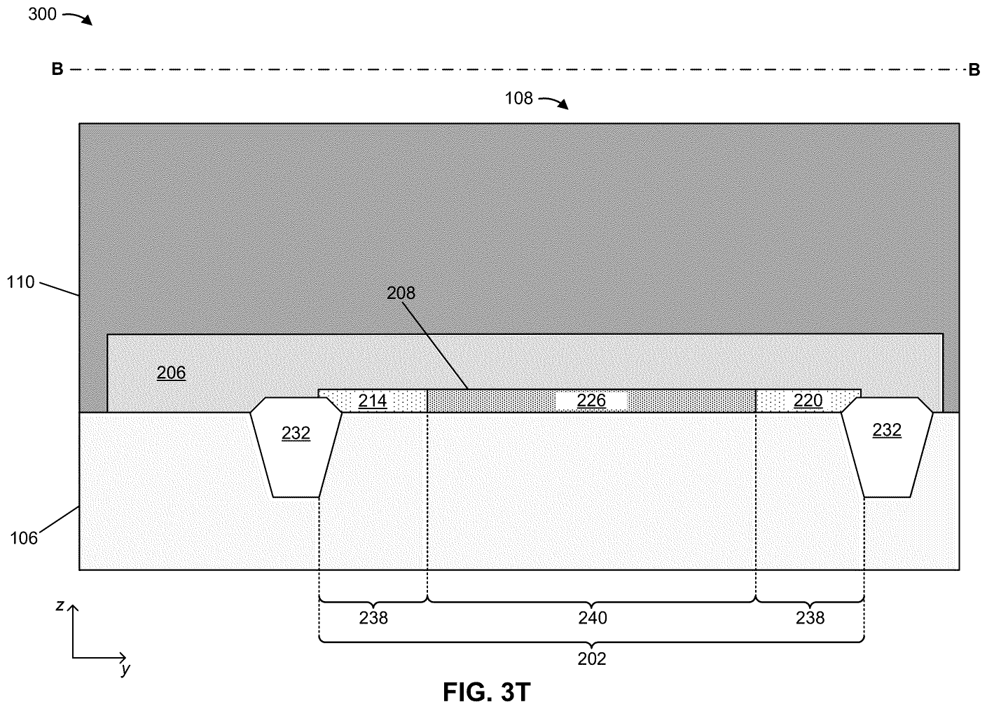

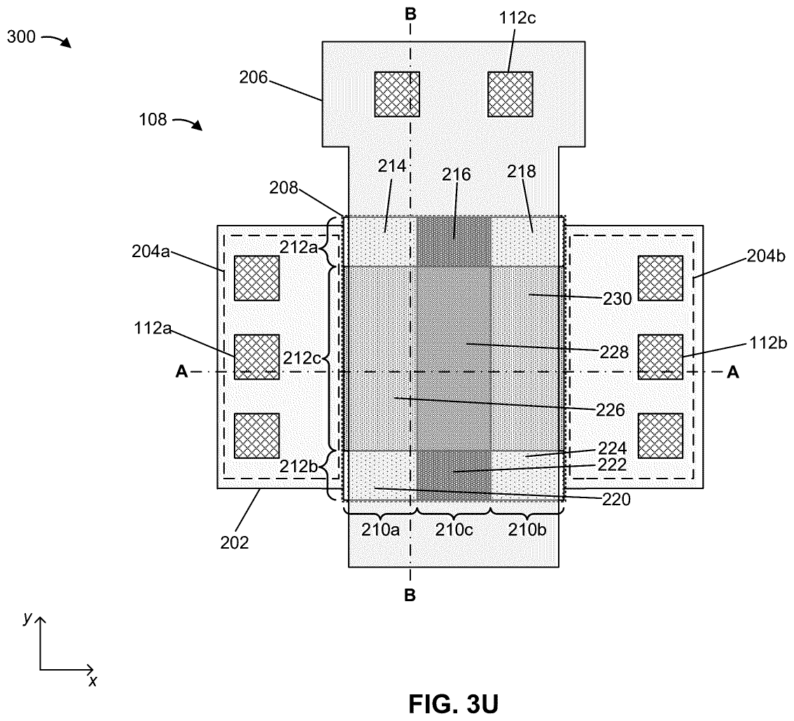

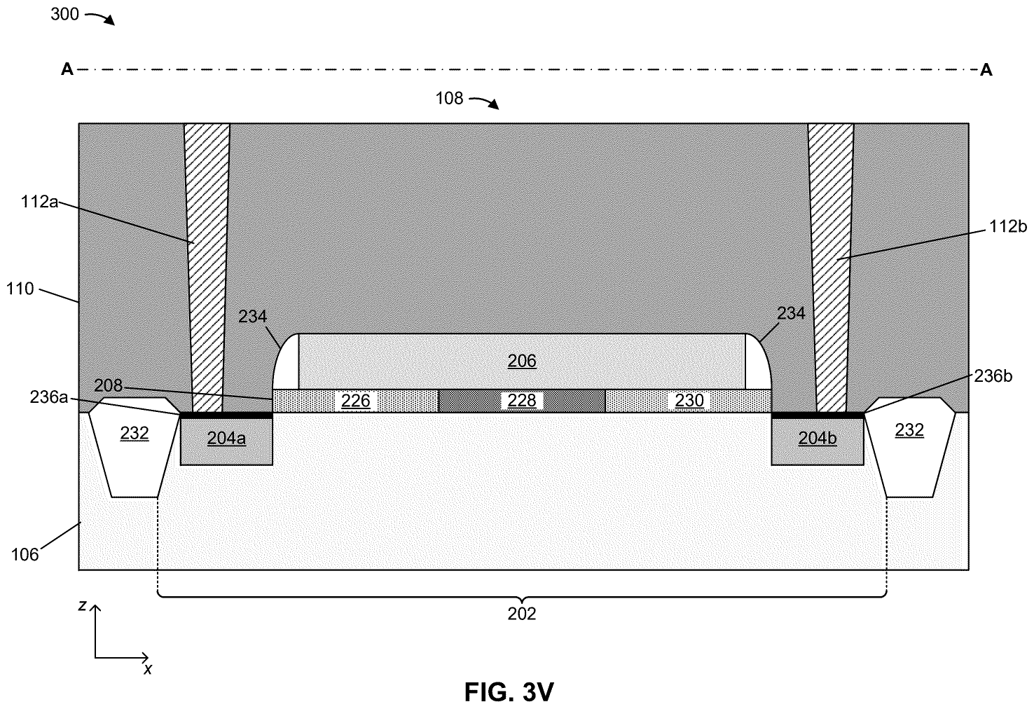

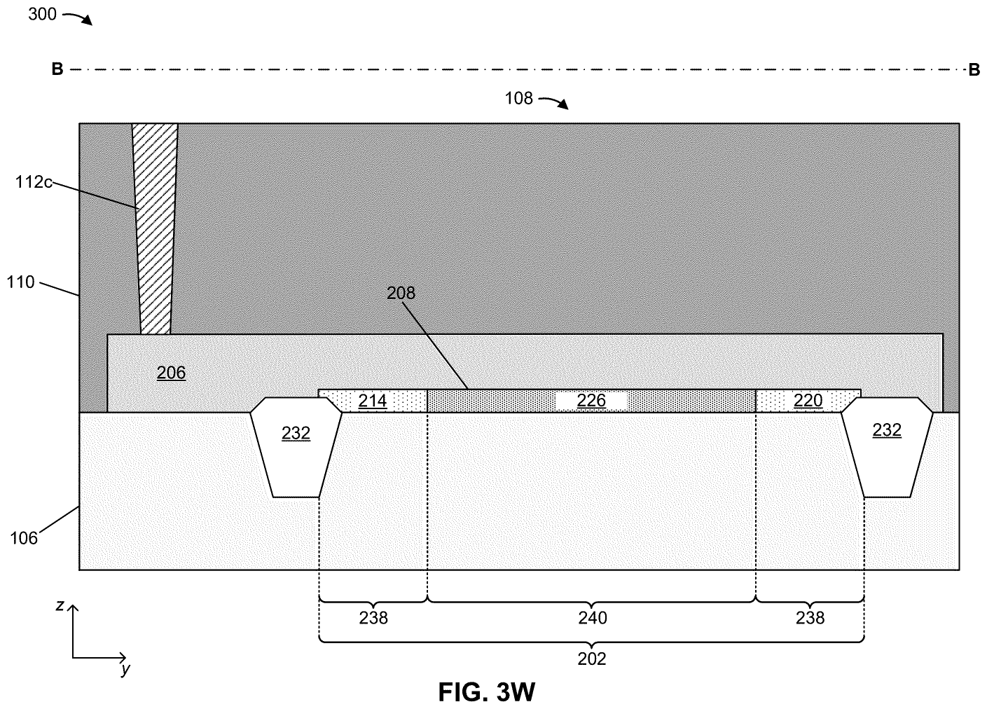

FIGS. 3A-3W are diagrams of an example implementation 300 of forming an integrated circuit device 108 that includes a composite gate dielectric layer 208 described herein. In some implementations, one or more of the operations described in connection may be performed using one or more semiconductor processing tools, such as a deposition tool, an exposure tool, a developer tool, an etch tool, an ion implantation tool, a planarization tool, and/or another suitable semiconductor processing tool.

Turning to FIGS. 3A-3C, one or more of the operations in the example implementation 300 may be performed in connection with the substrate 106 of the semiconductor device 100. The substrate 106 may be provided in the form of a semiconductor wafer or another type of substrate.

As shown in FIGS. 3D and 3E, the isolation region 232 may be formed in the substrate 106. The isolation region 232 may define the active region 202 of the integrated circuit device 108. In some implementations, a recess may be formed in the substrate 106, and the isolation region 232 may be formed in the recess.

In some implementations, a pattern in a photoresist layer is used to etch the substrate 106 to form the recess. In these implementations, a deposition tool may be used to form the photoresist layer on the substrate 106 (e.g., using a spin-coating technique and/or another suitable deposition technique). An exposure tool may be used to expose the photoresist layer to a radiation source to pattern the photoresist layer. A developer tool may be used to develop and remove portions of the photoresist layer to expose the pattern. An etch tool may be used to etch the substrate 106 based on the pattern to form the recess. In some implementations, the etch operation includes a dry etch operation (e.g., a plasma-based etch operation, a gas-based etch operation), a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the substrate 106 based on a pattern. A deposition tool may be used to deposit the isolation region 232 in the recess using a physical vapor deposition (PVD) technique, an atomic layer deposition (ALD) technique, a chemical vapor deposition (CVD) technique, an oxidation technique, and/or another suitable deposition technique.

Alternative, one or more regions of the substrate 106 may be doped to form the isolation region 232. An ion implantation tool may be used to perform an ion implantation operation to implant dopants into the substrate 106 to form the isolation region 232.

As shown in FIGS. 3F and 3G, the portions 214, 218, 220, and/or 224 of the gate dielectric layer 208 may be formed above the active region 202 of the substrate 106. In some implementations, a layer of dielectric material is deposited above the substrate 106, a patterned masking layer (e.g., a photoresist layer, a hard mask layer) may be formed on the layer of dielectric material, and the layer of dielectric material may be etched to form the portions 214, 218, 220, and/or 224 of the gate dielectric layer 208. In some implementations, a patterned masking layer is formed on the substrate 106, and the portions 214, 218, 220, and/or 224 of the gate dielectric layer 208 are deposited based on the pattern in the masking layer.

The portions 214, 218, 220, and/or 224 may be formed at the edge portions 238 of the active region 202. Moreover, two or more of the portions 214, 218, 220, and/or 224 may be formed of a same dielectric material and may have approximately a same k-value.

As shown in FIGS. 3H-3J, the portions 226 and/or 230 of the gate dielectric layer 208 may be formed above the active region 202 of the substrate 106. In some implementations, a layer of dielectric material is deposited above the substrate 106, a patterned masking layer (e.g., a photoresist layer, a hard mask layer) may be formed on the layer of dielectric material, and the layer of dielectric material may be etched to form the portions 226 and/or 230 of the gate dielectric layer 208. In some implementations, a patterned masking layer is formed on the substrate 106, and the portions 226 and/or 230 of the gate dielectric layer 208 are deposited based on the pattern in the masking layer.

The portions 226 and/or 230 may be formed at the central portion 240 of the active region 202. Moreover, the portions 226 and 230 may be formed of a same dielectric material and may have approximately a same k-value. The portion 226 may be formed such that the portion 226 is laterally between the portions 214 and 220 in the y-direction. The portion 230 may be formed such that the portion 230 is laterally between the portions 218 and 224 in the direction. In some implementations, the portions 226 and/or 230 may be formed after the portions 214, 218, 220, and/or 224. In some implementations, the portions 214, 218, 220, and/or 224 may be formed after the portions 226 and/or 230.

As shown in FIG. 3K, the portions 216 and 222 of the gate dielectric layer 208 may be formed above the active region 202 of the substrate 106. In some implementations, a layer of dielectric material is deposited above the substrate 106, a patterned masking layer (e.g., a photoresist layer, a hard mask layer) may be formed on the layer of dielectric material, and the layer of dielectric material may be etched to form the portions 216 and/or 222 of the gate dielectric layer 208. In some implementations, a patterned masking layer is formed on the substrate 106, and the portions 216 and/or 222 of the gate dielectric layer 208 are deposited based on the pattern in the masking layer.

The portions 216 and/or 222 may be formed at the edge portions 238 of the active region 202. Moreover, the portions 216 and 222 may be formed of a same dielectric material and may have approximately a same k-value. The portion 216 may be formed such that the portion 216 is laterally between the portions 214 and 218 in the x-direction. The portion 222 may be formed such that the portion 222 is laterally between the portions 220 and 224 in the x-direction. In some implementations, the portions 216 and/or 218 may be formed after the portions 214, 218, 220, 224, 226, and/or 230. In some implementations, the portions 214, 218, 220, 224, 226, and/or 230 may be formed after the portions 216 and/or 222.

As shown in FIGS. 3L and 3M, the portion 228 of the gate dielectric layer 208 may be formed above the active region 202 of the substrate 106. In some implementations, a layer of dielectric material is deposited above the substrate 106, a patterned masking layer (e.g., a photoresist layer, a hard mask layer) may be formed on the layer of dielectric material, and the layer of dielectric material may be etched to form the portion 228 of the gate dielectric layer 208. In some implementations, a patterned masking layer is formed on the substrate 106, and the portion 228 of the gate dielectric layer 208 is deposited based on the pattern in the masking layer.

The portion 228 may be formed at the central portion 240 of the active region 202. The portion 228 may be formed such that the portion 228 is laterally between the portions 216 and 222 in the y-direction. Moreover, the portion 228 may be formed such that the portion 228 is laterally between the portions 226 and 230 in the x-direction. In some implementations, the portion 228 may be formed after the portions 214, 216, 218, 220, 222, 224, 226, and/or 230. In some implementations, the portions 214, 216, 218, 220, 222, 224, 226, and/or 230 may be formed after the portion 228.

As shown in FIGS. 3N-3P, the gate structure 206 may be formed over the gate dielectric layer 208. The gate structure 206 may extend along the substrate 106 in the y-direction. A deposition tool may be used to deposit a layer of material for the gate structure 206 using a PVD technique, a CVD technique, and ALD technique, and electroplating technique, and/or another suitable deposition technique. The layer of material may be etched (e.g., using an etch tool) to define the gate structure 206.

In some implementations, a dummy gate structure is formed in place of the gate structure 206. In these implementations, the dummy gate structure may be removed after formation of source/drain regions of the integrated circuit device 108. This may be referred to as a gate replacement process. The gate structure 206 may be formed in the space left behind after removal of the dummy gate structure.

Sidewall spacers 234 may be deposited (e.g., using a deposition tool) using a CVD technique, an ALD technique, a PVD technique, and/or another type of deposition technique. In some implementations, a sidewall spacer layer is deposited on the sidewalls of the gate structure 206 and along the surface of the substrate 106. An etch tool may then be used to etch the sidewall spacer layer to define the sidewall spacers 234.

As shown in FIGS. 3Q and 3R, the source/drain region 204a and the source/drain region 204b may be formed in the substrate 106. The source/drain region 204a may be formed on a first side of the gate structure 206, and the source/drain region 204b may be formed on a second side of the gate structure 206 opposing the first side. Accordingly, the gate structure 206 is located laterally between the source/drain region 204a and the source/drain region 204b in the x-direction. This enables the gate structure 206 to selectively control the electrical conductivity of a channel region in the substrate 106 between the source/drain region 204a and the source/drain region 204b.

In some implementations, the source/drain region 204a and the source/drain region 204b may be formed by doping portions of the substrate 106. For example, a first portion of the substrate 106 may be doped with one or more types of dopants (e.g., n-type dopants, p-type dopants) to form the source/drain region 204a, and a second portion of the substrate 106 may be doped with one or more types of dopants (e.g., n-type dopants, p-type dopants) to form the source/drain region 204b. An ion implantation tool may be used to implant dopant ions into the first portion and/or into the second portion of the substrate 106 to form the source/drain region 204a and/or the source/drain region 204b. Additionally and/or alternatively, another doping technique may be used to form the source/drain region 204a and the source/drain region 204b such as diffusion.

In some implementations, the source/drain region 204a and the source/drain region 204b are formed by epitaxially growing the source/drain region 204a and the source/drain region 202b in recesses in the substrate 106. An etch tool may be used to etch the substrate 106 to form the recesses in the substrate 106. The etch operation may be referred to a strained source/drain (SSD) etch operation, and the recesses may be referred to as strained source/drain recesses. In some implementations, the etch operation includes a plasma etch technique, a wet chemical etch technique, and/or another type of etch technique.

A deposition tool may be used to form the source/drain region 204a and the source/drain region 204b in the recesses. The deposition tool may be used to form the source/drain region 204a and the source/drain region 204b by epitaxial growth, in which layers of the epitaxial material are deposited in the recesses such that the layers of semiconductor material are formed by epitaxial growth in a particular crystalline orientation.

The material (e.g., silicon (Si), gallium (Ga), or another type of semiconductor material) that is used to form the source/drain region 204a and the source/drain region 204b may be doped with a p-type dopant (e.g., a type of dopant that includes electron acceptor atoms that create holes in the material), with an n-type dopant (e.g., a type of dopant that includes electron donor atoms that create mobile electrons in the material), and/or with another type of dopant. The material may be doped by adding impurities (e.g., the p-type dopant, the n-type dopant) to a source gas that is used during the epitaxial operation. Examples of p-type dopants that may be used in the epitaxial operation include boron (B) or germanium (Ge), among other examples. Examples of n-type dopants that may be used in the epitaxial operation include phosphorous (P) or arsenic (As), among other examples.

As further shown in FIG. 3R, the metal silicide layers 236a and 236b may be respectively formed on the source/drain regions 204a and 204b. A salicidation process may be performed to form the metal silicide layers 236a and 236b. The salicidation process may include using a deposition tool to deposit a layer of metal material (e.g., titanium (Ti), cobalt (Co), ruthenium (Ru)) on the source/drain regions 204a and 204b, and then performing an annealing operation to cause the metal material to diffuse into the top surface of the source/drain regions 204a and 204b to form the metal silicide layers 236a and 236b. In some implementations, another technique is used to form the metal silicide layers 236a and 236b.

As shown in FIGS. 3S and 3T, the dielectric layer 110 may be formed over and/or on the integrated circuit device 108. A deposition tool may be used to deposit the dielectric layer 110 using a PVD technique, a CVD technique, an ALD technique, an oxidation technique, and/or another suitable deposition technique. In some implementations, a planarization tool is used to perform a chemical-mechanical planarization (CMP) operation to planarize the dielectric layer 110.

As shown in FIGS. 3U-3W, the contact structure(s) 112a may be formed over the source/drain region 204a such that the contact structure(s) 112a land on the metal silicide layer 236a on the source/drain region 204a. The contact structure(s) 112b may be formed over the source/drain region 204b such that the contact structure(s) 112b land on the metal silicide layer 236b on the source/drain region 204b. The contact structure(s) 112c may be formed over the gate structure 206 such that the contact structure(s) 112c lands on the gate structure 206.

The contact structures 112a-112c may be formed in recesses in the dielectric layer 110. For example, a recess may be formed over the source/drain region 204a to expose the metal silicide layer 236a on the source/drain region 204a through the recess. As another example, a recess may be formed over the source/drain region 204b to expose the metal silicide layer 236b on the source/drain region 204b through the recess. As another example, a recess may be formed over the gate structure 206 to expose the gate structure 206 through the recess.

In some implementations, a pattern in a photoresist layer is used to form the recesses in the dielectric layer 110. In these implementations, a deposition tool may be used to form the photoresist layer over the dielectric layer 110. An exposure tool may be used to expose the photoresist layer to a radiation source to pattern the photoresist layer. A developer tool may be used to develop and remove portions of the photoresist layer to expose the pattern. An etch tool may be used to etch through the dielectric layer 110 to form the recesses. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the recesses based on a pattern.

A deposition tool may be used to deposit the contact structures 112a-112c using a CVD technique, a PVD technique, an ALD technique, an electroplating technique, and/or another suitable deposition technique. The contact structures 112a-112c may be deposited in one or more deposition operations. In some implementations, a seed layer is first deposited, and the contact structures 112a-112c are deposited on the seed layer. In some implementations, a liner is deposited in the recesses, and the contact structures 112a-112c are deposited on the liner in the recesses. The liner may include a barrier liner, an adhesion liner, and/or another suitable liner. Examples of liner materials include tantalum nitride (TaN), titanium nitride (TiN), and/or other suitable liner materials. In some implementations, a planarization tool is used to perform a planarization operation (e.g., a CMP operation) to planarize the contact structures 112a-112c after the contact structures 112a-112c are deposited.

As indicated above, FIGS. 3A-3W are provided as an example. Other examples may differ from what is described with regard to FIGS. 3A-3W.

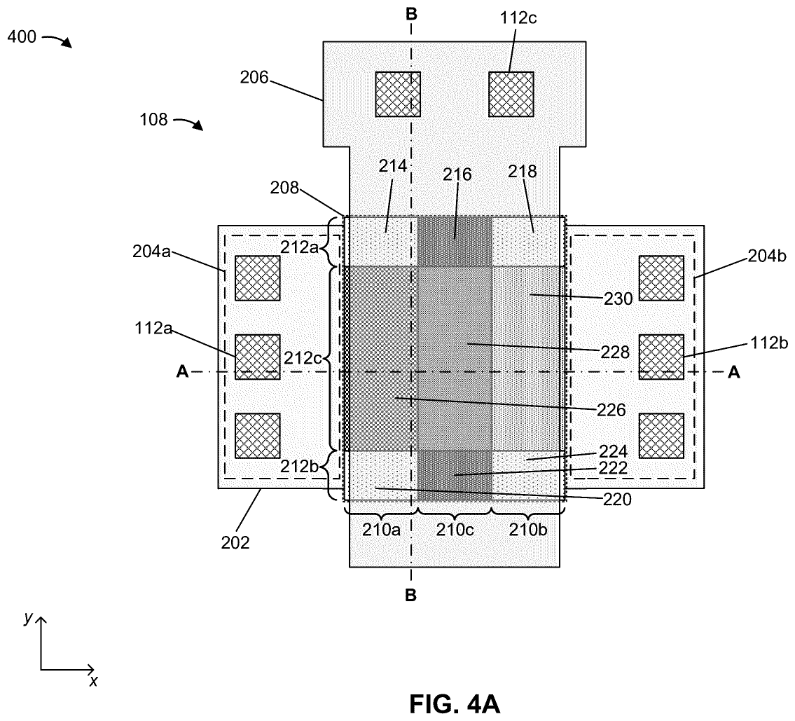

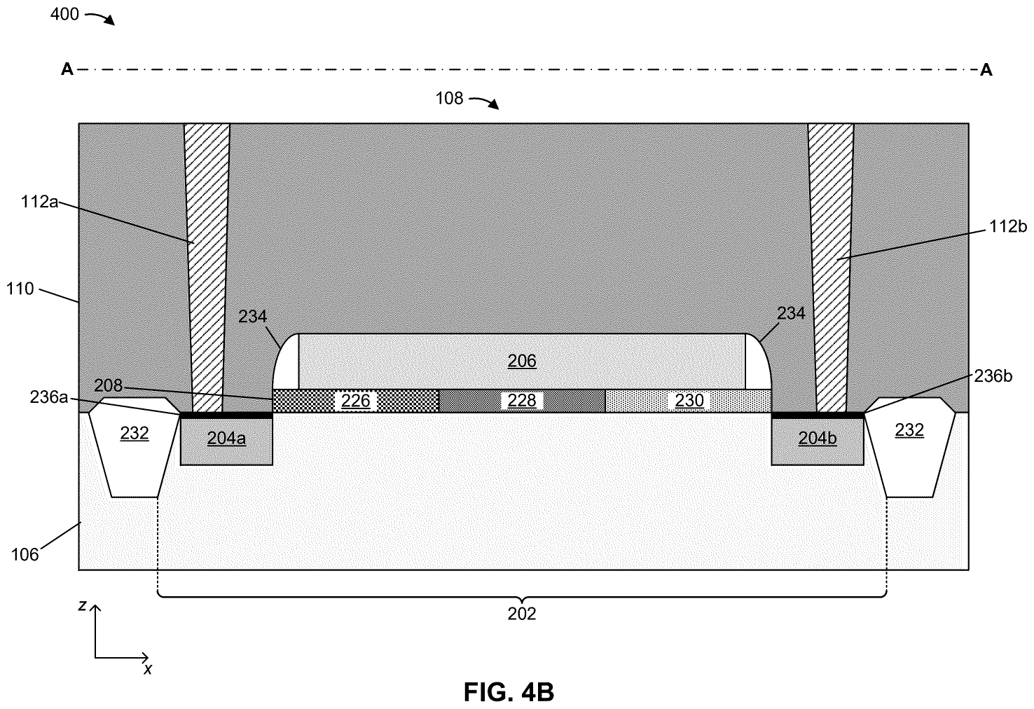

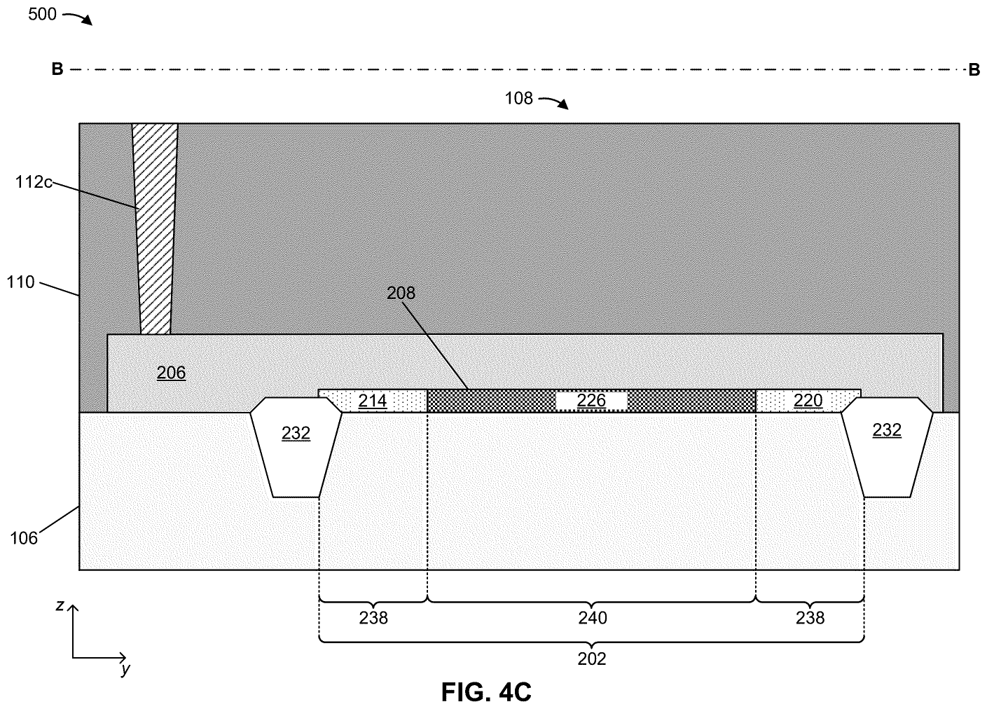

FIGS. 4A-4C are diagrams of an example implementation 400 of an integrated circuit device 108 described herein. In the example implementation 400, the integrated circuit device 108 includes a high-voltage transistor structure. FIG. 4A illustrates a top view of the integrated circuit device 108. FIG. 4B illustrates an example cross-section view of the integrated circuit device 108 along the line A-A in FIG. 4A (e.g., along the x-direction). FIG. 4C illustrates an example cross-section view of the integrated circuit device 108 along the line B-B in FIG. 4A (e.g., along the y-direction).

As shown in FIGS. 4A-4C, the example implementation 400 of the integrated circuit device 108 includes a similar combination and arrangement of layers and/or structures as the example implementation 200 of the integrated circuit device 108 in FIGS. 2A-2C. However, in the example implementation 400 of the integrated circuit device 108, the portion 226 of the gate dielectric layer 208 includes a material composition that is different from the material composition of the portion 230 of the gate dielectric layer 208. In the central portion of the active region 202, the threshold voltage may be asymmetric along the x-direction between the source/drain regions 204a and 204b. For example, the threshold voltage might otherwise be higher near the source/drain region 204a than near the source/drain region 204b if the gate dielectric layer 208 had a uniform k-value between the source/drain regions 204a and 204b. Accordingly, the material compositions of the portions 226 and 230 may be different such that the portions 226 and 230 have different k-values to compensate for an otherwise asymmetric threshold voltage to achieve a substantially unform threshold voltage between the source/drain regions 204a and 204b.

As indicated above, FIGS. 4A-4C are provided as an example. Other examples may differ from what is described with regard to FIGS. 4A-4C.

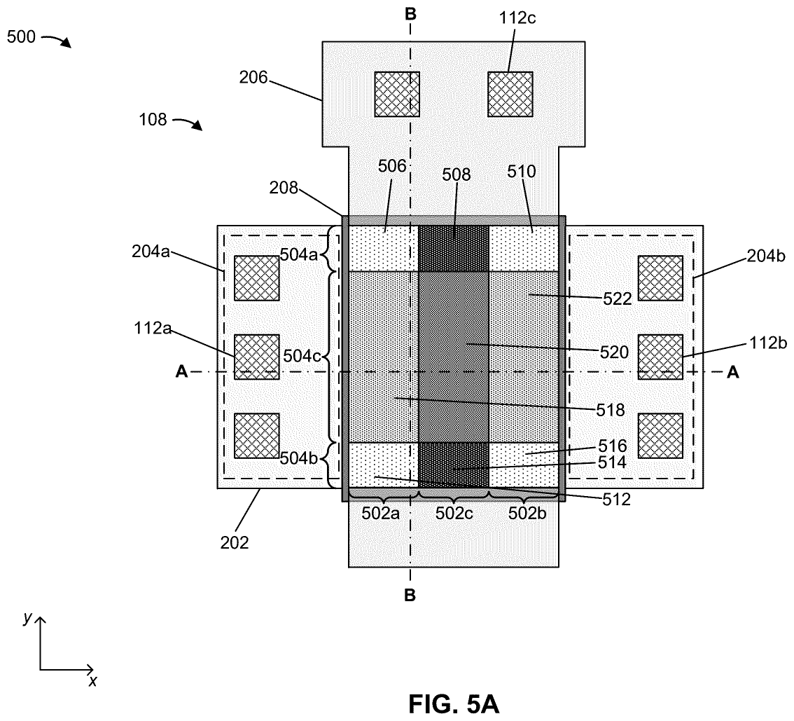

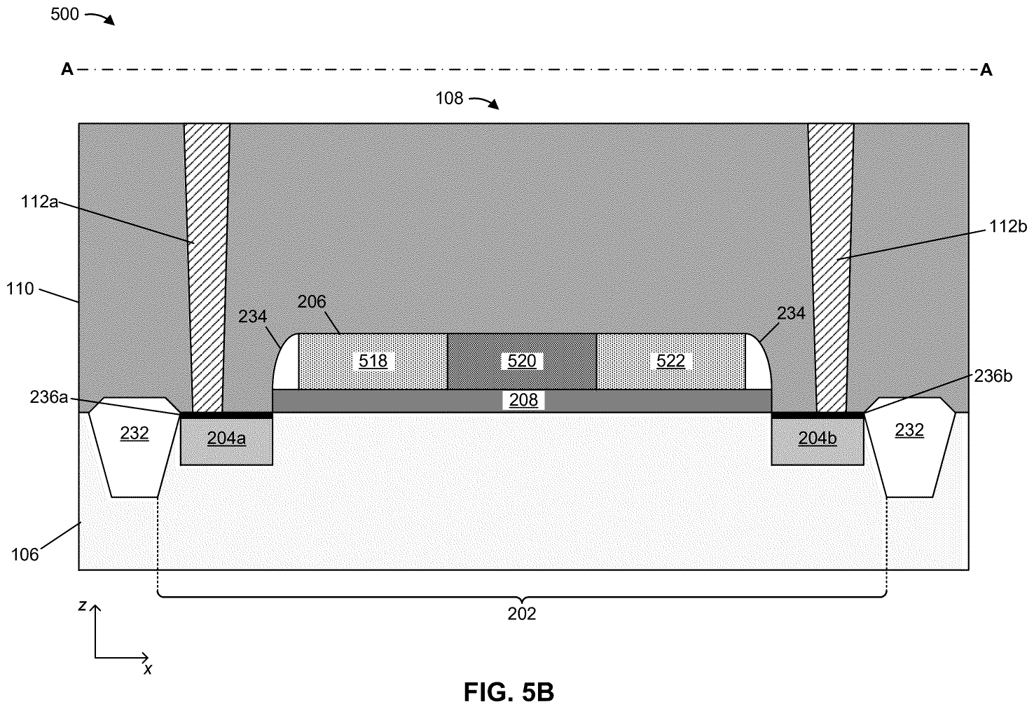

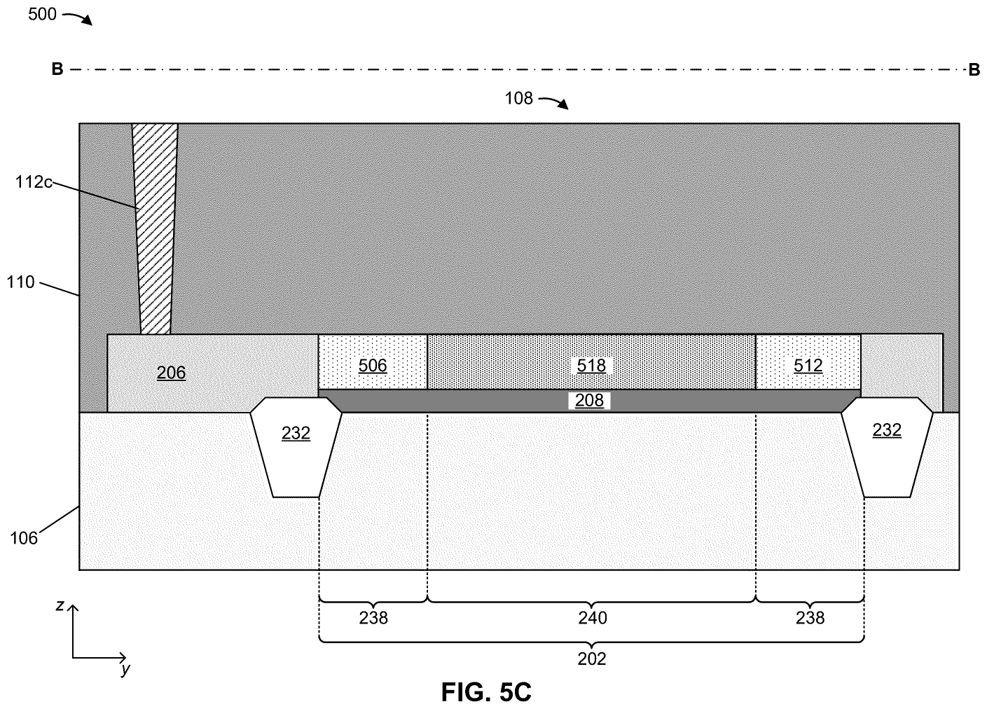

FIGS. 5A-5C are diagrams of an example implementation 500 of an integrated circuit device 108 described herein. In the example implementation 500, the integrated circuit device 108 includes a high-voltage transistor structure. FIG. 5A illustrates a top view of the integrated circuit device 108. FIG. 5B illustrates an example cross-section view of the integrated circuit device 108 along the line A-A in FIG. 5A (e.g., along an x-direction). FIG. 5C illustrates an example cross-section view of the integrated circuit device 108 along the line B-B in FIG. 5A (e.g., along a y-direction).

As shown in FIGS. 5A-5C, the example implementation 500 of the integrated circuit device 108 includes a similar combination and arrangement of layers and/or structures as the example implementation 200 of the integrated circuit device 108 in FIGS. 5A-5C. However, in the example implementation 500 of the integrated circuit device 108, the gate structure 206 is a composite gate structure as opposed to the gate dielectric layer 208 being a composite gate dielectric layer.

As shown in FIG. 5A, the gate structure 206 is a composite gate structure in that the gate structure 206 includes a plurality of doped regions having different work function values. A work function value may refer to a bandgap energy level (in electron-volts (eV)) of the gate structure 206. The threshold voltage of the integrated circuit device 108 may be based on the work function value of the gate structure 206 and the work function value of the substrate 106. The greater the difference between the work function of the gate structure 206 and the work function value of the substrate 106, the greater the threshold voltage of the integrated circuit device 108. Conversely, the lesser the difference between the work function of the gate structure 206 and the work function value of the substrate 106, the lesser the threshold voltage of the integrated circuit device 108. Thus, the gate structure 206 having a plurality of doped regions with different work function values may compensate for the subthreshold hump effect at edges of the active region 202 of the integrated circuit device 108 in that the work function values may be selected to tune the threshold voltage (Vₜ) at the edges of the active region 202 and/or near the source/drain regions 204a and 204b. This enables a greater threshold voltage (Vₜ) uniformity across the active region 202 to be achieved for the integrated circuit device 108.

The plurality of doped regions of the gate structure 206 may be arranged in a grid that includes a plurality of columns 502a-502c arranged in the x-direction and extending in the y-direction, and a plurality of rows 504a-504c arranged in the y-direction and extending in the x-direction. The quantity of columns, rows, and portions illustrated in FIG. 5A is an example, and other quantities are within the scope of the present disclosure.

The row 504a may include doped region 506, 508, and 510 of the gate structure 206. The row 504b may include doped regions 512, 516, and 518 of the gate structure 206. The row 504c may be located between the rows 504a and 504b in the y-direction and may include doped regions 518, 520, and 522. The rows 504a and 504b may be located at the outer edges of the active region 202 of the integrated circuit device 108, and the material compositions of the doped regions 506, 508, 510, 512, 514, and 516 included in the rows 504a and 504b may be selected for tuning the threshold voltage of the integrated circuit device 108 at the edges of the active region 202. The material compositions of the doped regions 518, 520, and 522 included in the row 504c may be selected for tuning the threshold voltage of the integrated circuit device 108 at the center of the active region 202.

The doped regions 506, 508, and 510 of the row 504a may be arranged in the x-direction, and the doped regions 508 may be located laterally between the doped regions 506 and 510 in the x-direction. The doped regions 512, 514, and 516 of the row 504b may be arranged in the x-direction, and the doped region 514 may be located laterally between the doped regions 512 and 516 in the x-direction. The doped regions 518, 520, and 522 of the row 504c may be arranged in the x-direction, and the doped region 520 may be located laterally between the doped regions 518 and 522 in the x-direction.

The column 502a may include doped regions 506, 512, and 518 of the gate structure 206. The column 502b may include doped regions 510, 516, and 522 of the gate structure 206. The column 502c may be located between the columns 502a and 502b in the x-direction and may include doped regions 508, 514, and 520. The columns 502a and 502b may be located at opposing ends of the channel region under the gate structure 206 of the integrated circuit device 108, and the material compositions of the doped regions 506, 510, 512, 516, 518, and 522 included in the columns 502a and 502b may be selected for tuning the threshold voltage of the integrated circuit device 108 at the ends of the channel region. The material compositions of the doped regions 508, 514, and 520 included in the column 502c may be selected for tuning the threshold voltage of the integrated circuit device 108 at the center of the channel region.

The doped regions 506, 512, and 518 of the column 502a may be arranged in the y-direction, and the doped region 518 may be located laterally between the doped regions 506 and 512 in the y-direction. The doped regions 510, 516, and 522 of the column 502b may be arranged in the y-direction, and the doped region 522 may be located laterally between the doped regions 510 and 516 in the y-direction. The doped regions 508, 514, and 520 of the column 502c may be arranged in the y-direction, and the doped region 520 may be located laterally between the doped regions 508 and 514 in the y-direction.

Two or more of the doped regions 506-522 may have approximately the same work function value. For example, the doped regions 506, 510, 512, and 516 may have approximately the same work function value. These doped regions 506, 510, 512, and 516 may include the same material or same material composition to achieve approximately the same work function value. For example, the doped regions 506, 510 512, and 516 may each include polysilicon that is doped with the same dopant type (e.g., an n-type dopant, a p-type dopant) and/or may be doped with approximately the same dopant concentration of a particular dopant such that the doped regions 506, 510, 512, and 516 have approximately the same work function value. As an example, the doped regions 506, 510, 512, and 516 may each be doped with approximately the same concentration of boron (B) (a p-type dopant). As another example, the doped regions 506, 510, 512, and 516 may each be doped with approximately the same concentration of phosphorous (P) (an n-type dopant). Similarly, the doped regions 508 and 514 may have approximately the same work function value and may include the same material or same material composition (e.g., the same doped material with approximately the same dopant concentration), and/or the doped regions 518 and 522 may have approximately the same work function value and may include the same material or same material composition (e.g., the same doped material with approximately the same dopant concentration).

The work function value of the doped regions 506, 510, 512, and 516 may be different from the work function value of the doped regions 518 and 522 to compensate for the field crowding and/or surface doping concentration at the edges of the active region 202. For example, the work function value of the doped regions 506, 510, 512, and 516 may be greater than the work function value of the doped regions 518 and 522. The greater work function value of the doped regions 506, 510, 512, and 516 provides for a higher threshold voltage (Vₜ) at the edges of the active region 202 than if the work function value of the doped regions 506, 510, 512, and 516 was approximately equal to the work function value of the doped regions 518 and 522, which provides for greater threshold voltage uniformity across the active region 202 in the y-direction than if the k-value of the work function value of the doped regions 506, 510, 512, and 516 was approximately equal to the work function value of the doped regions 518 and 522. Thus, the doped regions 506, 510, 512, and 516 may be composed of a material (e.g., polysilicon) that is doped with a dopant having a higher work function value than the doped material (e.g., doped poly silicon) of the doped regions 518 and 520. Additionally and/or alternatively, the doped regions 506, 510, 512, and 516 may include a higher dopant concentration the dopant concentration of the doped regions 518 and 520.

Similarly, the work function value of the doped regions 508 and 514 may be different from the work function value of the doped region 520 to compensate for the field crowding and/or surface doping concentration at the edges of the active region 202. For example, the work function value of the doped regions 508 and 514 may be greater than the work function value of the doped region 520, which provides for greater threshold voltage uniformity across the active region 202 in the y-direction than if the work function value of the doped regions 508 and 514 were approximately equal to the work function value of the doped region 520. Thus, the doped regions 508 and 514 may be composed of a material (e.g., polysilicon) that is doped with a dopant having a higher work function value than the doped material of the doped region 520. Additionally and/or alternatively, the doped regions 508 and 514 may include a higher dopant concentration the dopant concentration of the doped region 520.

Along the x-direction (e.g., along the length of the channel region of the integrated circuit device 108), the work function value of the doped regions 506, 510, 512, and 516 may be different from the work function value of the doped regions 508 and 514 to compensate for the field crowding and/or surface doping concentration at the ends of the channel region. For example, the work function value of the doped regions 506, 510, 512, and 516 may be greater than the work function value of the doped regions 508 and 514. Thus, at the edges of the active region 202, which provides for greater threshold voltage uniformity across the channel region in the x-direction than if the work function value of the doped regions 506, 510, 512, and 516 were approximately equal to the work function value of the doped regions 508 and 514. Thus, the doped regions 506, 510, 512, and 516 may be composed of a material (e.g., polysilicon) that is doped with a dopant having a higher work function value than the doped material (e.g., doped poly silicon) of the doped regions 508 and 514. Additionally and/or alternatively, the doped regions 506, 510, 512, and 516 may include a higher dopant concentration the dopant concentration of the doped regions 508 and 514.

Similarly, the work function value of the doped regions 518 and 522 may be different from the work function value of the doped region 520 to compensate for the field crowding and/or surface doping concentration at the ends of the channel region. For example, the work function value of the doped regions 518 and 522 may be greater than the work function value of the doped region 522, which provides for greater threshold voltage uniformity across the channel region in the x-direction than if the work function value of the doped regions 518 and 522 were approximately equal to the work function value of the doped region 522. Thus, the doped regions 518 and 522 may be composed of a material (e.g., polysilicon) that is doped with a dopant having a higher work function value than the doped material (e.g., doped poly silicon) of the doped region 520. Additionally and/or alternatively, the doped regions 518 and 522 may include a higher dopant concentration the dopant concentration of the doped region 520.

The arrangement of the doped regions of 506-522, the associated work function values, and the associated material compositions are an example, and other arrangements for the doped regions of 506-522, the associated work function values, and the associated material compositions are within the scope of the present disclosure. The doped regions of 506-522 of the gate dielectric layer 208 may include various types of dopants (e.g., p-type dopants such as boron (B) and/or gallium (Ga), among other examples; n-type dopants such as arsenic (As) and/or phosphorous (P), among other examples) and/or various dopant concentrations.

As shown in FIG. 5B, the doped region 518 (and the doped regions 506 and 512 not shown in the cross-section in FIG. 5B) of the gate structure 206 may be closest to the source/drain region 204a. The doped region 522 (and the doped regions 510 and 516 not shown in the cross-section in FIG. 5B) of the gate structure 206 may be closest to the source/drain region 204b.

As shown in FIG. 5C, the doped regions 506 and 512 of the gate structure 206 may be located over the edge portions 238 of the active region 202 in the y-direction, and the doped region 518 of the gate dielectric layer 208 may be located over the central portion 240 of the active region 202. The material, dopant type, dopant, and/or dopant concentration of the doped regions 506 and 512 may be selected such that the doped regions 506 and 512 have a particular work function value for tuning the threshold voltage of the integrated circuit device 108 in the edge portions 238. The material, dopant type, dopant, and/or dopant concentration of the doped regions 508, 510, 514, and 516 (not shown in the cross-section in FIG. 5C) may similarly be selected such that the doped regions 508, 510, 514, and 516 have work function values for tuning the threshold voltage of the integrated circuit device 108 in the edge portions 238.

The material, dopant type, dopant, and/or dopant concentration of the doped region 518 may be selected such that the doped region 518 has a particular work function value for tuning the threshold voltage of the integrated circuit device 108 in the central portion 240. The material, dopant type, dopant, and/or dopant concentration of the doped regions 520 and 522 (not shown in the cross-section in FIG. 5C) may similarly be selected such that the doped regions 520 and 522 have work function values for tuning the threshold voltage of the integrated circuit device 108 in the central portion 240.

As indicated above, FIGS. 5A-5C are provided as an example. Other examples may differ from what is described with regard to FIGS. 5A-5C. For example, while the gate structure 206 in FIGS. 5A-5C is described has having doped regions 506-522 of doped polysilicon, the work function values of the doped regions 506-522 may instead be implemented as regions having different work function metals. Examples of work function metals for tuning the work function values of different regions of the gate structure 206 may include p-type work function metals (e.g., metals that raise the work function of the gate structure 206 such as tungsten (W), cobalt (Co), titanium nitride (TiN), and/or tungsten nitride (WN)) and/or n-type work function metals (e.g., metals that lower the work function of the gate structure 206, such as titanium aluminum (TiAl) and/or titanium aluminum carbon (TiAlC)).

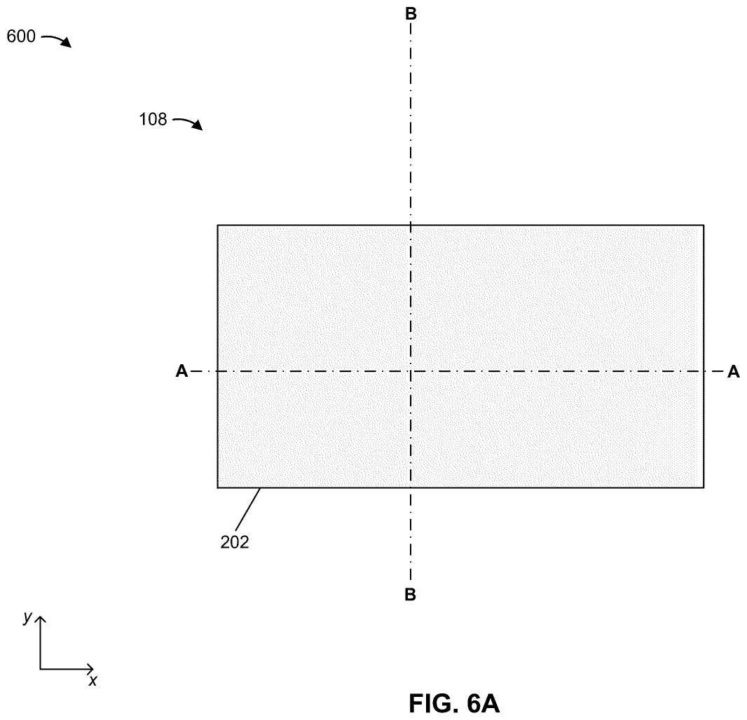

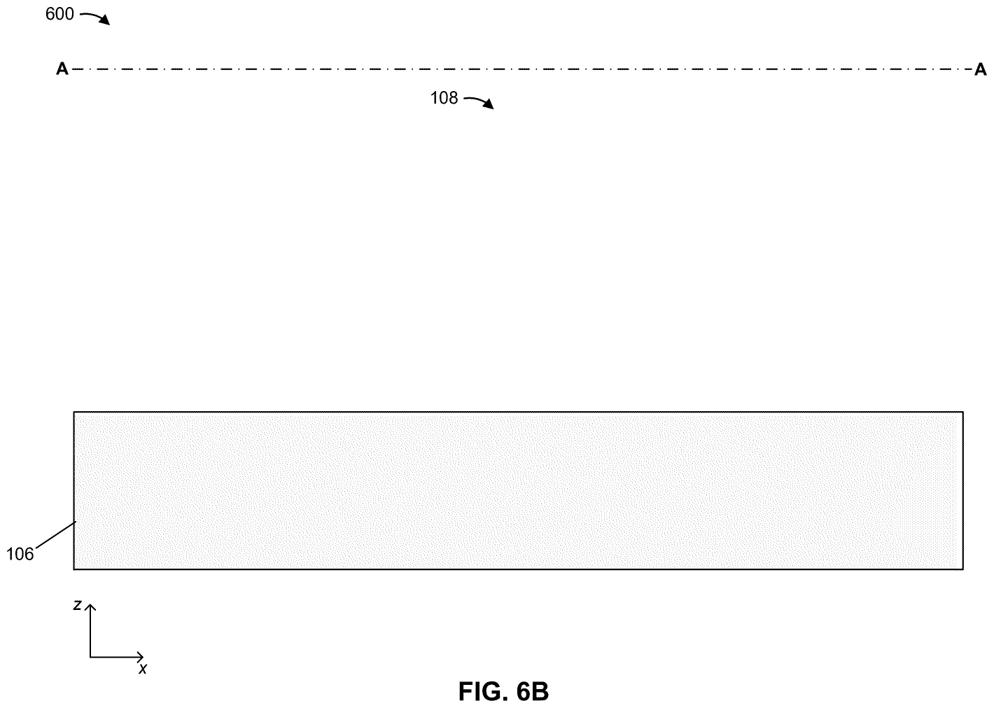

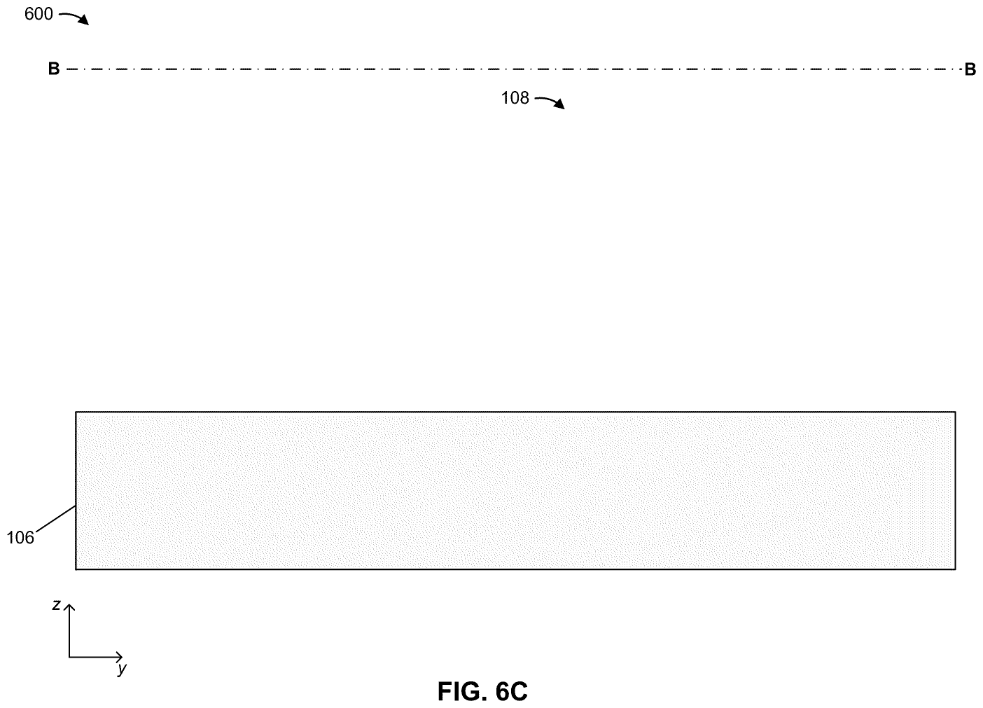

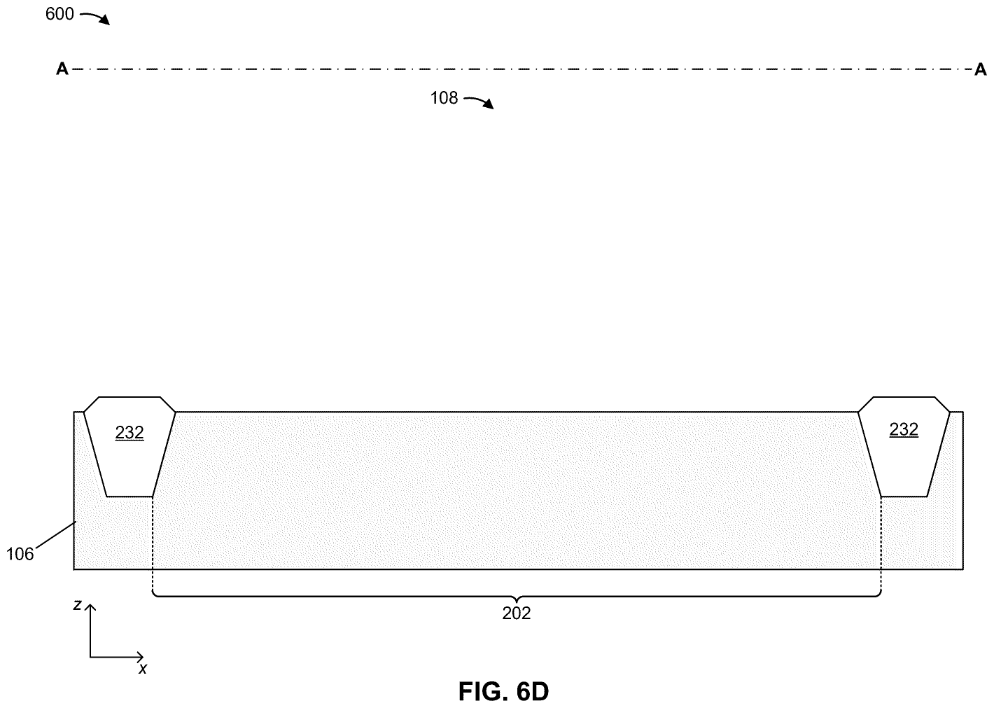

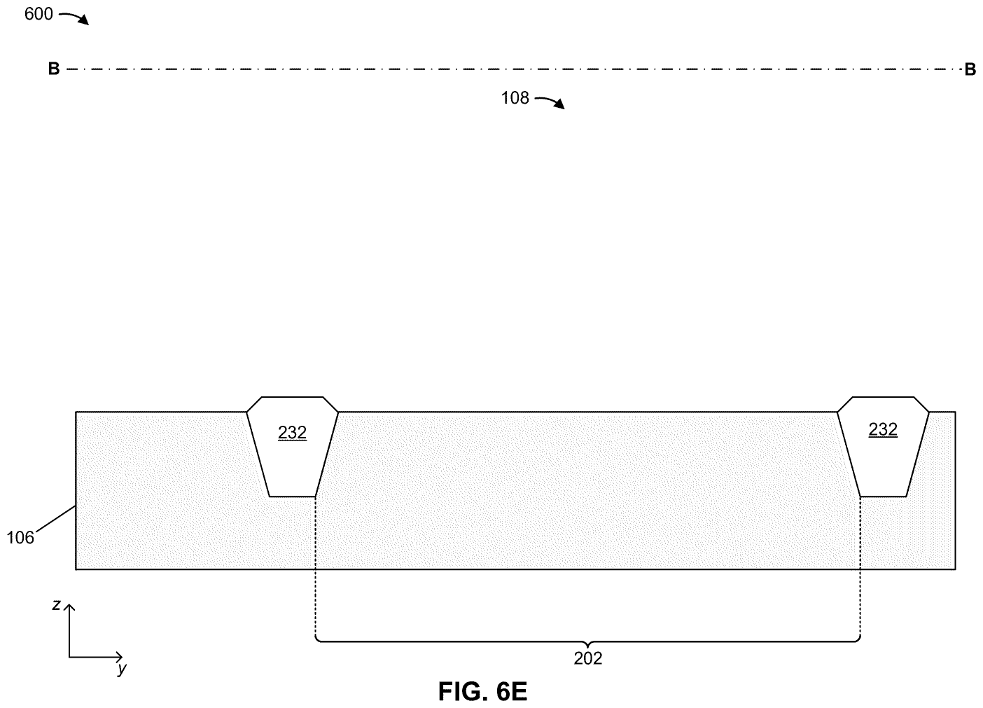

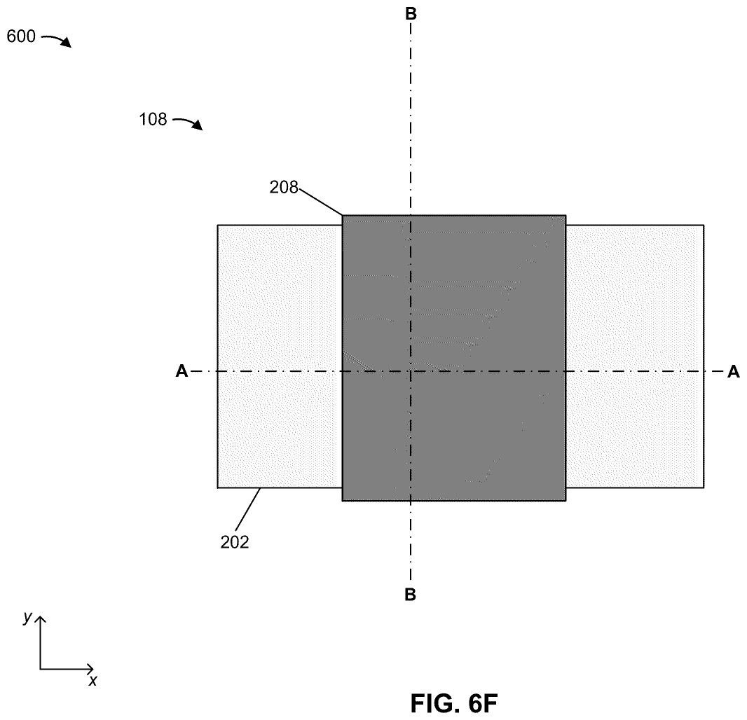

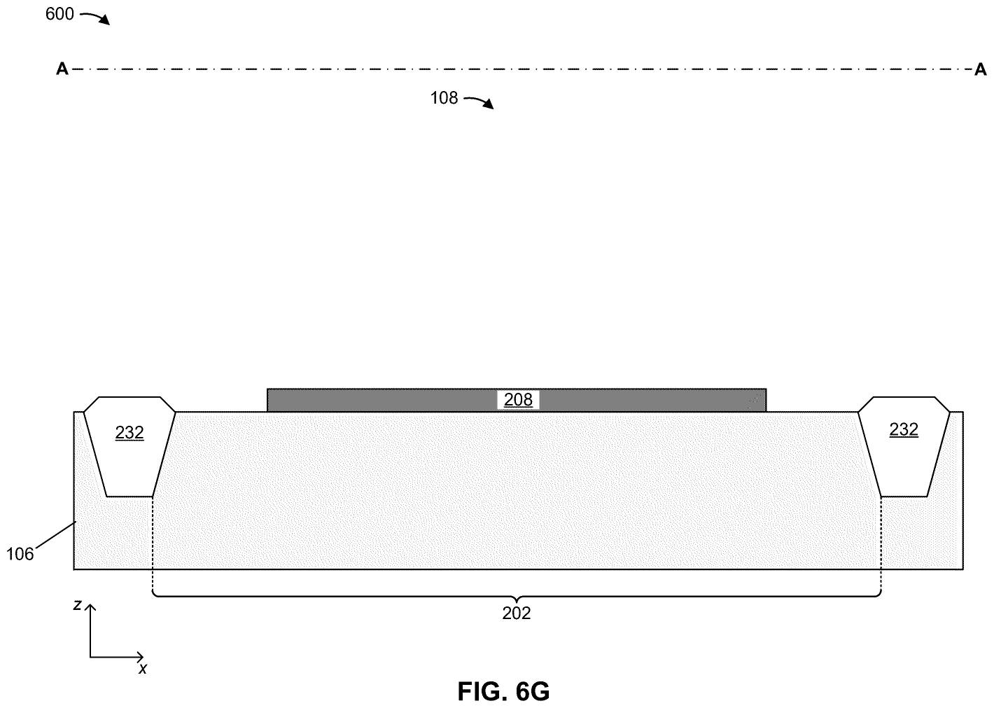

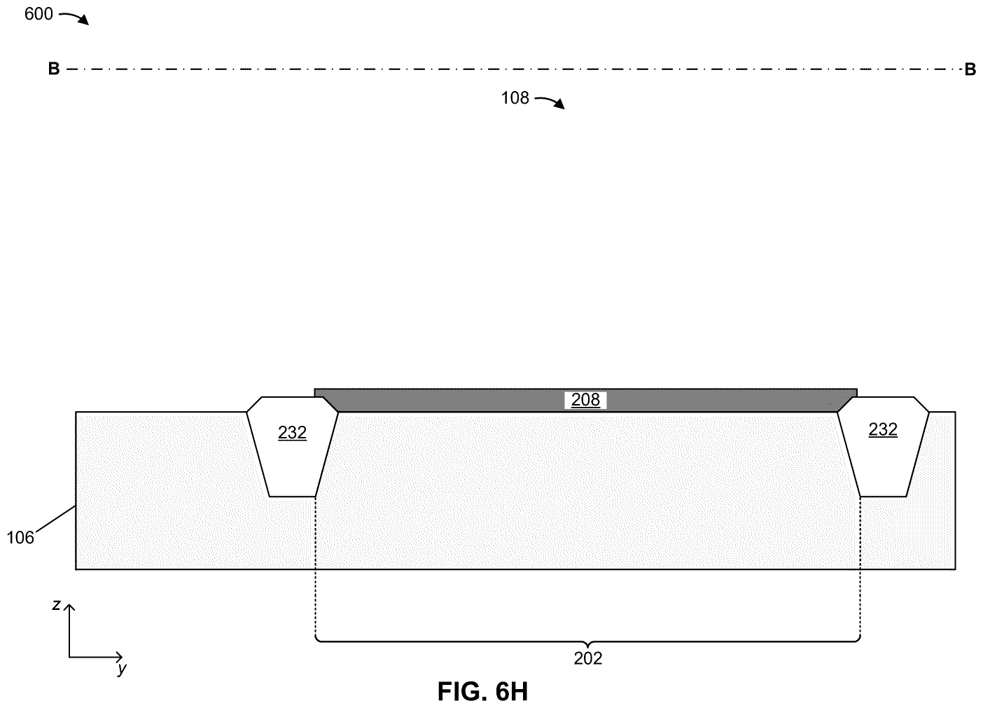

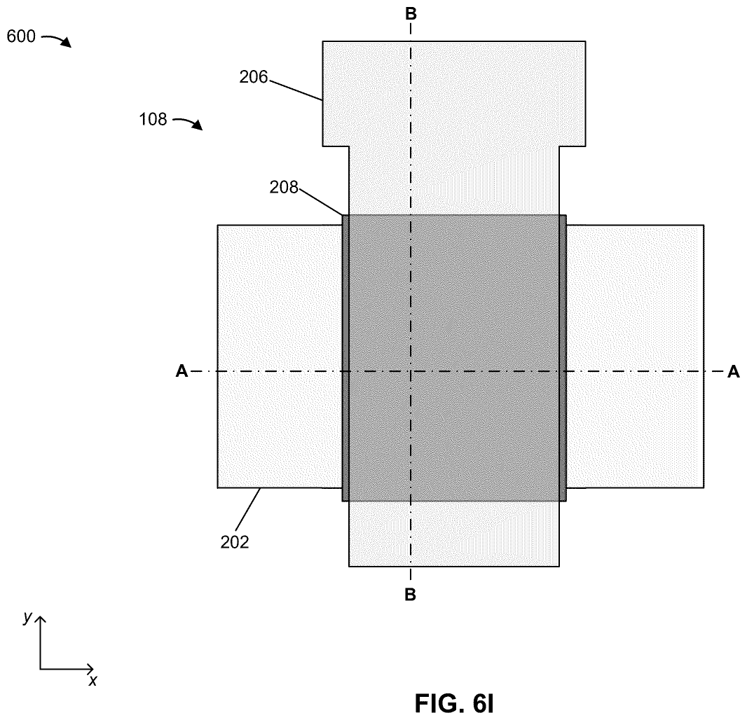

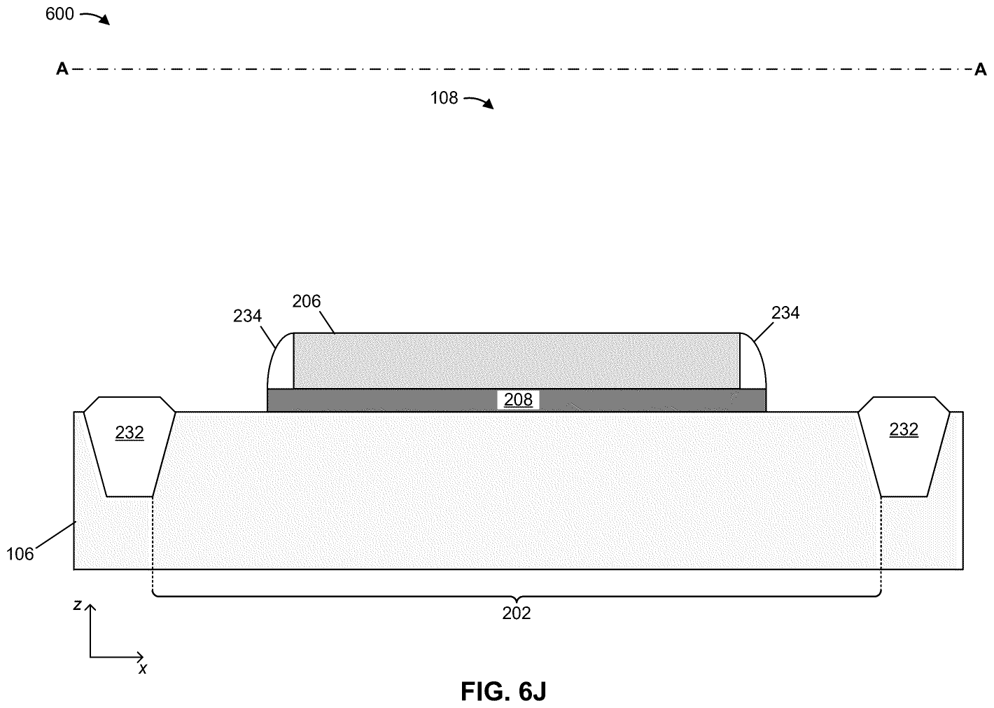

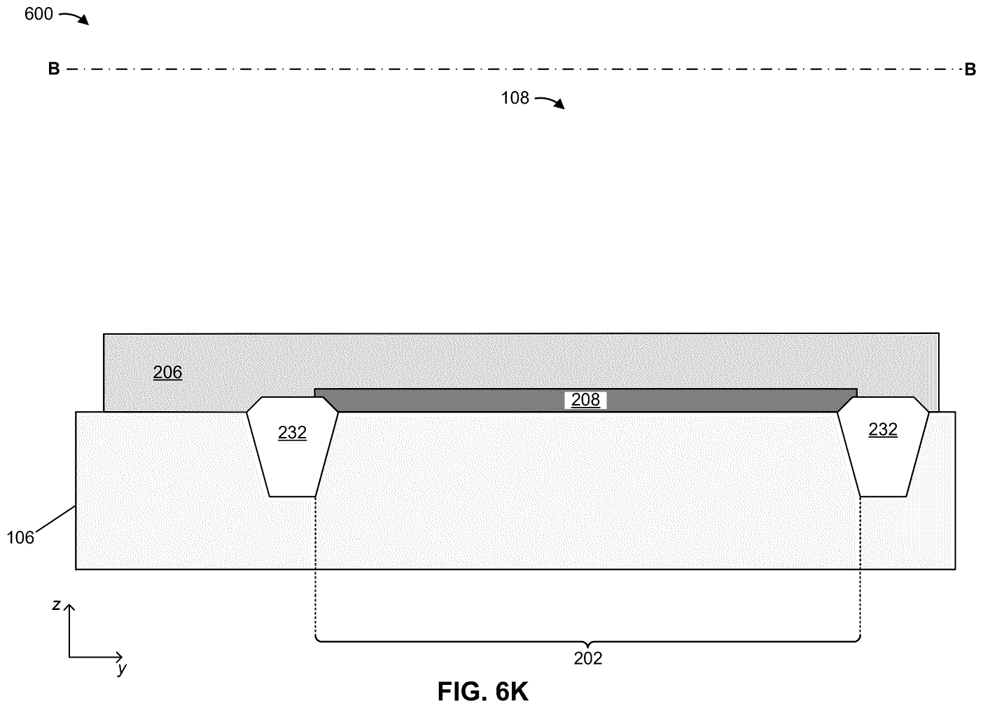

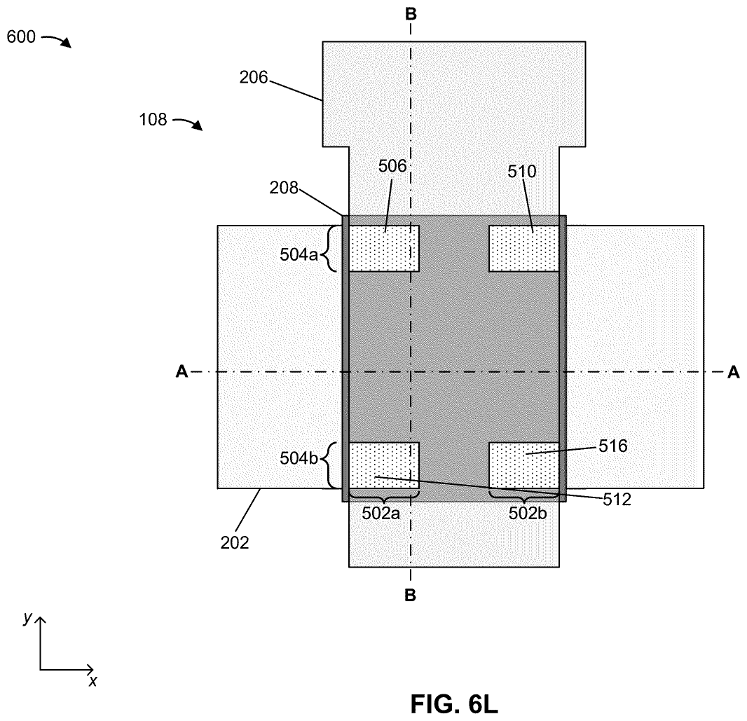

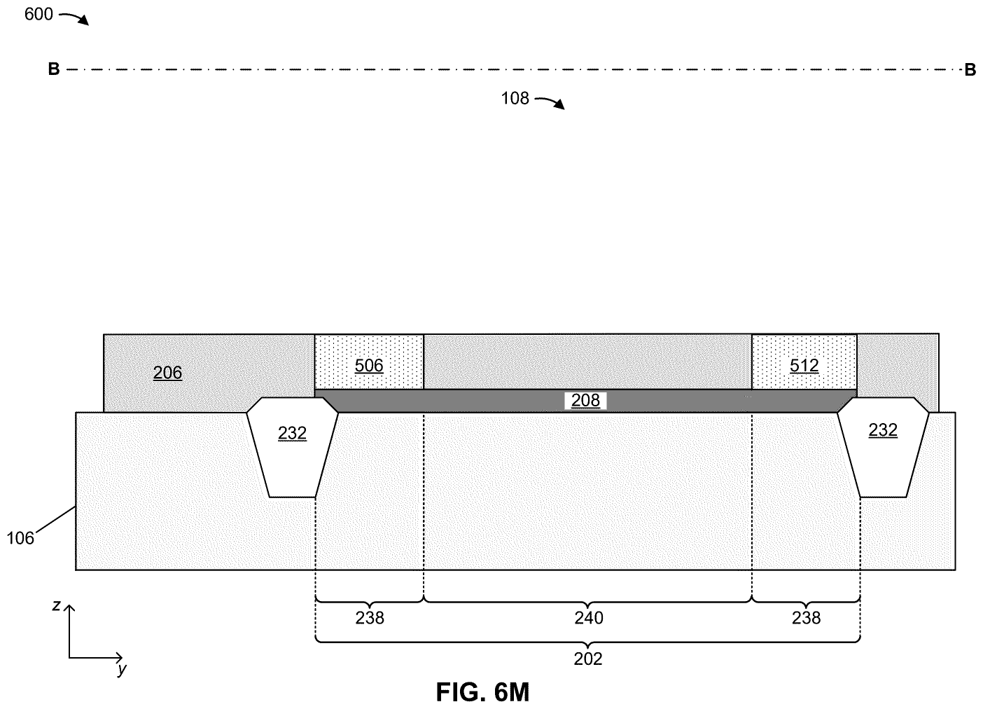

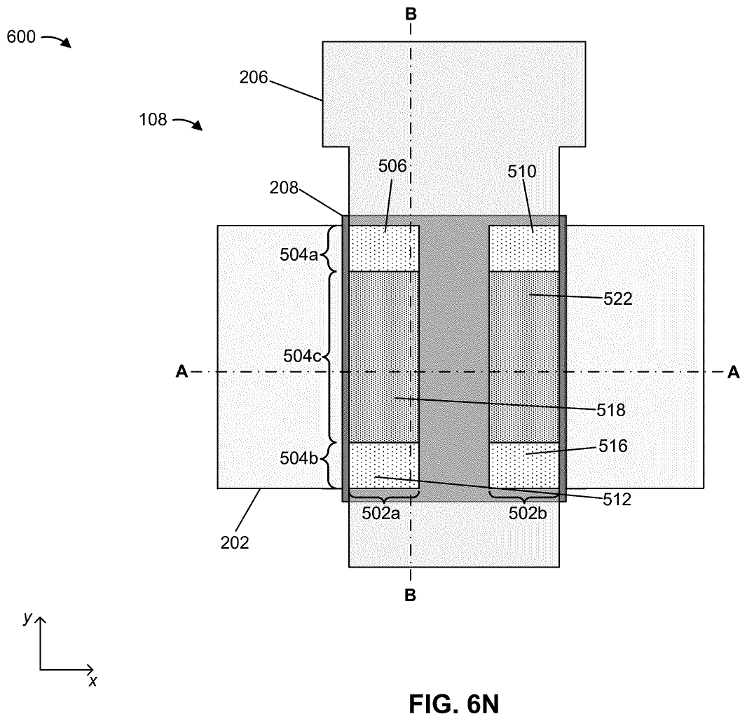

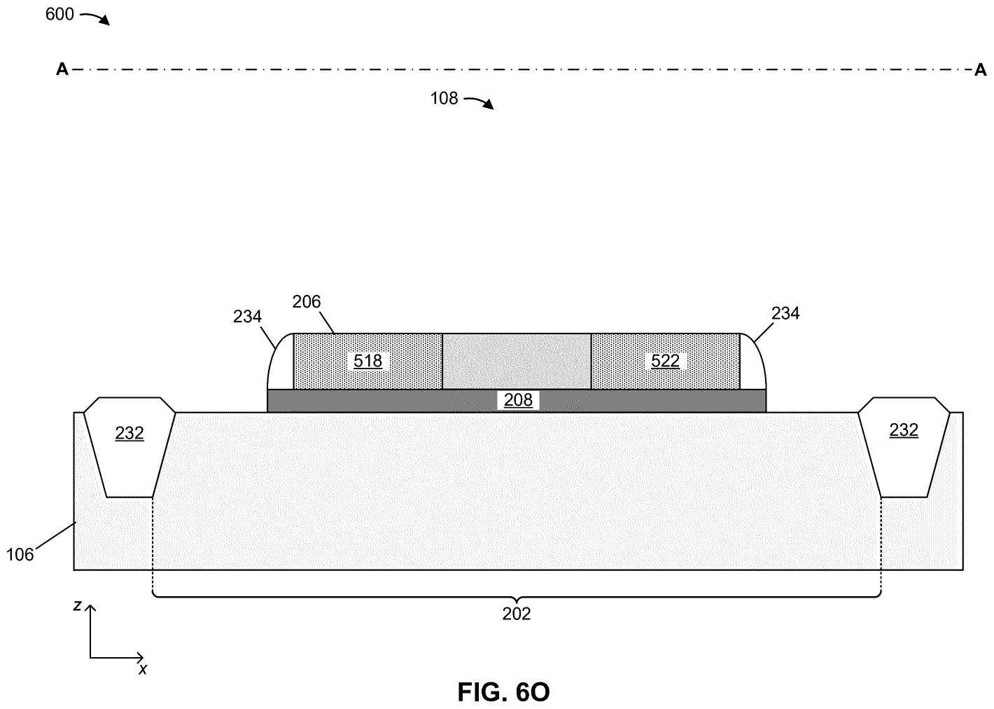

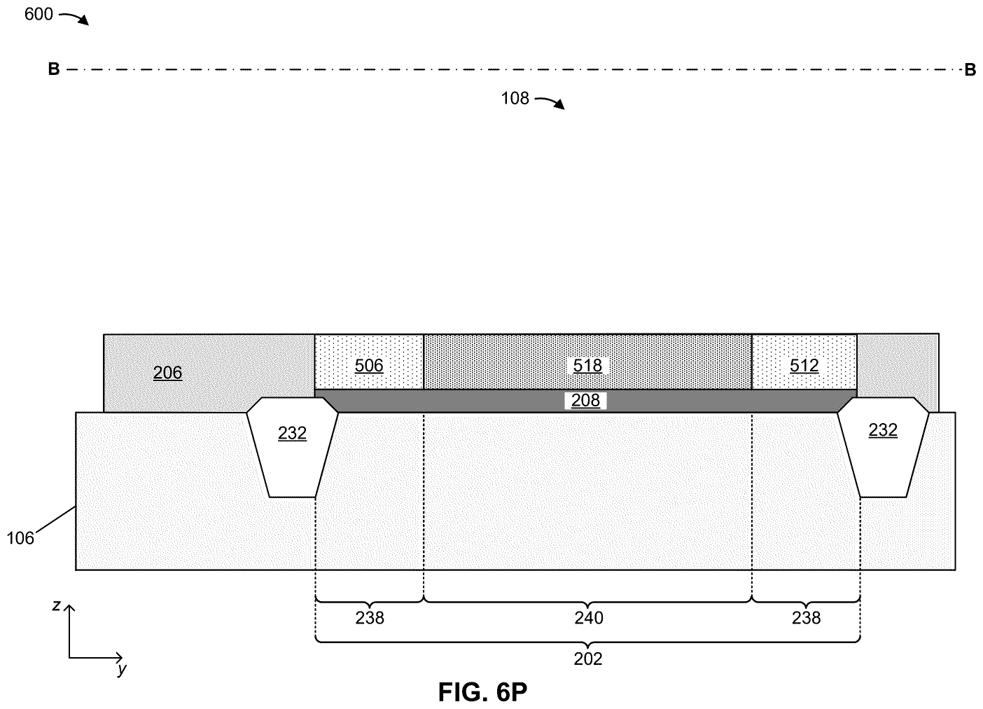

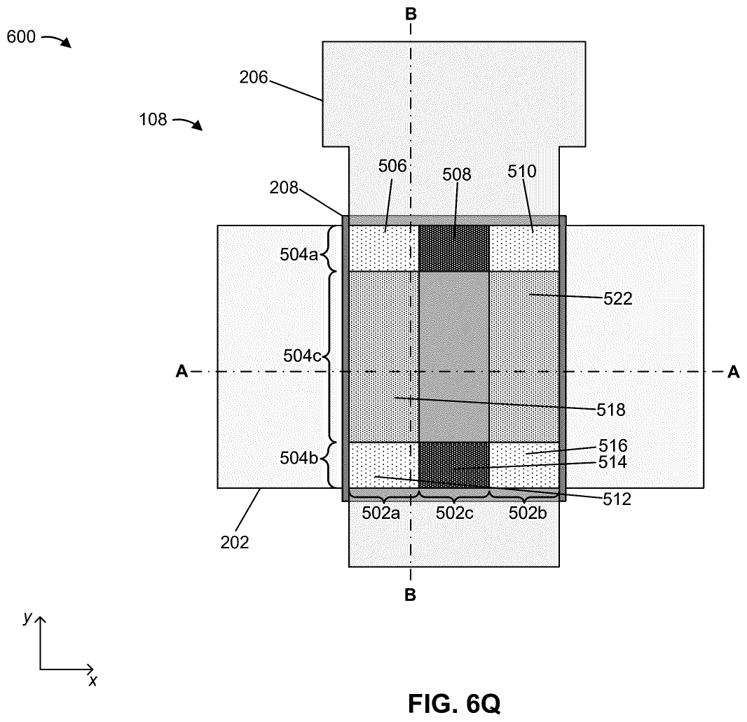

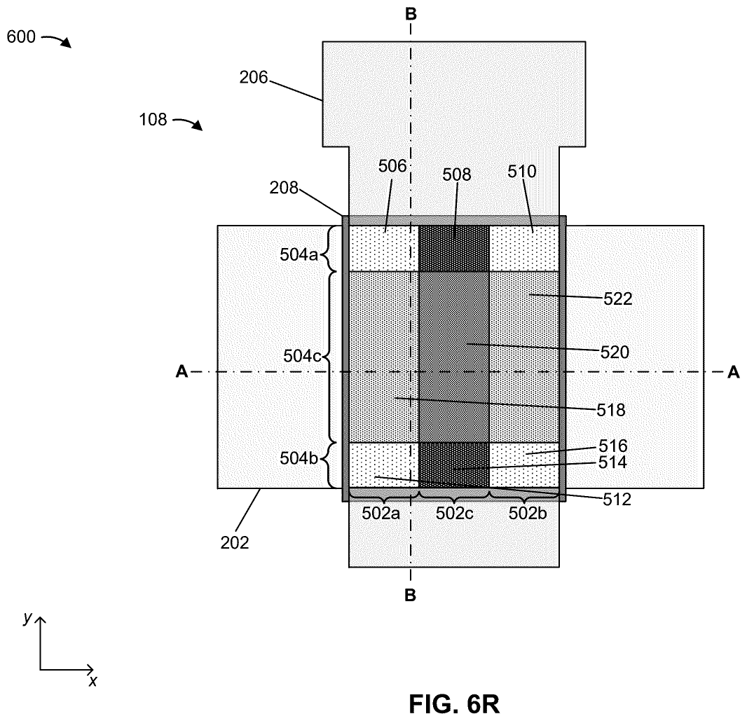

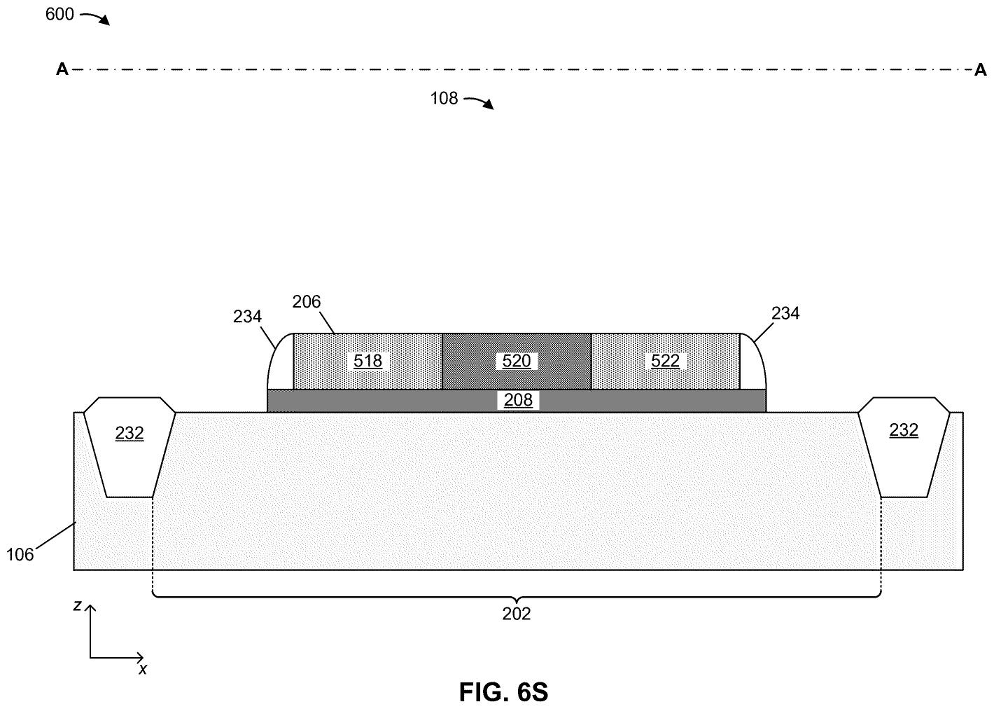

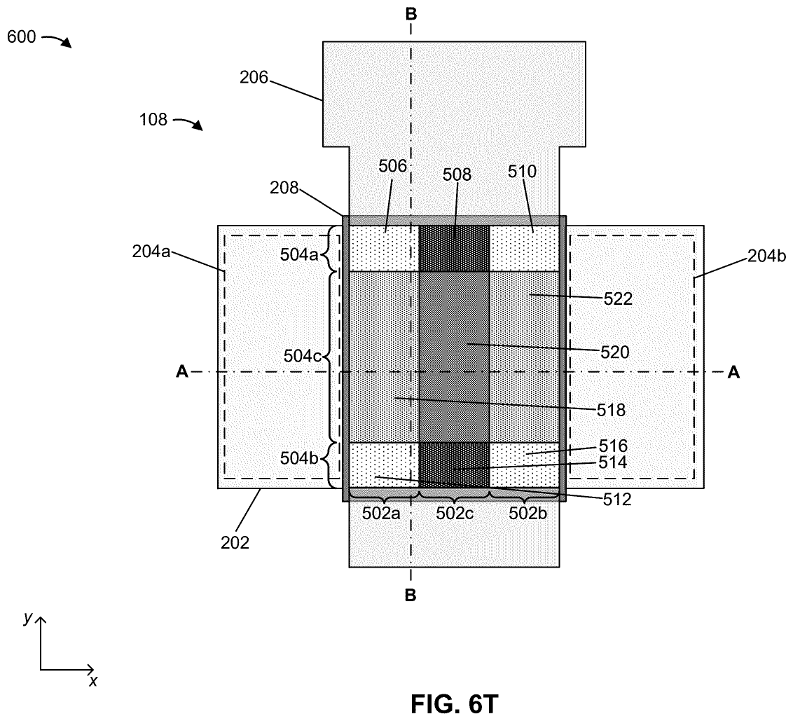

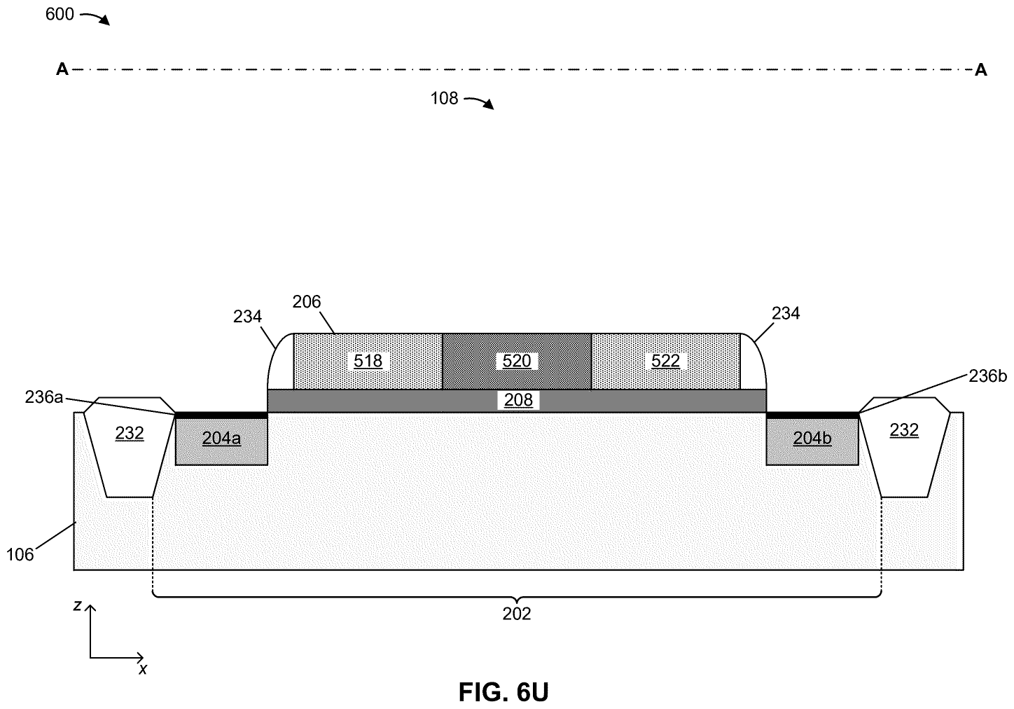

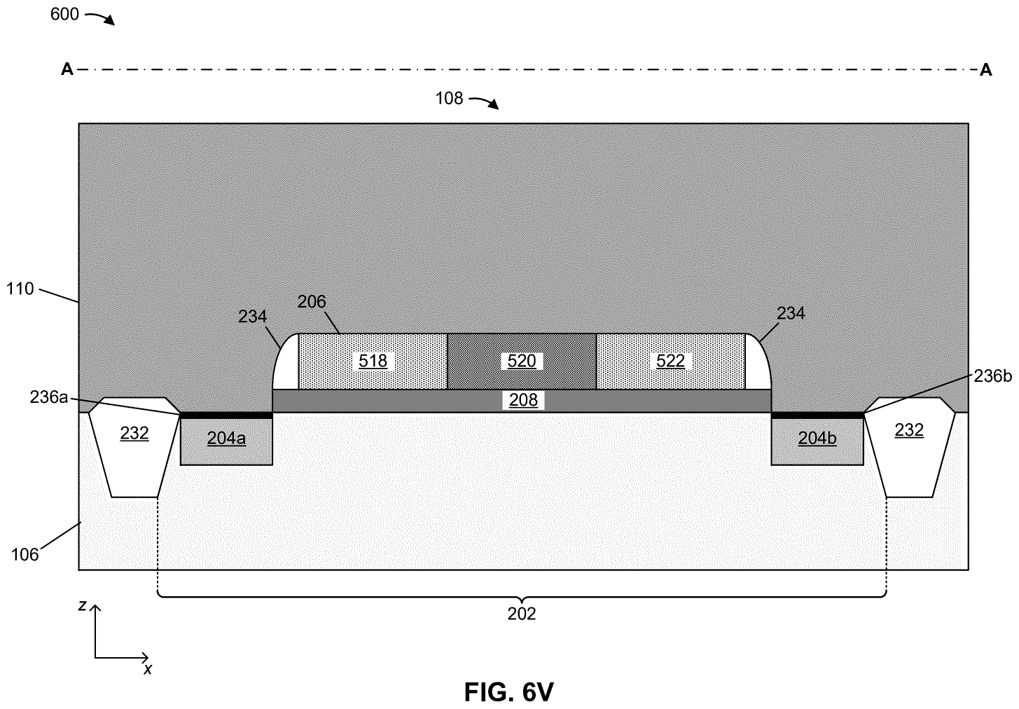

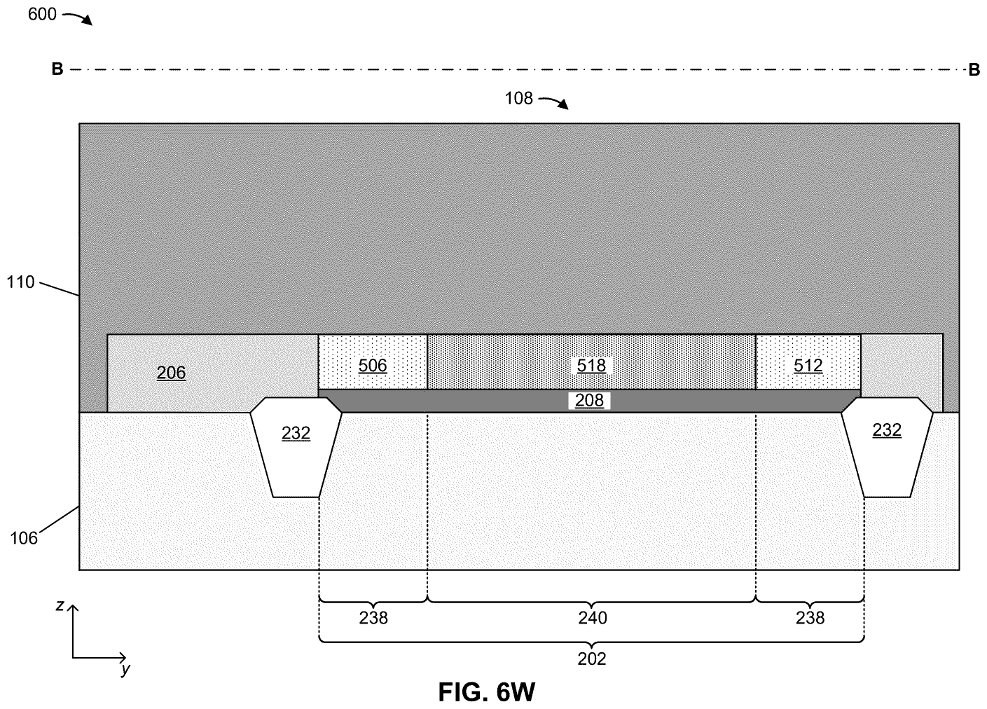

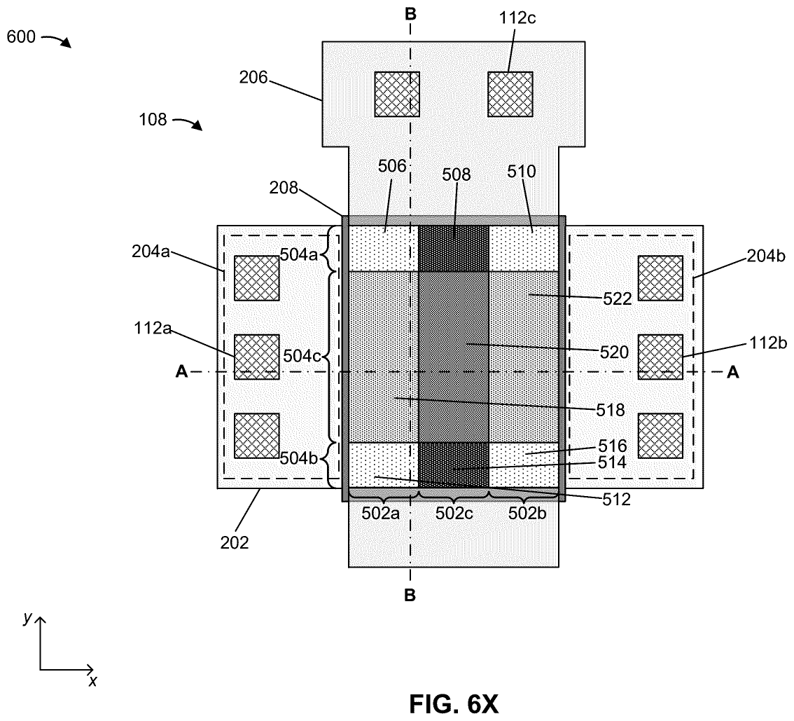

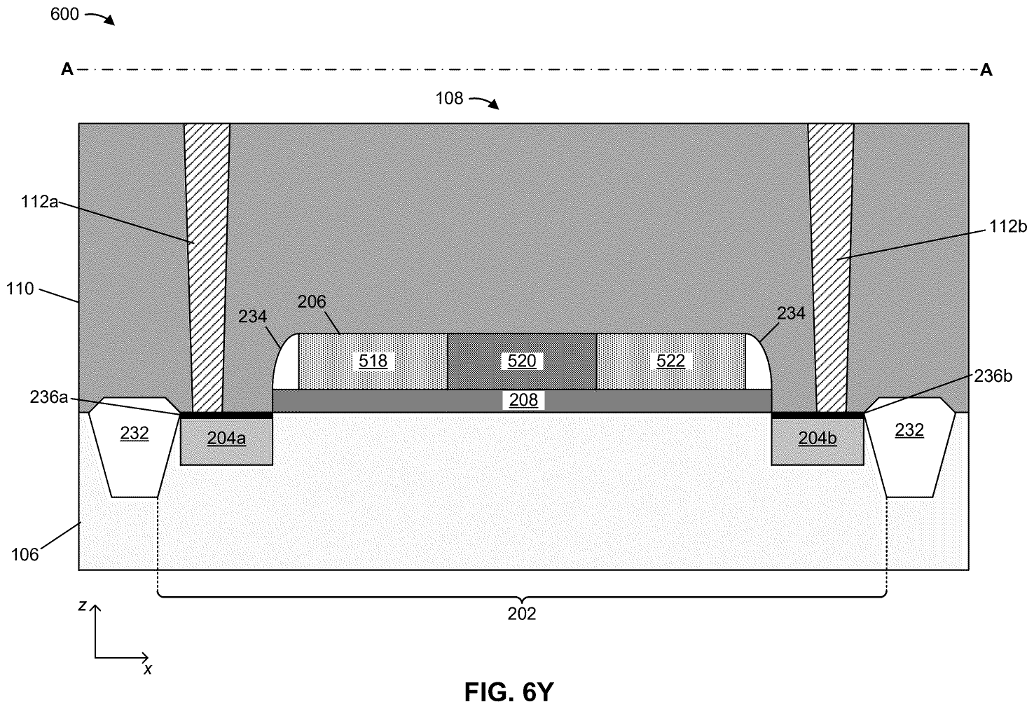

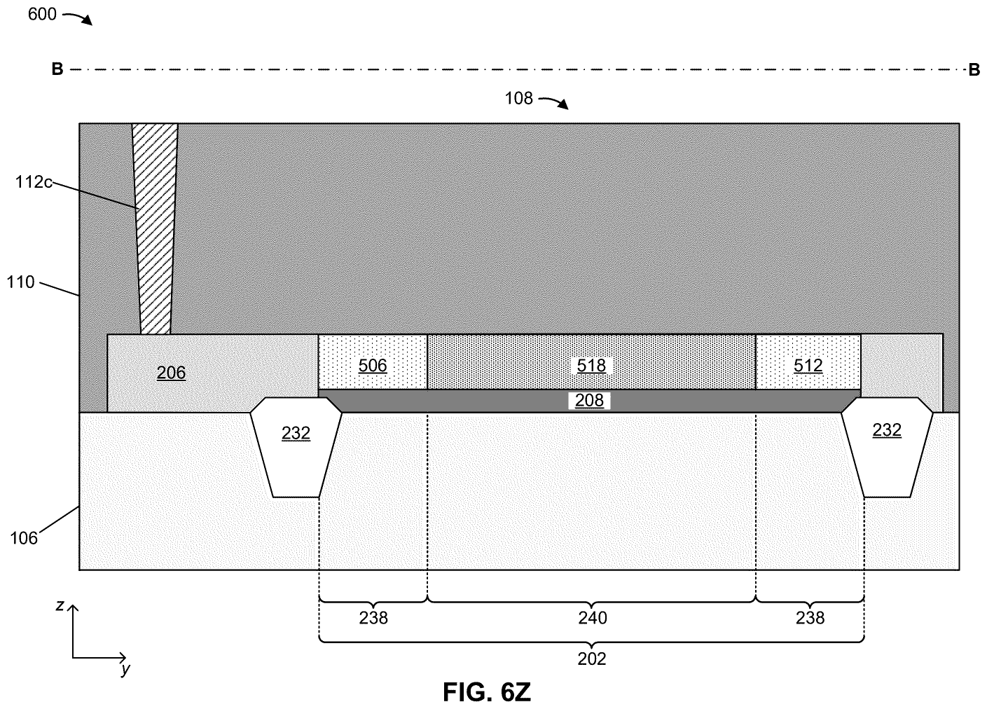

FIGS. 6A-6Z are diagrams of an example implementation 600 of forming an integrated circuit device 108 that includes a composite gate structure 206 described herein. In some implementations, one or more of the operations described in connection may be performed using one or more semiconductor processing tools, such as a deposition tool, an exposure tool, a developer tool, an etch tool, an ion implantation tool, a planarization tool, and/or another suitable semiconductor processing tool.

Turning to FIGS. 6A-6C, one or more of the operations in the example implementation 300 may be performed in connection with the substrate 106 of the semiconductor device 100. The substrate 106 may be provided in the form of a semiconductor wafer or another type of substrate.

As shown in FIGS. 6D and 6E, the isolation region 232 may be formed in the substrate 106. The isolation region 232 may define the active region 202 of the integrated circuit device 108. The isolation region 232 may be formed according to one or more examples described in connection with FIGS. 3A-3W.

As shown in FIGS. 6F-6H, the gate dielectric layer 208 may be formed above the active region 202 of the substrate 106. A deposition tool may be used to deposit the gate dielectric layer 208 using a PVD technique, an ALD technique, a CVD technique, an oxidation technique, and/or another suitable deposition technique. The gate dielectric layer 208 may be deposited in one or more deposition operations. In some implementations, a planarization tool may be used to perform a planarization operation (e.g., a CMP operation) to planarize the gate dielectric layer 208 after the gate dielectric layer 208 is deposited.

As shown in FIGS. 6I-6K, the gate structure 206 may be formed over the gate dielectric layer 208. The gate structure 206 may extend along the substrate 106 in the y-direction. A deposition tool may be used to deposit a layer of material for the gate structure 206 using a PVD technique, a CVD technique, and ALD technique, and electroplating technique, and/or another suitable deposition technique. The layer of material may be etched (e.g., using an etch tool) to define the gate structure 206. Sidewall spacer layers 234 may be deposited (e.g., using a deposition tool) using a CVD technique, an ALD technique, a PVD technique, and/or another type of deposition technique. In some implementations, a sidewall spacer layer is deposited on the sidewalls of the gate structure 206 and along the surface of the substrate 106. An etch tool may then be used to etch the sidewall spacer layer to define the sidewall spacers 234.

As shown in FIGS. 6L and 6M, the doped regions 506, 510, 512, and 516 may be formed in the gate structure 206. An ion implantation tool may be used to implant dopants into the gate structure 206 to form the doped regions 506, 510, 512, and 516. In some implementations, an implant mask is used to define the portions of the gate structure 206 that are doped with ions to form the doped regions 506, 510, 512, and 516. The doped regions 506, 510, 512, and/or 516 may be formed at the edge portions 238 of the active region 202. Moreover, two or more of the doped regions 506, 510, 512, and/or 516 may be formed of a same dopant type, the dopant, and/or the same dopant concentration to have approximately a same work function value.

As shown in FIGS. 6N-6P, the doped regions 518 and 522 may be formed in the gate structure 206. An ion implantation tool may be used to implant dopants into the gate structure 206 to form the doped regions 518 and 522. In some implementations, an implant mask is used to define the portions of the gate structure 206 that are doped with ions to form the doped regions 518 and 522.

The doped regions 518 and/or 522 may be formed at the central portion 240 of the active region 202. Moreover, doped regions 518 and 522 may be formed of a same dopant type, the dopant, and/or the same dopant concentration to have approximately a same work function value. The doped region 518 may be formed such that the doped region 518 is located laterally between the doped regions 506 and 512 in the y-direction. The doped region 522 may be formed such that the doped region 522 is located laterally between the doped regions 510 and 516 in the y-direction.

In some implementations, the doped regions 518 and/or 522 are formed after the doped regions 506, 510, 512, and/or 516. In some implementations, the doped regions 518 and/or 522 are formed prior to the doped regions 506, 510, 512, and/or 516.

As shown in FIG. 6Q, the doped regions 508 and 514 may be formed in the gate structure 206. An ion implantation tool may be used to implant dopants into the gate structure 206 to form the doped regions 508 and 514. In some implementations, an implant mask is used to define the portions of the gate structure 206 that are doped with ions to form the doped regions 508 and 514.

The doped regions 508 and/or 514 may be formed at the edge portions 238 of the active region 202. Moreover, doped regions 508 and/or 514 may be formed of a same dopant type, the dopant, and/or the same dopant concentration to have approximately a same work function value. The doped region 508 may be formed such that the doped region 508 is located laterally between the doped regions 506 and 510 in the x-direction. The doped region 514 may be formed such that the doped region 514 is located laterally between the doped regions 512 and 516 in the x-direction.

In some implementations, the doped regions 508 and/or 514 are formed after the doped regions 506, 510, 512, 516, 518, and/or 522. In some implementations, the doped regions 508 and/or 514 are formed prior to the doped regions 506, 510, 512, 516, 518, and/or 522.

As shown in FIGS. 6R and 6S, the doped region 520 may be formed in the gate structure 206. An ion implantation tool may be used to implant dopants into portions into the gate structure 206 to form the doped region 520. In some implementations, an implant mask is used to define the portions of the gate structure 206 that are doped with ions to form the doped region 520.

The doped region 520 may be formed at the central portion 240 of the active region 202. The doped region 520 may be formed such that the doped region 520 is located laterally between the doped regions 518 and 522 in the x-direction. Moreover, the doped region 520 may be formed such that the doped region 520 is located laterally between the doped regions 508 and 514 in the y-direction.

In some implementations, the doped region 520 is formed after the doped regions 506, 508, 510, 512, 514, 516, 518, and/or 522. In some implementations, the doped region 520 is formed prior to the doped regions 506, 508, 510, 512, 514, 516, 518, and/or 522.

As shown in FIGS. 6T and 6U, the source/drain region 204a and the source/drain region 204b may be formed in the substrate 106. As further shown in FIG. 6U, the metal silicide layers 236a and 236b may be respectively formed on the source/drain regions 204a and 204b. The source/drain regions 204a and 204b, and the metal silicide layers 236a and 236b, may be formed in a similar manner as described in connection with FIGS. 3Q and 3R.

As shown in FIGS. 6V and 6W, the dielectric layer 110 may be formed on the integrated circuit device 108. The dielectric layer 110 may be formed in a similar manner as described in connection with FIGS. 3S and 3T.

As shown in FIGS. 6X-6Z, the contact structure(s) 112a may be formed over the source/drain region 204a such that the contact structure(s) 112a land on the metal silicide layer 236a on the source/drain region 204a. The contact structure(s) 112b may be formed over the source/drain region 204b such that the contact structure(s) 112b land on the metal silicide layer 236b on the source/drain region 204b. The contact structure(s) 112c may be formed over the gate structure 206 such that the contact structure(s) 112c lands on the gate structure 206. The contact structures 112a-112c may be formed in a similar manner as described in connection with FIGS. 3U-3W.

As indicated above, FIGS. 6A-6Z are provided as an example. Other examples may differ from what is described with regard to FIGS. 6A-6Z.

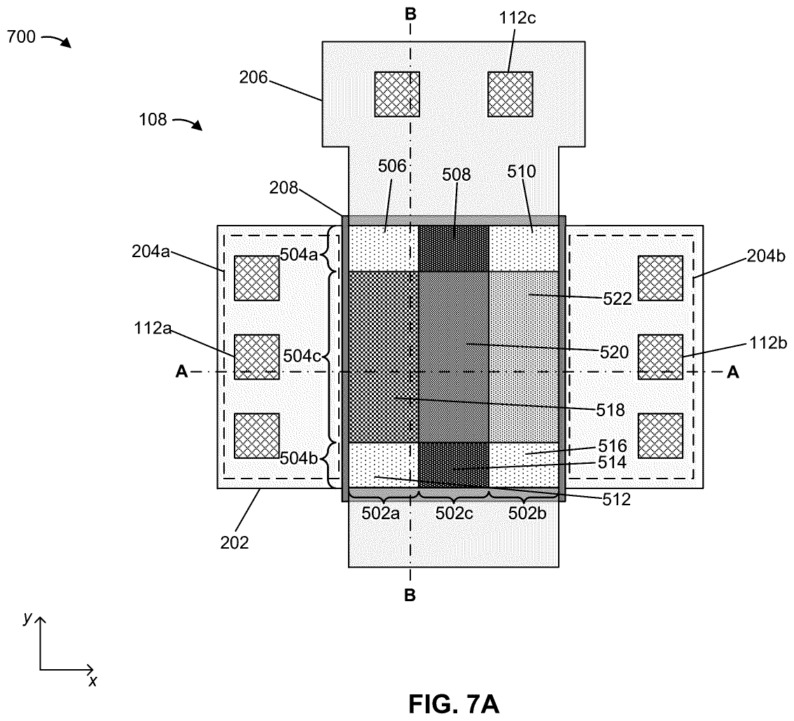

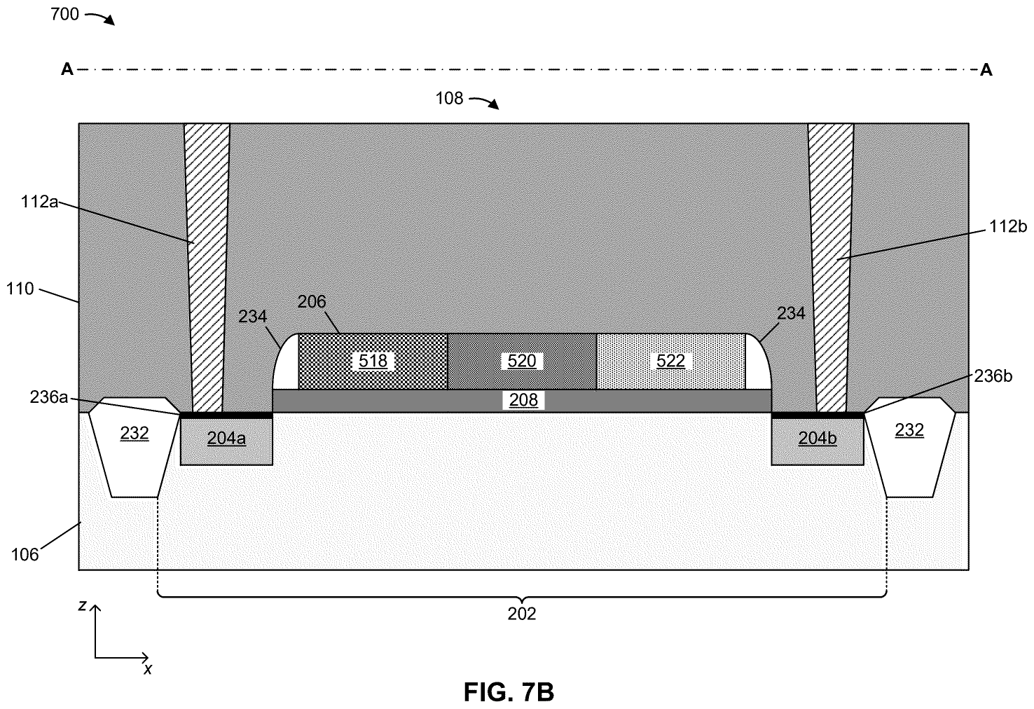

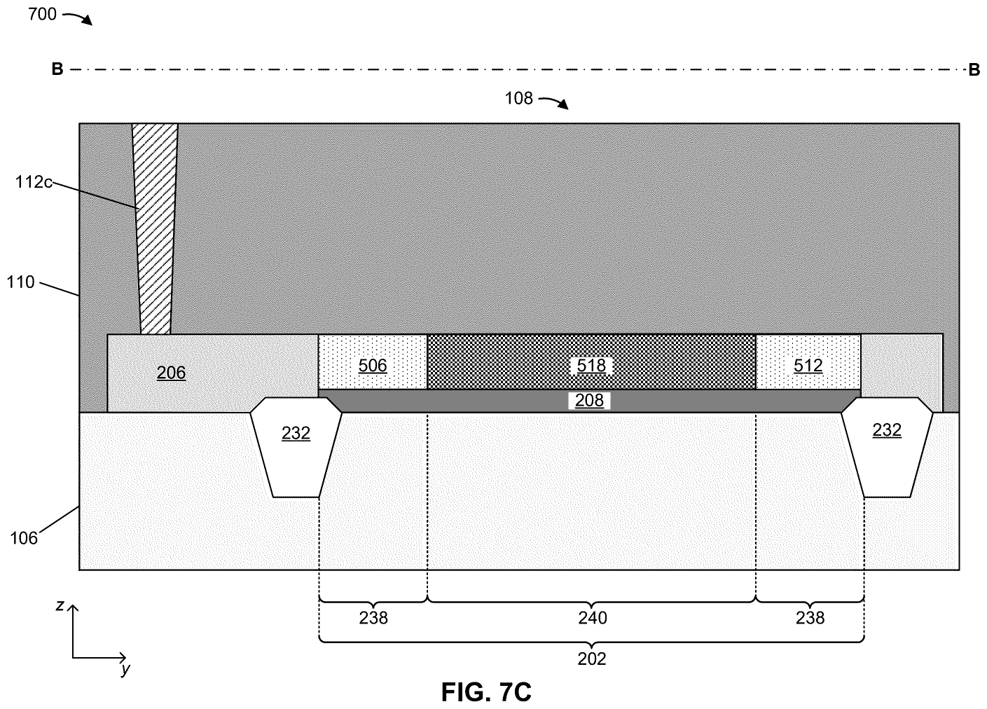

FIGS. 7A-7C are diagrams of an example implementation 700 of an integrated circuit device 108 described herein. In the example implementation 700, the integrated circuit device 108 includes a high-voltage transistor structure. FIG. 7A illustrates a top view of the integrated circuit device 108. FIG. 7B illustrates an example cross-section view of the integrated circuit device 108 along the line A-A in FIG. 7A (e.g., along the x-direction). FIG. 7C illustrates an example cross-section view of the integrated circuit device 108 along the line B-B in FIG. 7A (e.g., along the y-direction).

As shown in FIGS. 7A-7C, the example implementation 700 of the integrated circuit device 108 includes a similar combination and arrangement of layers and/or structures as the example implementation 200 of the integrated circuit device 108 in FIGS. 5A-5C. However, in the example implementation 700 of the integrated circuit device 108, the doped region 518 of the gate structure 206 includes a material composition (e.g., a dopant concentration, a dopant type, a dopant material) that is different from the material composition of the doped region 522 of the gate structure 206. In the central portion of the active region 202, the threshold voltage may be asymmetric along the x-direction between the source/drain regions 204a and 204b. For example, the threshold voltage might otherwise be higher near the source/drain region 204a than near the source/drain region 204b if the gate structure 206 had a work function value between the source/drain regions 204a and 204b. Accordingly, the material compositions of the doped regions 518 and 522 may be different such that the doped regions 518 and 522 have different work function values to compensate for an otherwise asymmetric threshold voltage to achieve a substantially unform threshold voltage between the source/drain regions 204a and 204b.

As indicated above, FIGS. 7A-7C are provided as an example. Other examples may differ from what is described with regard to FIGS. 7A-7C.

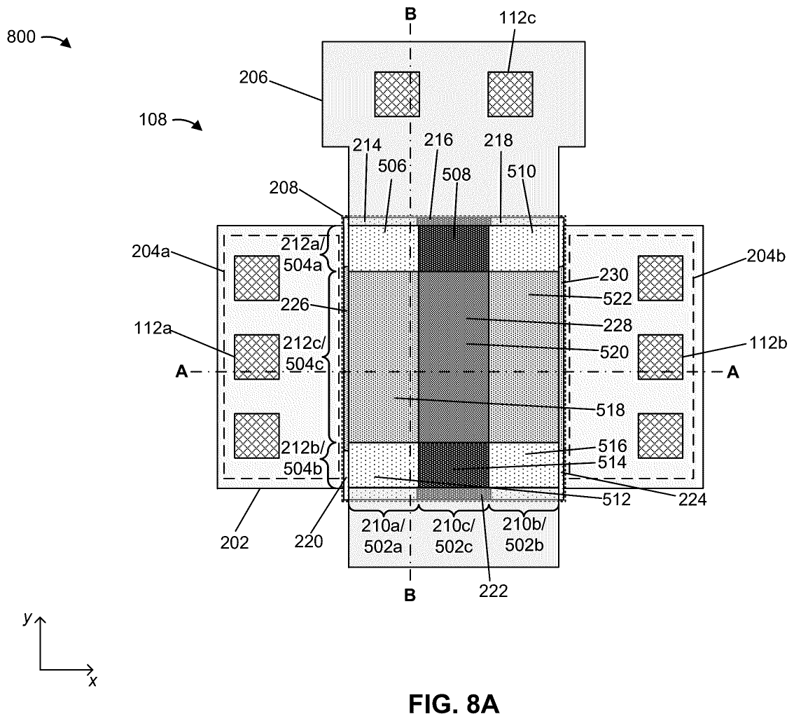

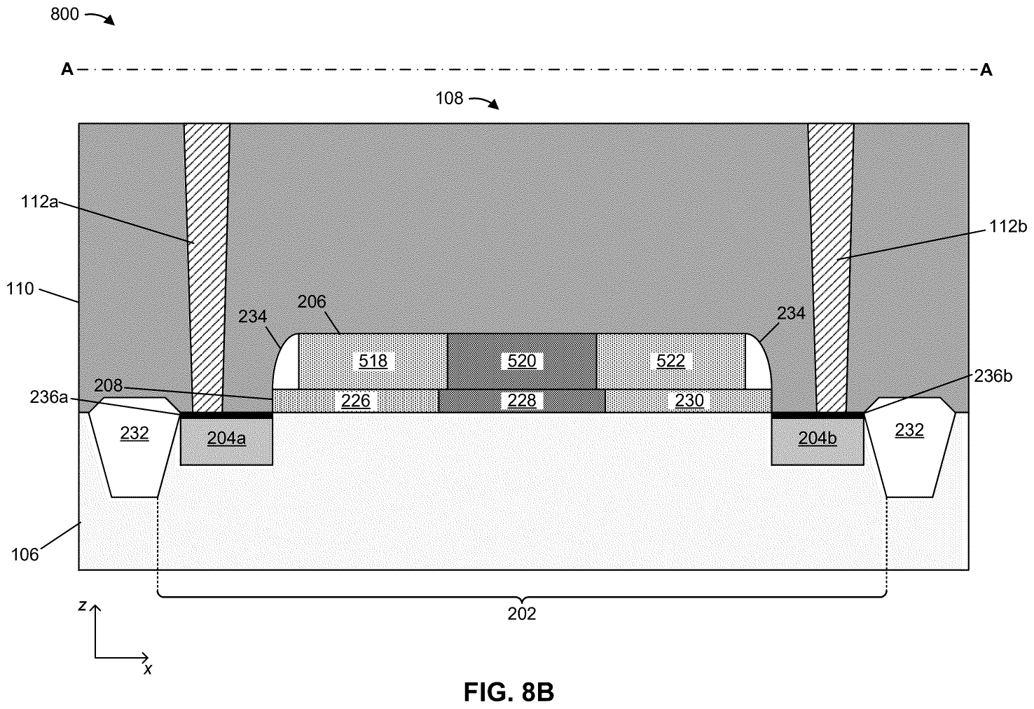

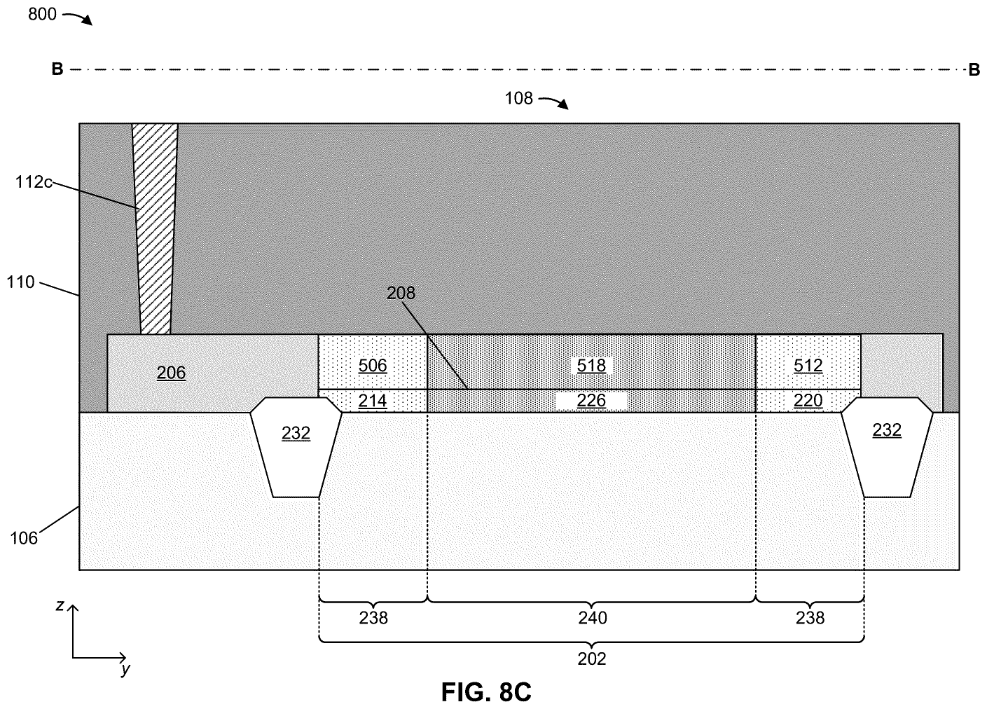

FIGS. 8A-8C are diagrams of an example implementation 800 of an integrated circuit device 108 described herein. In the example implementation 800, the integrated circuit device 108 includes a high-voltage transistor structure. FIG. 8A illustrates a top view of the integrated circuit device 108. FIG. 8B illustrates an example cross-section view of the integrated circuit device 108 along the line A-A in FIG. 8A (e.g., along the x-direction). FIG. 8C illustrates an example cross-section view of the integrated circuit device 108 along the line B-B in FIG. 8A (e.g., along the y-direction).

As shown in FIGS. 8A-8C, the example implementation 800 of the integrated circuit device 108 includes a similar combination and arrangement of layers and/or structures as the example implementation 200 of the integrated circuit device 108 in FIGS. 2A-2C. However, in the example implementation 800 of the integrated circuit device 108, the gate structure 206 is a composite gate structure, in addition to the gate dielectric layer 208 being a composite gate dielectric layer. Including both a composite gate dielectric layer and a composite gate structure provides for further threshold voltage tuning for the integrated circuit device 108 through k-value tuning in the gate dielectric layer 208 and work function value tuning in the gate structure 206.

As shown in FIG. 8A, the gate structure 206 is a composite gate structure in that the gate structure 206 includes a plurality of doped regions 506-522 having different work function values. The plurality of doped regions 506-522 of the gate structure 206 may be arranged in a grid that includes a plurality of columns 502a-502c arranged in the x-direction and extending in the y-direction, and a plurality of rows 504a-504c arranged in the y-direction and extending in the x-direction. The work function values of the doped regions 506-522 may be selected according to the examples described in connection with FIGS. 5A-5C, among other examples.

As further shown in FIG. 8A, the columns 510a-510c of the gate structure 206 may be located over the columns 210a-210c of the gate dielectric layer 208, respectively. The rows 512a-512c of the gate structure 206 may be located over the rows 212a-212c of the gate dielectric layer 208, respectively.

As shown in FIG. 8B, the doped region 518 of the gate structure 206 may be located over the portion 226 of the gate dielectric layer 208, the doped region 520 of the gate structure 206 may be located over the portion 228 of the gate dielectric layer 208, and the doped region 522 of the gate structure 206 may be located over the portion 230 of the gate dielectric layer 208.

As shown in FIG. 8C, the doped region 506 of the gate structure 206 may be located over the portion 214 of the gate dielectric layer 208, the doped region 512 of the gate structure 206 may be located over the portion 220 of the gate dielectric layer 208, and the doped region 518 of the gate structure 206 may be located over the portion 226 of the gate dielectric layer 208.

Additionally, the doped region 508 of the gate structure 206 may be located over the portion 216 of the gate dielectric layer 208, the doped region 510 of the gate structure 206 may be located over the portion 218 of the gate dielectric layer 208, the doped region 514 of the gate structure 206 may be located over the portion 222 of the gate dielectric layer 208, and the doped region 516 of the gate structure 206 may be located over the portion 224 of the gate dielectric layer 208.

As indicated above, FIGS. 8A-8C are provided as an example. Other examples may differ from what is described with regard to FIGS. 8A-8C.

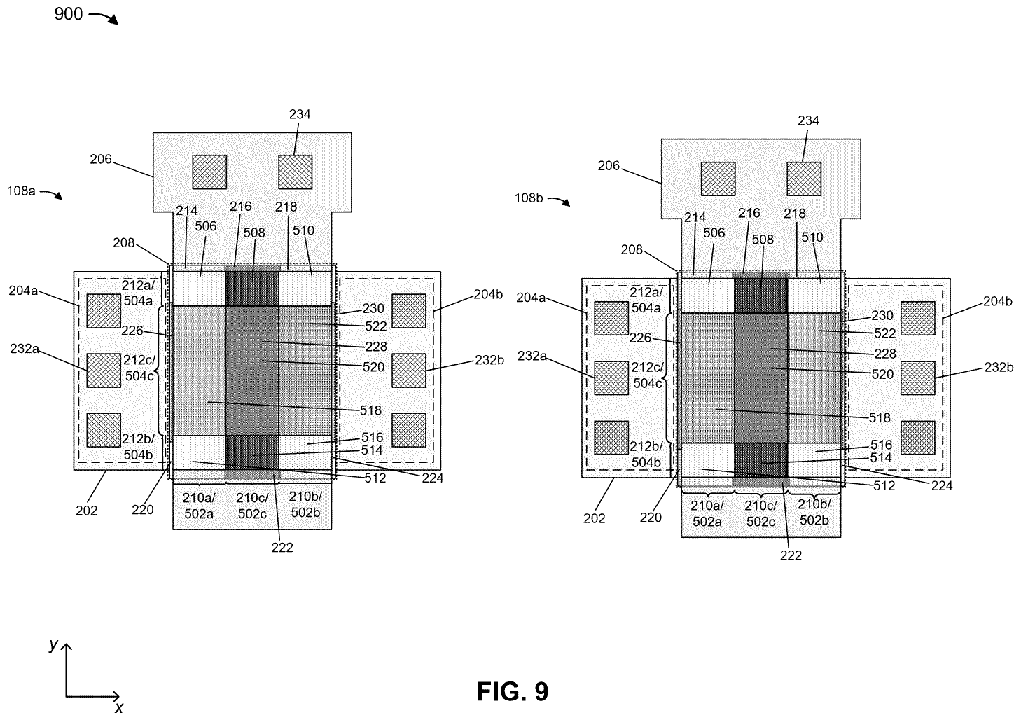

FIG. 9 is a diagram of an example implementation 900 of an integrated circuit devices 108a and 108b described herein. In the example implementation 900, the integrated circuit devices 108a and 108b each include a high-voltage transistor structure. The integrated circuit device 108a may include a p-type high-voltage transistor structure (e.g., a p-type metal-oxide-semiconductor (PMOS) high-voltage transistor), and integrated circuit device 108b may include an n-type high-voltage transistor structure (e.g., an n-type metal-oxide-semiconductor (NMOS) high-voltage transistor).

FIG. 9 illustrates a top view of the integrated circuit devices 108a and 108b. As shown in FIG. 9 each of the integrated circuit devices 108a and 108b may include a composite gate structure 206 having a plurality of doped regions 506-522 with two or more different work function values, and/or a composite gate dielectric layer 208 having a plurality of portions 214-230 with two or more different k-values. The work function values of the doped regions 506-522 of the integrated circuit device 108a, and/or the k-values of the portions 214-230 of the integrated circuit device 108a, may be selected to achieve a substantially uniform and low threshold voltage (e.g., a small band gap between the work function of the gate structure 206 and the valance band (E_{V})) for the integrated circuit device 108a. The work function values of the doped regions 506-522 of the integrated circuit device 108b, and/or the k-values of the portions 214-230 of the integrated circuit device 108b, may be selected to achieve a substantially uniform and low threshold voltage (e.g., a small band gap between the work function of the gate structure 206 and the condition band (E_{C})) for the integrated circuit device 108b.

As indicated above, FIG. 9 is provided as an example. Other examples may differ from what is described with regard to FIG. 9.

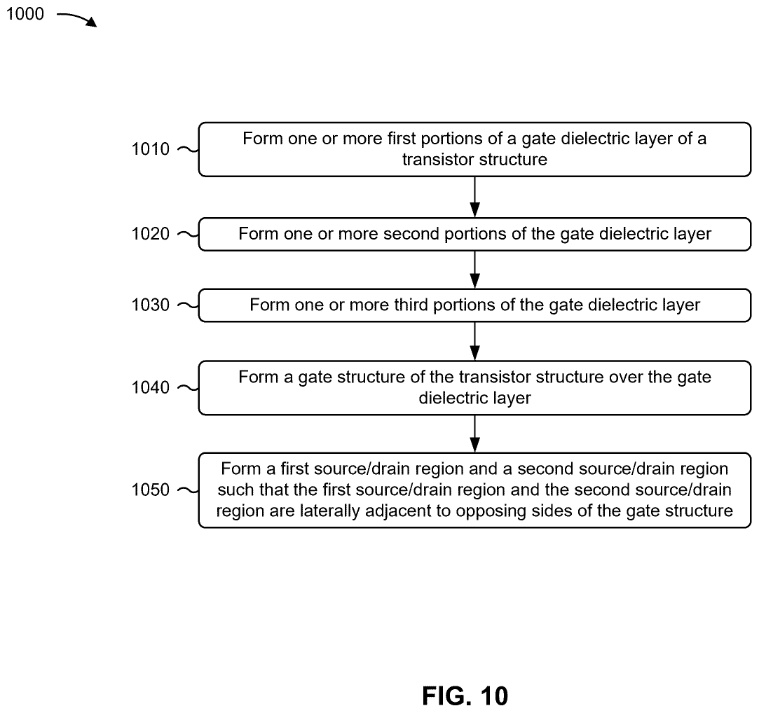

FIG. 10 is a flowchart of an example process 1000 associated with forming a transistor structure described herein. In some implementations, one or more process blocks of FIG. 10 are performed using one or more semiconductor processing tools, such as a deposition tool, an exposure tool, a developer tool, an etch tool, a planarization tool, an ion implantation tool, an annealing tool, a wafer/die transport tool, and/or another type of semiconductor processing tool.

As shown in FIG. 10, process 1000 may include forming one or more first portions of a gate dielectric layer of a transistor structure (block 1010). For example, one or more semiconductor processing tools may be used to form one or more first portions (e.g., portions 214, 218, 220, and/or 224) of a gate dielectric layer (e.g., a gate dielectric layer 208) of a transistor structure (e.g., an integrated circuit device 108), as described herein. In some implementations, the one or more first portions are composed of a first material having a first k-value.

As further shown in FIG. 10, process 1000 may include forming one or more second portions of the gate dielectric layer (block 1020). For example, one or more semiconductor processing tools may be used to form one or more second portions (e.g., portions 226 and/or 230) of the gate dielectric layer, as described herein. In some implementations, the one or more second portions are composed of a second material having a second k-value that is different than the first k-value.

As further shown in FIG. 10, process 1000 may include forming one or more third portions of the gate dielectric layer (block 1030). For example, one or more semiconductor processing tools may be used to form one or more third portions (e.g., portions 216 and/or 222) of the gate dielectric layer, as described herein. In some implementations, the one or more third portions are composed of a third material having a third k-value that is different than the first and second k-values.

As further shown in FIG. 10, process 1000 may include forming a gate structure of the transistor structure over the gate dielectric layer (block 1040). For example, one or more semiconductor processing tools may be used to form a gate structure (e.g., a gate structure 206) of the transistor structure over the gate dielectric layer, as described herein.

As further shown in FIG. 10, process 1000 may include forming a first source/drain region and a second source/drain region such that the first source/drain region and the second source/drain region are laterally adjacent to opposing sides of the gate structure (block 1050). For example, one or more semiconductor processing tools may be used to form a first source/drain region (e.g., a source/drain region 204a) and a second source/drain region (e.g., a source/drain region 204b) such that the first source/drain region and the second source/drain region are laterally adjacent to opposing sides of the gate structure, as described herein.

Process 1000 may include additional implementations, such as any single implementation or any combination of implementations described below and/or in connection with one or more other processes described elsewhere herein.

In a first implementation, forming the one or more second portions comprises forming a fourth portion (e.g., a portion 226) of the one or more second portions such that the fourth portion is laterally between a first subset (e.g., portions 214 and/or 220) of the one or more first portions, and forming a fifth portion (e.g., a portion 230) of the one or more second portions such that the fifth portion is laterally between a second subset (e.g., portions 218 and/or 224) of the one or more first portions.

In a second implementation, alone or in combination with the first implementation, process 1000 includes forming a fourth portion (e.g., a portion 228) of the gate dielectric layer, where the fourth portion is composed of a material having a fourth k-value that is different than the first, second, and third k-values.

In a third implementation, alone or in combination with one or more of the first and second implementations, forming the fourth portion of the gate dielectric layer comprises forming the fourth portion laterally between a fifth portion (e.g., a portion 226) of the one or more second portions and a sixth portion (e.g., a portion 230) of the one or more second portions.

In a fourth implementation, alone or in combination with one or more of the first through third implementations, forming the fourth portion of the gate dielectric layer comprises forming the fourth portion laterally between a seventh portion (e.g., a portion 216) of the one or more third portions and an eight portion (e.g., a portion 222) of the one or more third portions.

In a fifth implementation, alone or in combination with one or more of the first through fourth implementations, forming the gate structure comprises forming one or more first doped regions (e.g., doped regions 506, 510, 512, and/or 516) of the gate structure above the one or more first portions of the gate dielectric layer, wherein the one or more first doped regions have a first work function value, forming one or more second doped regions (e.g., doped regions 518 and/or 522) of the gate structure above the one or more second portions of the gate dielectric layer, wherein the one or more second doped regions have a second work function value that is different than the first work function value, and forming one or more third doped regions (e.g., doped regions 508 and/or 514) of the gate structure above the one or more third portions of the gate dielectric layer, wherein the one or more third doped regions have a third work function value that is different than the first and second work function values.

Although FIG. 10 shows example blocks of process 1000, in some implementations, process 1000 includes additional blocks, fewer blocks, different blocks, or differently arranged blocks than those depicted in FIG. 10. Additionally, or alternatively, two or more of the blocks of process 1000 may be performed in parallel.

In this way, a high-voltage transistor may include a composite gate dielectric layer having multiple regions with different dielectric constant values (e.g., different k-values) to achieve greater threshold voltage (Vₜ) uniformity across a channel region of the high-voltage transistor than if a uniform gate dielectric layer were used. The regions of different k-values may be arranged in a direction along a length of the channel region between source/drain regions of the high-voltage transistor, and/or may be arranged in a direction along a width of the channel region. The use of regions of different k-values can compensate for the subthreshold hump effect at edges of the channel region by tuning the threshold voltage at the edges of the channel region. Additionally and/or alternatively, the threshold voltage uniformity may be increased (e.g., separately or in addition to threshold voltage tuning by regions of different k-values for the gate dielectric layer) by forming a gate structure of the high-voltage transistor to have multiple regions of different work function values. Thus, the gate structure may be referred to as a composite gate structure. The regions with different work function values of the composite gate structure may compensate for the subthreshold hump effect at edges of the channel region.

As described in greater detail above, some implementations described herein provide a transistor structure. The transistor structure includes a first source/drain region in a substrate of a semiconductor device. The transistor structure includes a second source/drain region in the substrate. The transistor structure includes a gate structure above the substrate, where the gate structure is laterally between the first source/drain region and the second source/drain region. The transistor structure includes a composite gate dielectric layer between the gate structure and the substrate, where the composite gate dielectric layer includes a plurality of laterally-arranged portions, each having a different k-value.

As described in greater detail above, some implementations described herein provide a transistor structure. The transistor structure includes a first source/drain region in a substrate of a semiconductor device. The transistor structure includes a second source/drain region in the substrate. The transistor structure includes a gate structure above the substrate, where the gate structure is laterally between the first source/drain region and the second source/drain region. The transistor structure includes a gate dielectric layer between the gate structure and the substrate, where the gate structure includes a plurality of laterally-arranged doped regions, each having a different work function value.

As described in greater detail above, some implementations described herein provide a method. The method includes forming one or more first portions of a gate dielectric layer of a transistor structure, where the one or more first portions are composed of a first material having a first k-value. The method includes forming one or more second portions of the gate dielectric layer, where the one or more second portions are composed of a second material having a second k-value that is different than the first k-value. The method includes forming one or more third portions of the gate dielectric layer, where the one or more third portions are composed of a third material having a third k-value that is different than the first and second k-values. The method includes forming a gate structure of the transistor structure over the gate dielectric layer. The method includes forming a first source/drain region and a second source/drain region such that the first source/drain region and the second source/drain region are laterally adjacent to opposing sides of the gate structure.

The terms “approximately” and “substantially” can indicate a value of a given quantity that varies within 5% of the value (e.g., ±1%, ±2%, ±3%, ±4%, ±5% of the value). These values are merely examples and are not intended to be limiting. It is to be understood that the terms “approximately” and “substantially” can refer to a percentage of the values of a given quantity in light of this disclosure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A transistor structure, comprising:
a first source/drain region in a substrate of a semiconductor device;
a second source/drain region in the substrate;
a gate structure above the substrate,
wherein the gate structure is laterally between the first source/drain region and the second source/drain region; and
a composite gate dielectric layer between the gate structure and the substrate,
wherein the composite gate dielectric layer comprises a plurality of laterally-arranged portions, each having a different dielectric constant (k-value).

2. The transistor structure of claim 1, wherein the first source/drain region, the gate structure, and the second source/drain region are arranged in a first direction in the semiconductor device; and
wherein the plurality of laterally-arranged portions comprises:
a first portion having a first k-value;
a second portion having a second k-value; and
a third portion having the first k-value,
wherein the first portion, the second portion, and the third portion are arranged in a second direction in the semiconductor device that is approximately perpendicular to the first direction, and
wherein the first k-value and the second k-value are different k-values.

3. The transistor structure of claim 2, wherein the plurality of laterally-arranged portions comprises:
a fourth portion, laterally adjacent to the first portion, having a third k-value;
a fifth portion, laterally adjacent to the second portion, having a fourth k-value; and
a sixth portion, laterally adjacent to the third portion, having the third k-value,
wherein the fourth portion, the fifth portion, and the sixth portion are arranged in the second direction, and
wherein the third k-value and the fourth k-value are different k-values.

4. The transistor structure of claim 3, wherein the first k-value, the second k-value, the third k-value, and the fourth k-value are different k-values.

5. The transistor structure of claim 1, wherein the first source/drain region, the gate structure, and the second source/drain region are arranged in a first direction in the semiconductor device;
wherein the gate structure extends between the first source/drain region and the second source/drain region in a second direction in the semiconductor device that is approximately perpendicular to the first direction; and
wherein the plurality of laterally-arranged portions comprises:
a first portion having a first k-value;
a second portion having a second k-value; and
a third portion having the first k-value,
wherein the first portion, the second portion, and the third portion are arranged in the first direction, and
wherein the first k-value and the second k-value are different k-values.

6. The transistor structure of claim 1, wherein the first source/drain region, the gate structure, and the second source/drain region are arranged in a first direction in the semiconductor device;
wherein the gate structure extends between the first source/drain region and the second source/drain region in a second direction in the semiconductor device that is approximately perpendicular to the first direction; and
wherein the plurality of laterally-arranged portions comprises:
a first portion having a first k-value;
a second portion having a second k-value; and
a third portion having a third k-value,
wherein the first portion, the second portion, and the third portion are arranged in the first direction, and
wherein the first k-value, the second k-value, and the third k-value are different k-values.

7. The transistor structure of claim 6, wherein the plurality of laterally-arranged portions comprises:
a fourth portion, adjacent to a first end of the first portion, having a fourth k-value; and
a fifth portion, adjacent to a second end of the first portion, having the fourth k-value,
wherein the fourth portion, the first portion, and the fifth portion are arranged in the second direction, and
wherein the first k-value, the second k-value, the third k-value, and the fourth k-value are different k-values.

8. A transistor structure, comprising:
a first source/drain region in a substrate of a semiconductor device;
a second source/drain region in the substrate;
a gate structure above the substrate,
wherein the gate structure is laterally between the first source/drain region and the second source/drain region; and
a gate dielectric layer between the gate structure and the substrate,
wherein the gate structure comprises a plurality of laterally-arranged doped regions, each having a different work function value.

9. The transistor structure of claim 8, wherein the first source/drain region, the gate structure, and the second source/drain region are arranged in a first direction in the semiconductor device; and
wherein the plurality of laterally-arranged doped regions comprises:
a first doped region having a first work function value;
a second doped region having a second work function value; and
a third doped region having the first work function value,
wherein the first doped region, the second doped region, and the third doped region are arranged in a second direction in the semiconductor device that is approximately perpendicular to the first direction, and
wherein the first work function value and the second work function value are different work function values.

10. The transistor structure of claim 9, wherein the plurality of laterally-arranged doped regions comprises:
a fourth doped region, laterally adjacent to the first doped region, having a third work function value;
a fifth doped region, laterally adjacent to the second doped region, having a fourth work function value; and
a sixth doped region, laterally adjacent to the third doped region, having the third work function value,
wherein the fourth doped region, the fifth doped region, and the sixth doped region are arranged in the second direction, and
wherein the third work function value and the fourth work function value are different work function values.

11. The transistor structure of claim 10, wherein the first work function value, the second work function value, the third work function value, and the fourth work function value are different work function values.

12. The transistor structure of claim 8, wherein the first source/drain region, the gate structure, and the second source/drain region are arranged in a first direction in the semiconductor device;
wherein the gate structure extends between the first source/drain region and the second source/drain region in a second direction in the semiconductor device that is approximately perpendicular to the first direction; and
wherein the plurality of laterally-arranged doped regions comprises:
a first doped region having a first work function value;
a second doped region having a second work function value; and
a third doped region having the first work function value,
wherein the first doped region, the second doped region, and the third doped region are arranged in the first direction, and
wherein the first work function value and the second work function value are different work function values.

13. The transistor structure of claim 8, wherein the first source/drain region, the gate structure, and the second source/drain region are arranged in a first direction in the semiconductor device;
wherein the gate structure extends between the first source/drain region and the second source/drain region in a second direction in the semiconductor device that is approximately perpendicular to the first direction; and
wherein the plurality of laterally-arranged doped regions comprises:
a first doped region having a first work function value;
a second doped region having a second work function value; and
a third doped region having a third work function value,
wherein the first doped region, the second doped region, and the third doped region are arranged in the first direction, and
wherein the first work function value, the second work function value, and the third work function value are different work function values.

14. The transistor structure of claim 13, wherein the plurality of laterally-arranged doped regions comprises:
a fourth doped region, adjacent to a first end of the first doped region, having a fourth work function value; and
a fifth doped region, adjacent to a second end of the first doped region, having the fourth work function value,
wherein the fourth doped region, the first doped region, and the fifth doped region are arranged in the second direction, and
wherein the first work function value, the second work function value, the third work function value, and the fourth work function value are different work function values.

15. A method, comprising:
forming one or more first portions of a gate dielectric layer of a transistor structure,
wherein the one or more first portions are composed of a first material having a first dielectric constant (k-value);
forming one or more second portions of the gate dielectric layer,
wherein the one or more second portions are composed of a second material having a second k-value that is different than the first k-value;
forming one or more third portions of the gate dielectric layer,
wherein the one or more third portions are composed of a third material having a third k-value that is different than the first and second k-values;
forming a gate structure of the transistor structure over the gate dielectric layer; and
forming a first source/drain region and a second source/drain region such that the first source/drain region and the second source/drain region are laterally adjacent to opposing sides of the gate structure.

16. The method of claim 15, wherein forming the one or more second portions comprises:
forming a fourth portion of the one or more second portions such that the fourth portion is laterally between a first subset of the one or more first portions; and
forming a fifth portion of the one or more second portions such that the fifth portion is laterally between a second subset of the one or more first portions.

17. The method of claim 15, further comprising:
forming a fourth portion of the gate dielectric layer,
wherein the fourth portion is composed of a material having a fourth k-value that is different than the first, second, and third k-values.

18. The method of claim 17, wherein forming the fourth portion of the gate dielectric layer comprises:
forming the fourth portion laterally between a fifth portion of the one or more second portions and a sixth portion of the one or more second portions.

19. The method of claim 18, wherein forming the fourth portion of the gate dielectric layer comprises:
forming the fourth portion laterally between a seventh portion of the one or more third portions and an eight portion of the one or more third portions.

20. The method of claim 15, wherein forming the gate structure comprises:
forming one or more first doped regions of the gate structure above the one or more first portions of the gate dielectric layer,
wherein the one or more first doped regions have a first work function value;
forming one or more second doped regions of the gate structure above the one or more second portions of the gate dielectric layer,
wherein the one or more second doped regions have a second work function value that is different than the first work function value; and
forming one or more third doped regions of the gate structure above the one or more third portions of the gate dielectric layer,
wherein the one or more third doped regions have a third work function value that is different than the first and second work function values.
